(19) United States
(12) Patent Application Publication
(10) Pub. No.: US 2026/0282352 A1
(43) Pub. Date: Sep. 17, 2026

(54) SEMICONDUCTOR STORAGE DEVICE

(71) Applicant: Kioxia Corporation, Tokyo (JP)

(72) Inventors: Natsuki FUKUDA, Yokkaichi (JP); Hisashi KATO, Yokkaichi (JP)

(73) Assignee: Kioxia Corporation, Tokyo (JP)

(21) Appl. No.: 19/325,550

(22) Filed: Sep. 11, 2025

(30) Foreign Application Priority Data
Mar. 17, 2025 (JP) 2025-042810

(51) Int. Cl. H10B 43/27; H10B 43/10; H10B 43/35

(52) U.S. Cl. CPC H10B 43/27; H10B 43/10; H10B 43/35

(57) ABSTRACT

A semiconductor storage device includes first and second laminates, a memory pillar, first and second contacts, and first and second dividing portions. The first laminate includes first wiring layers and first insulator layers on the same layers as the first wiring layers. The second laminate includes second wiring layers and second insulator layers on the same layers as the second wiring layers, and is above the first laminate. The memory pillar penetrates the first wiring layers and the second wiring layers. The first contact penetrates the second laminate and is connected to one of the first wiring layers. The first dividing portion divides the first wiring layers. The second contact is connected to one of the second wiring layers. The second dividing portion divides the second wiring layers. The second dividing portion does not overlap with the first dividing portion.

### CROSS-REFERENCE TO RELATED APPLICATION

This application is based upon and claims the benefit of priority from Japanese Patent Application No. 2025-042810, filed Mar. 17, 2025, the entire contents of which are incorporated herein by reference.

### FIELD

Embodiments described herein relate generally to a semiconductor storage device.

### BACKGROUND

The NAND-type flash memory is a known semiconductor storage device that can store data in a nonvolatile manner.

### BRIEF DESCRIPTION OF THE DRAWINGS

FIG. 1 is a block diagram showing an example of a configuration of a memory system including a semiconductor storage device according to a first embodiment.

FIG. 2 is a circuit diagram showing an example of a circuit configuration of a memory cell array included in the semiconductor storage device according to the first embodiment.

FIG. 3 is a perspective view showing an overview of a bonded structure of the semiconductor storage device according to the first embodiment.

FIG. 4 is a plan view showing an example of a plan layout of the semiconductor storage device according to the first embodiment.

FIG. 5 is a plan view showing an example of a plan layout of the memory cell array in a core region of the semiconductor storage device according to the first embodiment.

FIG. 6 is a cross-sectional view taken along the line VI-VI in FIG. 5, showing an example of a cross-sectional structure in a memory region of the memory cell array included in the semiconductor storage device according to the first embodiment.

FIG. 7 is a cross-sectional view taken along the line VII-VII in FIG. 6, showing an example of a cross-sectional structure of a memory pillar included in the semiconductor storage device according to the first embodiment.

FIG. 8 is a cross-sectional view taken along the line VIII-VIII in FIG. 5, showing an example of a cross-sectional structure in a contact region of the memory cell array included in the semiconductor storage device according to the first embodiment.

FIG. 9 is a cross-sectional view taken along the line IX-IX in FIG. 5, showing an example of the cross-sectional structure in the contact region of the memory cell array included in the semiconductor storage device according to the first embodiment.

FIG. 10 is a cross-sectional view showing an example of a cross-sectional structure during production of the semiconductor storage device according to the first embodiment.

FIG. 11 is a cross-sectional view showing an example of the cross-sectional structure during production of the semiconductor storage device according to the first embodiment.

FIG. 12 is a cross-sectional view showing an example of the cross-sectional structure during production of the semiconductor storage device according to the first embodiment.

FIG. 13 is a cross-sectional view showing an example of the cross-sectional structure during production of the semiconductor storage device according to the first embodiment.

FIG. 14 is a cross-sectional view showing an example of the cross-sectional structure during production of the semiconductor storage device according to the first embodiment.

FIG. 15 is a cross-sectional view showing an example of the cross-sectional structure during production of the semiconductor storage device according to the first embodiment.

FIG. 16 is a plan view showing an example of a plan structure during production of the semiconductor storage device according to the first embodiment.

FIG. 17 is a cross-sectional view showing an example of the cross-sectional structure during production of the semiconductor storage device according to the first embodiment.

FIG. 18 is a cross-sectional view showing an example of the cross-sectional structure during production of the semiconductor storage device according to the first embodiment.

FIG. 19 is a plan view showing an example of the plan structure during production of the semiconductor storage device according to the first embodiment.

FIG. 20 is a cross-sectional view showing an example of the cross-sectional structure during production of the semiconductor storage device according to the first embodiment.

FIG. 21 is a cross-sectional view showing an example of the cross-sectional structure during production of the semiconductor storage device according to the first embodiment.

FIG. 22 is a plan view showing an example of the plan structure during production of the semiconductor storage device according to the first embodiment.

FIG. 23 is a cross-sectional view showing an example of the cross-sectional structure during production of the semiconductor storage device according to the first embodiment.

FIG. 24 is a cross-sectional view showing an example of the cross-sectional structure during production of the semiconductor storage device according to the first embodiment.

FIG. 25 is a plan view showing an example of the plan structure during production of the semiconductor storage device according to the first embodiment.

FIG. 26 is a cross-sectional view showing an example of the cross-sectional structure during production of the semiconductor storage device according to the first embodiment.

FIG. 27 is a cross-sectional view showing an example of the cross-sectional structure during production of the semiconductor storage device according to the first embodiment.

FIG. 28 is a plan view showing an example of the plan structure during production of the semiconductor storage device according to the first embodiment.

FIG. 29 is a cross-sectional view showing an example of the cross-sectional structure during production of the semiconductor storage device according to the first embodiment.

FIG. 30 is a cross-sectional view showing an example of the cross-sectional structure during production of the semiconductor storage device according to the first embodiment.

FIG. 31 is a cross-sectional view showing an example of the cross-sectional structure during production of the semiconductor storage device according to the first embodiment.

FIG. 32 is a cross-sectional view showing an example of the cross-sectional structure during production of the semiconductor storage device according to the first embodiment.

FIG. 33 is a plan view showing an example of the plan structure during production of the semiconductor storage device according to the first embodiment.

FIG. 34 is a cross-sectional view showing an example of the cross-sectional structure during production of the semiconductor storage device according to the first embodiment.

FIG. 35 is a cross-sectional view showing an example of the cross-sectional structure during production of the semiconductor storage device according to the first embodiment.

FIG. 36 is a cross-sectional view showing an example of the cross-sectional structure during production of the semiconductor storage device according to the first embodiment.

FIG. 37 is a plan view showing an example of the plan structure during production of the semiconductor storage device according to the first embodiment.

FIG. 38 is a cross-sectional view taken along the line VIII-VIII in FIG. 5, showing an example of a cross-sectional structure in a contact region of a memory cell array included in a semiconductor storage device according to a first variation of the first embodiment.

FIG. 39 is a cross-sectional view taken along the line IX-IX in FIG. 5, showing an example of the cross-sectional structure in the contact region of the memory cell array included in the semiconductor storage device according to the first variation of the first embodiment.

FIG. 40 is a cross-sectional view showing an example of a cross-sectional structure during production of the semiconductor storage device according to the first variation of the first embodiment.

FIG. 41 is a plan view showing an example of a plan structure during production of the semiconductor storage device according to the first variation of the first embodiment.

FIG. 42 is a cross-sectional view showing an example of the cross-sectional structure during production of the semiconductor storage device according to the first variation of the first embodiment.

FIG. 43 is a plan view showing an example of the plan structure during production of the semiconductor storage device according to the first variation of the first embodiment.

FIG. 44 is a cross-sectional view showing an example of the cross-sectional structure during production of the semiconductor storage device according to the first variation of the first embodiment.

FIG. 45 is a plan view showing an example of the plan structure during production of the semiconductor storage device according to the first variation of the first embodiment.

FIG. 46 is a cross-sectional view showing an example of the cross-sectional structure during production of the semiconductor storage device according to the first variation of the first embodiment.

FIG. 47 is a plan view showing an example of the plan structure during production of the semiconductor storage device according to the first variation of the first embodiment.

FIG. 48 is a cross-sectional view showing an example of the cross-sectional structure during production of the semiconductor storage device according to the first variation of the first embodiment.

FIG. 49 is a plan view showing an example of the plan structure during production of the semiconductor storage device according to the first variation of the first embodiment.

FIG. 50 is a cross-sectional view showing an example of the cross-sectional structure during production of the semiconductor storage device according to the first variation of the first embodiment.

FIG. 51 is a plan view showing an example of the plan structure during production of the semiconductor storage device according to the first variation of the first embodiment.

FIG. 52 is a cross-sectional view showing an example of the cross-sectional structure during production of the semiconductor storage device according to the first variation of the first embodiment.

FIG. 53 is a plan view showing an example of the plan structure during production of the semiconductor storage device according to the first variation of the first embodiment.

FIG. 54 is a cross-sectional view showing an example of the cross-sectional structure during production of the semiconductor storage device according to the first variation of the first embodiment.

FIG. 55 is a cross-sectional view showing an example of the cross-sectional structure during production of the semiconductor storage device according to the first variation of the first embodiment.

FIG. 56 is a plan view showing an example of a plan layout of a memory cell array in a core region of a semiconductor storage device according to a second variation of the first embodiment.

FIG. 57 is a plan view showing an example of a plan structure during production of the semiconductor storage device according to the second variation of the first embodiment.

FIG. 58 is a plan view showing an example of the plan structure during production of the semiconductor storage device according to the second variation of the first embodiment.

FIG. 59 is a plan view showing an example of the plan structure during production of the semiconductor storage device according to the second variation of the first embodiment.

FIG. 60 is a plan view showing an example of the plan structure during production of the semiconductor storage device according to the second variation of the first embodiment.

FIG. 61 is a plan view showing an example of the plan structure during production of the semiconductor storage device according to the second variation of the first embodiment.

FIG. 62 is a plan view showing an example of the plan structure during production of the semiconductor storage device according to the second variation of the first embodiment.

FIG. 63 is a plan view showing an example of the plan structure during production of the semiconductor storage device according to the second variation of the first embodiment.

FIG. 64 is a plan view showing an example of a plan layout of a memory cell array in a core region of a semiconductor storage device according to a second embodiment.

FIG. 65 is a cross-sectional view taken along the line S1-S1 in FIG. 64, showing an example of a cross-sectional structure in a memory region of a memory cell array included in the semiconductor storage device according to the second embodiment.

FIG. 66 is a cross-sectional view taken along the line S2-S2 in FIG. 64, showing an example of a cross-sectional structure in a contact region of the memory cell array included in the semiconductor storage device according to the second embodiment.

FIG. 67 is a cross-sectional view taken along the line S3-S3 in FIG. 64, showing an example of the cross-sectional structure in the contact region of the memory cell array included in the semiconductor storage device according to the second embodiment.

FIG. 68 is a cross-sectional view showing an example of a cross-sectional structure during production of the semiconductor storage device according to the second embodiment.

FIG. 69 is a plan view showing an example of a plan structure during production of the semiconductor storage device according to the second embodiment.

FIG. 70 is a cross-sectional view showing an example of the cross-sectional structure during production of the semiconductor storage device according to the second embodiment.

FIG. 71 is a plan view showing an example of the plan structure during production of the semiconductor storage device according to the second embodiment.

FIG. 72 is a cross-sectional view showing an example of the cross-sectional structure during production of the semiconductor storage device according to the second embodiment.

FIG. 73 is a plan view showing an example of the plan structure during production of the semiconductor storage device according to the second embodiment.

FIG. 74 is a cross-sectional view showing an example of the cross-sectional structure during production of the semiconductor storage device according to the second embodiment.

FIG. 75 is a plan view showing an example of the plan structure during production of the semiconductor storage device according to the second embodiment.

FIG. 76 is a cross-sectional view showing an example of the cross-sectional structure during production of the semiconductor storage device according to the second embodiment.

FIG. 77 is a plan view showing an example of the plan structure during production of the semiconductor storage device according to the second embodiment.

FIG. 78 is a cross-sectional view showing an example of the cross-sectional structure during production of the semiconductor storage device according to the second embodiment.

FIG. 79 is a plan view showing an example of the plan structure during production of the semiconductor storage device according to the second embodiment.

FIG. 80 is a cross-sectional view showing an example of the cross-sectional structure during production of the semiconductor storage device according to the second embodiment.

FIG. 81 is a plan view showing an example of the plan structure during production of the semiconductor storage device according to the second embodiment.

FIG. 82 is a cross-sectional view showing an example of the cross-sectional structure during production of the semiconductor storage device according to the second embodiment.

FIG. 83 is a cross-sectional view showing an example of the cross-sectional structure during production of the semiconductor storage device according to the second embodiment.

FIG. 84 is a plan view showing an example of the plan structure during production of the semiconductor storage device according to the second embodiment.

FIG. 85 is a cross-sectional view showing an example of the cross-sectional structure during production of the semiconductor storage device according to the second embodiment.

FIG. 86 is a plan view showing an example of the plan structure during production of the semiconductor storage device according to the second embodiment.

FIG. 87 is a cross-sectional view taken along the line S2-S2 in FIG. 64, showing an example of a cross-sectional structure in a contact region of a memory cell array included in a semiconductor storage device according to a variation of the second embodiment.

FIG. 88 is a cross-sectional view showing an example of a cross-sectional structure during production of the semiconductor storage device according to the variation of the second embodiment.

FIG. 89 is a cross-sectional view showing an example of the cross-sectional structure during production of the semiconductor storage device according to the variation of the second embodiment.

FIG. 90 is a cross-sectional view showing an example of the cross-sectional structure during production of the semiconductor storage device according to the variation of the second embodiment.

FIG. 91 is a cross-sectional view showing an example of the cross-sectional structure during production of the semiconductor storage device according to the variation of the second embodiment.

### DETAILED DESCRIPTION

A semiconductor storage device that can reduce the amount of digging of a substrate is provided.

In general, according to one embodiment, a semiconductor storage device includes a first laminate, a second laminate, a memory pillar, a first contact, a first dividing portion, a second contact and a second dividing portion. The first laminate includes a plurality of first wiring layers and a plurality of first insulator layers, the plurality of first wiring layers being arranged at intervals in a first direction, and the plurality of first insulator layers being provided in the same layers as the plurality of first wiring layers. The second laminate includes a plurality of second wiring layers and a plurality of second insulator layers and is arranged above the first laminate, the plurality of second wiring layers being arranged at intervals in the first direction, and the plurality of second insulator layers being provided in the same layers as the plurality of second wiring layers. The memory pillar penetrates the plurality of first wiring layers and the plurality of second wiring layers in the first direction. The first contact extends in the first direction, penetrates the second laminate and is connected to a third wiring layer among the plurality of first wiring layers, and at least a part of the side face of the first contact is covered by a first insulator. The first dividing portion extends in the first direction and a second direction that intersects with the first direction, and divides the plurality of first wiring layers in a third direction that intersects with the first direction and the second direction. The second contact extends in the first direction and is connected to a fourth wiring layer among the plurality of second wiring layers, and at least a part of the side face of the second contact is covered by a second insulator. The second dividing portion extends in the first direction and the second direction and divides the plurality of second wiring layers in the third direction. The second dividing portion does not overlap with the first dividing portion in the first direction.

In the following, embodiments will be described with reference to the drawings. The dimensions and proportions in the drawings are not necessarily the same as the actual ones. Illustration of some components may be omitted in some drawings as required. Note that in the following description, components having substantially the same or similar functions or configurations are denoted by the same reference numerals. To distinguish between components having similar configurations, different letters or numerals may be suffixed to the same reference numeral.

### 1. First Embodiment

### 1.1 Configuration

### 1.1.1 Configuration of Memory System

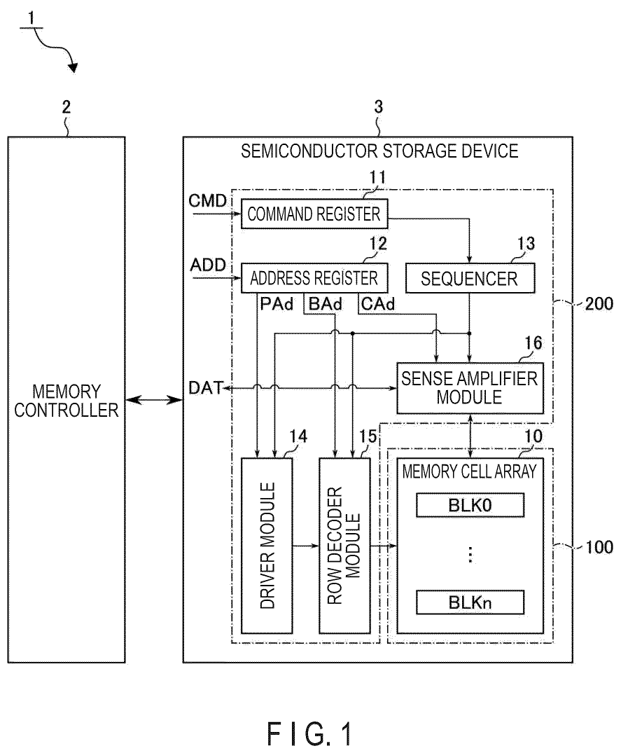

A configuration of a memory system including a semiconductor storage device according to a first embodiment will be described with reference to FIG. 1. FIG. 1 is a block diagram showing an example of a configuration of a memory system including a semiconductor storage device according to the first embodiment. A memory system 1 is a storage device configured to be connected to external host equipment (not shown). The memory system 1 is a memory card such as an SD™ card, a universal flash storage (UFS) or a solid state drive (SSD). As shown in FIG. 1, the memory system 1 includes a memory controller 2 and a semiconductor storage device 3.

The memory controller 2 is an integrated circuit such as a system-on-a-chip (SoC). The memory controller 2 controls the semiconductor storage device 3 based on a request from the host equipment. For example, the memory controller 2 writes data requested to write by the host equipment to the semiconductor storage device 3. Furthermore, the memory controller 2 reads data requested to read by the host equipment from the semiconductor storage device 3 and transmits the data to the host equipment.

The semiconductor storage device 3 is a memory that stores data in a nonvolatile manner. The semiconductor storage device 3 is a NAND-type flash memory, for example. The following description will be made taking a NAND-type flash memory as the semiconductor storage device 3, as an example.

### 1.1.2 Configuration of Semiconductor Storage Device

Still referring to FIG. 1, a configuration of the semiconductor storage device 3 will be described. As shown in FIG. 1, the semiconductor storage device 3 includes an array chip 100 and a circuit chip 200.

The array chip 100 includes a memory cell array 10, for example.

The memory cell array 10 includes a plurality of blocks BLK0 to BLKn (n denotes an integer equal to or greater than 1). The block BLK is a set of a plurality of memory cell transistors that can store data in a nonvolatile manner. The block BLK is used as a unit of data erasure, for example. In the memory cell array 10, a plurality of bit lines and a plurality of word lines are also provided. Each memory cell transistor is associated with one bit line and one word line, for example. A detailed configuration of the memory cell array 10 will be described later.

The circuit chip 200 includes a command register 11, an address register 12, a sequencer 13, a driver module 14, a row decoder module 15 and a sense amplifier module 16, for example.

The command register 11 is a circuit that stores a command CMD received by the semiconductor storage device 3 from the memory controller 2. The command CMD includes an instruction for making the sequencer 13 perform a read operation, a write operation, an erasure operation and the like,

The address register 12 is a circuit that stores an address ADD received by the semiconductor storage device 3 from the memory controller 2. The address ADD includes a block address BAd, a page address PAd and a column address CAd, for example. For example, the block address BAd, the page address PAd and the column address CAd are used for selecting a block BLK, a word line and a bit line, respectively.

The sequencer 13 is a circuit that controls an operation of another circuit according to a predetermined program. The sequencer 13 controls the operation of the whole of the semiconductor storage device 3. For example, the sequencer 13 controls the driver module 14, the row decoder module 15, the sense amplifier module 16 and the like based on a command CMD stored in the command register 11. For example, the sequencer 13 performs a read operation, a write operation, an erasure operation and the like.

The driver module 14 is a circuit that generates a voltage used for a read operation, a write operation, an erasure operation and the like. The driver module 14 applies the generated voltage to a signal line corresponding to a selected word line based on a page address PAd stored in the address register 12, for example.

The row decoder module 15 is a circuit that selects one relevant block BLK in the memory cell array 10 based on a block address BAd stored in the address register 12. The row decoder module 15 transfers the voltage applied to a signal line corresponding to a selected word line to the selected word line in the selected block BLK, for example.

The sense amplifier module 16 is a circuit that selects a bit line based on a column address CAd stored in the address register 12. For example, in a write operation, the sense amplifier module 16 applies, to a selected bit line, a voltage based on write data DAT received from the memory controller 2. In a read operation, the sense amplifier module 16 determines data stored in a memory cell transistor based on the voltage on the selected bit line. The sense amplifier module 16 transfers the determination result to the memory controller 2 as read data DAT.

### 1.1.3 Circuit Configuration of Memory Cell Array

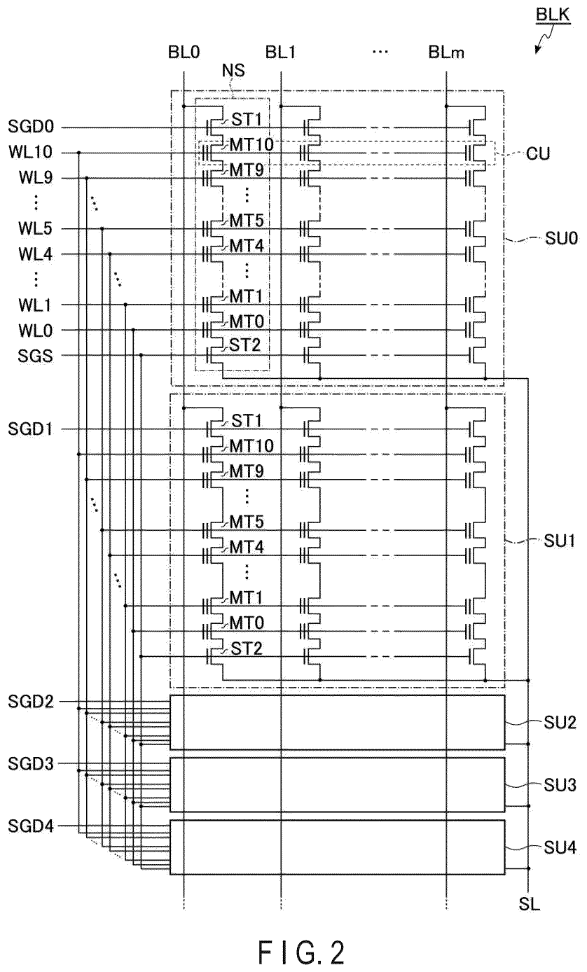

A circuit configuration of the memory cell array 10 will be described with reference to FIG. 2. FIG. 2 is a circuit diagram showing an example of a circuit configuration of the memory cell array 10 included in the semiconductor storage device 3 according to the first embodiment. FIG. 2 shows one block BLK among the plurality of blocks BLK included in the memory cell array 10. The other blocks BLK have the same configuration as that shown in FIG. 2. As shown in FIG. 2, the block BLK includes five string units SU0 to SU4, for example. The string unit SU is a set of NAND strings NS described later. For example, in a write operation or a read operation, the NAND strings NS in a string unit SU are selected by batch.

Each string unit SU includes a plurality of NAND strings NS each associated with bit lines BL0 to BLm (m denotes an integer equal to or greater than 1). Each NAND string NS includes memory cell transistors MT0 to MT10 and selection transistors ST1 and ST2, for example. Each memory cell transistor MT includes a control gate and a charge storage layer and stores data in a nonvolatile manner. Each of the selection transistors ST1 and ST2 is used for selecting a string unit SU in various operations.

In each NAND string NS, the memory cell transistors MT0 to MT10 are connected in series. The drain of the selection transistor ST1 is connected to an associated bit line BL. The source of the selection transistor ST1 is connected to one ends of the memory cell transistors MT0 to MT10 connected in series. The drain of the selection transistor ST2 is connected to the other ends of the memory cell transistors MT0 to MT10 connected in series. The source of the selection transistor ST2 is connected to a source line SL.

In the same block BLK, the control gates of the memory cell transistors MT0 to MT10 are connected to the word lines WL0 to WL10, respectively. The gates of the selection transistors ST1 in the string units SU0 to SU4 are connected to selection gate lines SGD0 to SGD4, respectively. The gates of the selection transistors ST2 in the string units SU0 to SU4 are connected to a selection gate line SGS.

Each of the bit lines BL0 to BLm is assigned a different column address CAd. Each bit line BL is shared by NAND strings NS assigned the same column address CAd among a plurality of blocks BLK. Each of the word lines WL0 to WL10 is provided for each block BLK. The source line SL is shared among a plurality of blocks BLK, for example.

A set of a plurality of memory cell transistors MT connected to a common word line WL in one string unit SU is referred to as a cell unit CU, for example. For example, the storage capacity of a cell unit CU including memory cell transistors MT each of which stores 1-bit data is defined as “one page of data”. The cell unit CU may have a storage capacity of two pages of data or more, depending on the number of bits stored by the memory cell transistor MT.

Note that the circuit configuration of the memory cell array 10 is not limited to the configuration described above. For example, the number of the string units SU included in each block BLK can be any number. The number of the memory cell transistors MT included in each NAND string NS and the number of the selection transistors ST1 and ST2 included in each NAND string NS can also be any number.

### 1.1.4 Structure of Semiconductor Storage Device

### 1.1.4.1 Bonded Structure of Semiconductor Storage Device

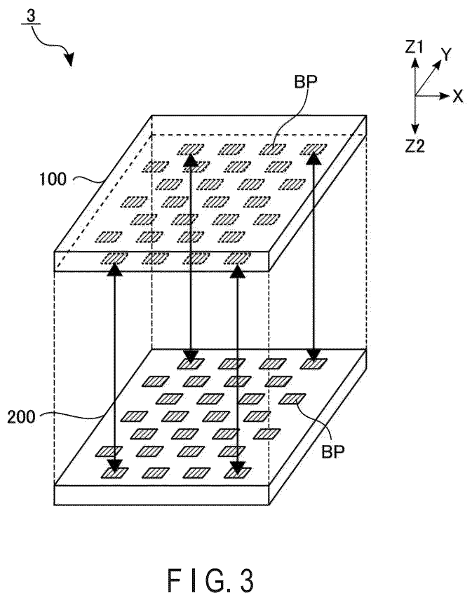

An overview of a bonded structure of the semiconductor storage device 3 will be described with reference to FIG. 3. FIG. 3 is a perspective view showing an overview of a bonded structure of the semiconductor storage device 3 according to the first embodiment. As shown in FIG. 3, the semiconductor storage device 3 has a structure (bonded structure) in which the array chip 100 is bonded to the circuit chip 200. The array chip 100 and the circuit chip 200 each include a plurality of bonding pads BP provided on faces facing each other. In the bonded structure, a bonding pad BP of the array chip 100 and a bonding pad BP of the circuit chip 200 are bonded to each other to form one bonded pad BP. In other words, an electrode (conductor) forming a bonding pad BP provided on the array chip 100 and an electrode (conductor) forming a bonding pad BP provided on the circuit chip 200 are bonded to each other to form a bonded pad BP.

In the following, it is assumed that a plane (lamination plane) on which the array chip 100 and the circuit chip 200 are bonded is an XY plane. In the XY plane, directions perpendicular to each other are an X direction and a Y direction. The X direction corresponds to the direction of extension of the word lines WL. The Y direction corresponds to the direction of extension of the bit lines BL. A direction from the circuit chip 200 to the array chip 100 that is generally perpendicular to the XY plane is referred to as a Z1 direction. A direction from the array chip 100 to the circuit chip 200 that is generally perpendicular to the XY plane is referred to as a Z2 direction. When the Z1 direction and the Z2 direction need not be discriminated from each other, the direction is referred to as a Z direction.

### 1.1.4.2 Plan Layout of Semiconductor Storage Device

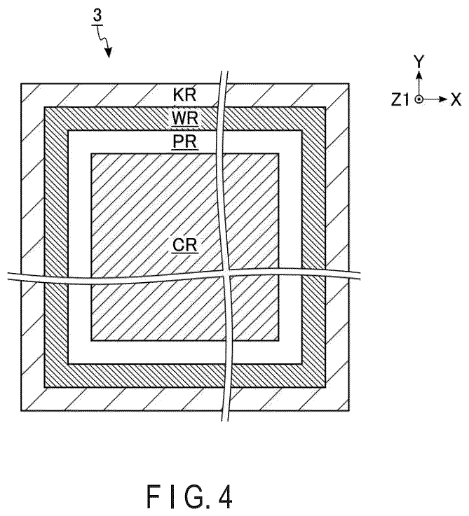

A plan layout of the semiconductor storage device 3 will be described with reference to FIG. 4. FIG. 4 is a plan view showing an example of the plan layout of the semiconductor storage device 3 according to the first embodiment. As shown in FIG. 4, the semiconductor storage device 3 (each of the array chip 100 and the circuit chip 200) includes a core region CR, a peripheral region PR, a wall region WR and a kerf region KR, for example.

The core region CR is a rectangular region provided around the center of the semiconductor substrate (not shown) of the semiconductor storage device 3, for example. In the core region CR, for example, the memory cell array 10, the command register 11, the address register 12, the row decoder module 15, the sense amplifier module 16 and the like are arranged.

The peripheral region PR is a rectangular annular region provided to surround the circumference of the core region CR. In the peripheral region PR, for example, the sequencer 13, the driver module 14 and the like are arranged. In the peripheral region PR, in addition, for example, a contact or the like for connecting the external equipment of the semiconductor storage device 3 and a circuit provided in the circuit chip 200 is arranged.

The wall region WR is a rectangular annular region provided to surround the circumference of the peripheral region PR. In the wall region WR, at least one sealing part (not shown) provided to surround the circumference of the peripheral region PR is arranged.

The kerf region KR is a rectangular annular region provided to surround the circumference of the wall region WR. The kerf region KR borders the outermost circumference of the semiconductor storage device 3. In the kerf region KR, for example, an alignment mark or the like used in production of the semiconductor storage device 3 is arranged.

### 1.1.4.3 Plan Layout of Memory Cell Array

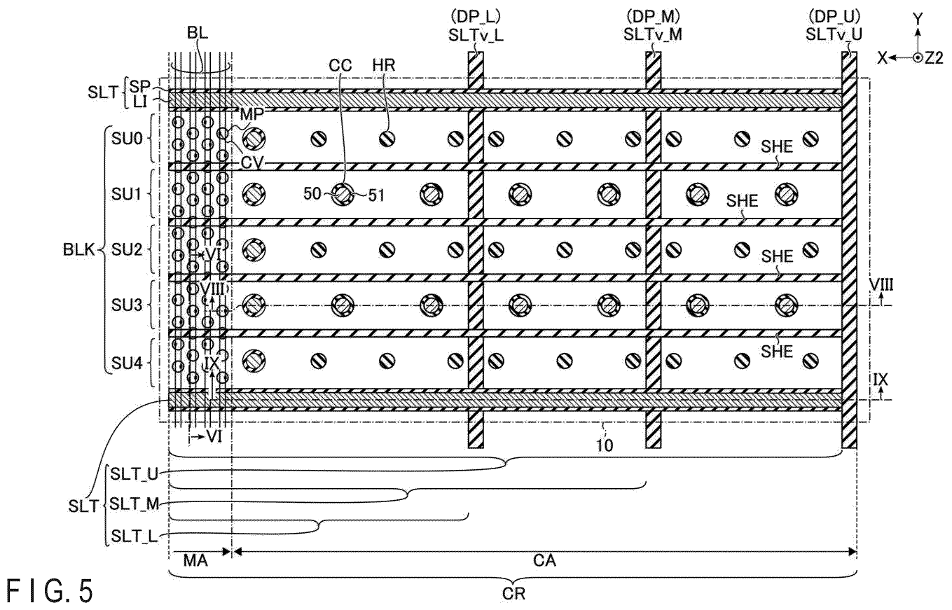

A plan layout of the memory cell array 10 will be described with reference to FIG. 5. FIG. 5 is a plan view showing an example of the plan layout of the memory cell array 10 in the core region CR of the semiconductor storage device 3 according to the first embodiment. FIG. 5 shows a region corresponding to one block BLK included in the memory cell array 10. As shown in FIG. 5, the memory cell array 10 includes two members SLT, a plurality of members SHE, a member SLTv_L, a member SLTv_M and a member SLTv_U, for example. The memory cell array 10 further includes a memory region MA and a contact region CA that are arranged in the X direction, for example. Note that illustration of an interlayer insulating film is omitted.

Each member SLT has a portion provided to extend in the X direction and is arranged to span the memory region MA and the contact region CA. The two members SLT are arranged in the Y direction. An end portion of each member SLT opposite to the memory region MA in the X direction is in contact with the member SLTv_U. Each member SLT divides multilayer wiring (the selection gate line SGS, the word lines WL0 to WL10 and the selection gate line SGD arranged at intervals in the Z direction) on opposite sides of the member SLT. Each member SLT has a conductor LI arranged therein, and the conductor LI is insulated from the multilayer wiring by a spacer SP formed by an insulator provided on a side wall thereof. Note that each member SLT may have a structure with an insulator embedded therein. In the memory cell array 10, each region partitioned by the members SLT corresponds to one block BLK.

Furthermore, each member SLT includes an upper member SLT_U, a middle member SLT_M and a lower member SLT_L. The upper member SLT_U is provided above the middle member SLT_M. The lower end of the upper member SLT_U is in contact with the upper end of the middle member SLT_M. The middle member SLT_M is provided above the lower member SLT_L. The lower end of the middle member SLT_M is in contact with the upper end of the lower member SLT_L. The upper member SLT_U, the middle member SLT_M and the lower member SLT_L span the memory region MA and the contact region CA. An end portion of the upper member SLT_U opposite to the memory region MA in the X direction is in contact with the member SLTv_U. An end portion of the middle member SLT_M opposite to the memory region MA in the X direction is in contact with the member SLTv_M. An end portion of the lower member SLT_L opposite to the memory region MA in the X direction is in contact with the member SLTv_L.

Each member SHE has a portion provided to extend in the X direction and is arranged to span the memory region MA and the contact region CA. The plurality of members SHE are arranged in the Y direction. An end portion of each member SHE opposite to the memory region MA in the X direction is in contact with the member SLTv_U. In this example, four members SHE are arranged between two members SLT adjacent to each other in the Y direction. Each member SHE divides wires (at least the selection gate line SGD) on opposite sides of the member SHE. Each member SHE has a structure with an insulator embedded therein, for example. In the memory cell array 10, each region partitioned by the members SLT and SHE corresponds to one string unit SU.

The members SLTv_L, SLTv_M and SLTv_U are disposed in the contact region CA. The members SLTv_L, SLTv_M and SLTv_U are arranged in the order of the members SLTv_L, SLTv_M and SLTv_U from the side of the memory region MA. The member SLTv_U is provided above the member SLTv_M. The member SLTv_M is provided above the member SLTv_L.

The member SLTv_L has a portion provided to extend in the Y direction. The member SLTv_L is in contact with the lower member SLT_L of each member SLT on a side closer to the memory region MA. The member SLTv_L divides blocks BLK adjacent to each other in the Y direction. The member SLTv_L has a structure with an insulator embedded therein, for example.

The member SLTv_M has a portion provided to extend in the Y direction. The member SLTv_M is in contact with the middle member SLT_M of each member SLT on a side closer to the memory region MA. The member SLTv_M divides blocks BLK adjacent to each other in the Y direction. The member SLTv_M has a structure with an insulator embedded therein, for example.

The member SLTv_U has a portion provided to extend in the Y direction. The member SLTv_U is in contact with the upper member SLT_U of each member SLT and each member SHE on a side closer to the memory region MA. That is, the member SLTv_U is in contact with an end portion of each member SLT opposite to the memory region MA in the X direction and an end portion of each member SHE opposite to the memory region MA in the X direction. The member SLTv_U divides blocks BLK adjacent to each other in the Y direction. The member SLTv_U has a structure with an insulator embedded therein, for example.

In the following, when the members SLTv_L, SLTv_M and SLTv_U need not be discriminated from each other, the member is referred to simply as a member SLTv. In addition, the members SLTv_L, SLTv_M and SLTv_U may be referred to as a “dividing portion DP_L”, a “dividing portion DP_M” and a “dividing portion DP_U”, respectively.

Note that the other blocks BLK have the same structure as that shown in FIG. 5. When the memory cell array 10 includes a plurality of blocks BLK, for example, the structure shown in FIG. 5 is repeatedly arranged in the Y direction.

The plan layout of the memory cell array 10 included in the semiconductor storage device 3 may be other layouts. For example, the number of the members SHE arranged between two adjacent members SLT can be any number. The number of the string units SU included in each block BLK can be modified based on the number of the members SHE arranged between two adjacent members SLT. The number of the members SLTv can be any number equal to or greater than 2 and can be modified according to the structure of the memory cell array 10.

### 1.1.4.4 Plan Layout of Memory Region

Still referring to FIG. 5, a plan layout of the memory region MA will be described. As shown in FIG. 5, for example, the semiconductor storage device 3 includes a plurality of memory pillars MP, a plurality of contacts CV and a plurality of bit lines BL in the memory region MA.

Each memory pillar MP functions as one NAND string NS. In the region between two adjacent members SLT, the plurality of memory pillars MP are arranged in twenty-four rows in a staggered configuration, for example. For example, one member SHE is overlaid on each of the fifth row of memory pillars MP, the tenth row of memory pillars MP, the fifteenth row of memory pillars MP and the twentieth row of memory pillars MP from the top of the sheet.

Each bit line BL has a portion provided to extend in the Y direction. The plurality of bit lines BL are arranged in the X direction. Each bit line BL is arranged to be overlaid on at least one memory pillar MP in each string unit SU. In this example, two bit lines BL are overlaid on each memory pillar MP. The memory pillar MP is electrically connected, via a contact CV, to one of the plurality of bit lines BL arranged to be overlaid on the memory pillar MP. Note that a contact CV between the memory pillar MP in contact with two different selection gate lines SGD and the bit line BL may be omitted.

Note that the plan layout of the memory region MA of the memory cell array 10 included in the semiconductor storage device 3 may be other layouts. For example, the number and arrangement of the memory pillars MP, the members SHE and the like disposed between two adjacent members SLT can be modified as required. The number of the bit lines BL overlaid on each memory pillar MP can be any number.

### 1.1.4.5 Plan Layout of Contact Region

Still referring to FIG. 5, a plan layout of the contact region CA will be described. As shown in FIG. 5, the memory cell array 10 includes a plurality of contacts CC and a plurality of supporting pillars HR in the contact region CA, for example.

The contacts CC electrically connect the selection gate line SGS, the word lines WL0 to WL10 and the selection gate line SGD to wiring provided above the memory cell array 10. The contact CC has a circular cross-sectional shape in the XY plane, for example.

The contacts CC are arranged in regions excluding the members SLT, SHE and SLTv in the contact region CA. In this example, five contacts CC are arranged side by side in the Y direction in the vicinity of the memory region MA. Each of these five contacts CC is disposed between the members SLT and SHE or between two members SHE, that is, in a region corresponding to the string units SU0 to SU4. These five contacts CC are connected to the selection gate line SGD, for example.

In the region corresponding to the string unit SU1, six contacts CC are arranged in addition to the contact CC in the vicinity of the memory region MA. Between the contact CC in the vicinity of the memory region MA and the member SLTv_L, two contacts CC are arranged side by side in the X direction. For example, of these two contacts CC, the one closer to the memory region MA is connected to the word line WL0, and the other is connected to the word line WL2. Between the member SLTv_L and the member SLTv_M, two contacts CC are arranged side by side in the X direction. For example, of these two contacts CC, the one closer to the memory region MA is connected to the word line WL4, and the other is connected to the word line WL6. Between the member SLTv_M and the member SLTv_U, two contacts CC are arranged side by side in the X direction. For example, of these two contacts CC, the one closer to the memory region MA is connected to the word line WL8, and the other is connected to the word line WL10.

In the region corresponding to the string unit SU3, six contacts CC are arranged in addition to the contact CC in the vicinity of the memory region MA. Between the contact CC in the vicinity of the memory region MA and the member SLTv_L, two contacts CC are arranged side by side in the X direction. For example, of these two contacts CC, the one closer to the memory region MA is connected to the selection gate line SGS, and the other is connected to the word line WL1. Between the member SLTv_L and the member SLTv_M, two contacts CC are arranged side by side in the X direction. For example, of these two contacts CC, the one closer to the memory region MA is connected to the word line WL3, and the other is connected to the word line WL5. Between the member SLTv_M and the member SLTv_U, two contacts CC are arranged side by side in the X direction. For example, of these two contacts CC, the one closer to the memory region MA is connected to the word line WL7, and the other is connected to the word line WL9.

The contact CC includes a conductor 50 and an insulator 51. The conductor 50 is connected to any of the selection gate line SGS, the word lines WL0 to WL10 and the selection gate line SGD. The conductor 50 contains tungsten, for example. The insulator 51 covers a side face of the conductor 50. The insulator 51 contains silicon oxide, for example.

The supporting pillar HR is an insulator that penetrates the multilayer wiring. The supporting pillar HR functions as a pillar that supports interlayer insulating films when gaps are formed in the region corresponding to the multilayer wiring in the production process, for example. The supporting pillar HR has a circular cross-sectional shape in the XY plane, for example. The supporting pillars HR are appropriately arranged in regions excluding the members SLT, SHE and SLTv and the contacts CC in the contact region CA. In this example, nine supporting pillars HR are arranged in the region corresponding to the string unit SU0. Between the contact CC in the vicinity of the memory region MA and the member SLTv_L, three supporting pillars HR are arranged side by side in the X direction. Between the member SLTv_L and the member SLTv_M, three supporting pillars HR are arranged side by side in the X direction. Between the member SLTv_M and the member SLTv_U, three supporting pillars HR are arranged side by side in the X direction. Similarly, nine supporting pillars HR are arranged in the region corresponding to the string unit SU2 and the region corresponding to the string unit SU4. The supporting pillar HR contains silicon oxide, for example.

The plan layout of the contact region CA of the memory cell array 10 included in the semiconductor storage device 3 may be other layouts. For example, the number and arrangement of the contacts CC and the supporting pillars HR can be modified as required.

### 1.1.4.6 Cross-Sectional Structure of Memory Region

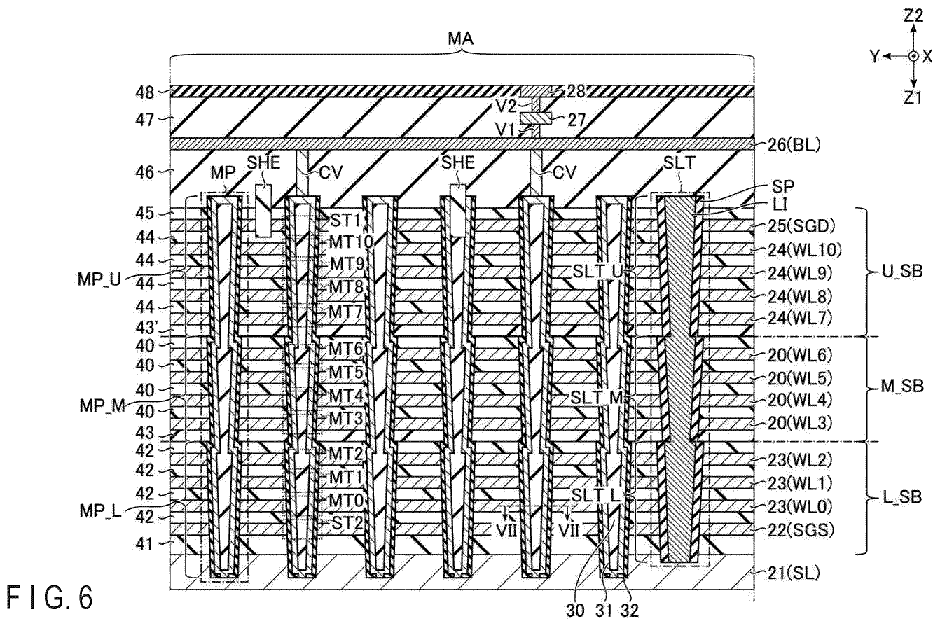

A cross-sectional structure of the memory region MA will be described with reference to FIG. 6. FIG. 6 is a cross-sectional view taken along the line VI-VI in FIG. 5, showing an example of the cross-sectional structure in the memory region MA of the memory cell array 10 included in the semiconductor storage device 3 according to the first embodiment. As shown in FIG. 6, in the memory region MA, the memory cell array 10 further includes wiring layers 20 to 28, insulator layers 40 to 43, 43′ and 44 to 48, and a plurality of contacts CV, V1 and V2. In the following description, it is assumed that the Z2 direction is the upward direction, and the Z1 direction is the downward direction.

The memory cell array 10 includes a lower laminate L_SB, a middle laminate M_SB and an upper laminate U_SB. The lower laminate L_SB includes a wiring layer 22 that corresponds to the selection gate line SGS and a plurality of wiring layers 23 that correspond to the word lines WL0 to WL2. The middle laminate M_SB is arranged above the lower laminate L_SB and includes a plurality of wiring layers 20 that correspond to the word lines WL3 to WL6. The upper laminate U_SB is arranged above the middle laminate M_SB and includes a plurality of wiring layers 24 that correspond to the word lines WL7 to WL10 and a wiring layer 25 that corresponds to the selection gate line SGD.

A wiring layer 21 is provided above a semiconductor substrate W2 (not shown). The wiring layer 21 is formed in the shape of a plate that extends in the X direction in the XY plane, for example. The wiring layer 21 is used as the source line SL. The wiring layer 21 contains silicon doped with phosphorus, for example.

On the wiring layer 21, the insulator layer 41 and the wiring layer 22 are stacked in this order. The insulator layer 41 contains silicon oxide (SiO₂), for example. The wiring layer 22 is formed in the shape of a plate that extends in the X direction in the XY plane, for example. The wiring layer 22 is used as the selection gate line SGS. The wiring layer 22 contains tungsten, for example.

On the wiring layer 22, the insulator layers 42 and the wiring layers 23 are alternately stacked. The insulator layer 42 contains silicon oxide, for example. The wiring layer 23 is formed in the shape of a plate that extends in the X direction in the XY plane, for example. Of the wiring layers 23, the one that is the closest to the wiring layer 22 is used as the word line WL0, the one that is the second closest to the wiring layer 22 is used as the word line WL1, and the one that is the third closest to the wiring layer 22 is used as the word line WL2. The wiring layer 22 contains tungsten, for example.

On the uppermost one of the insulator layers 42, the insulator layer 43 is provided. The insulator layer 43 contains tetra ethoxy silane (TEOS), for example. On the insulator layer 43, the wiring layers 20 and the insulator layers 40 are alternately stacked. The wiring layer 20 is formed in the shape of a plate that extends in the X direction in the XY plane, for example. Of the wiring layers 20, the one that is the closest to the insulator layer 43 is used as the word line WL3, the one that is the second closest to the insulator layer 43 is used as the word line WL4, the one that is the third closest to the insulator layer 43 is used as the word line WL5, and the one that is the fourth closest to the insulator layer 43 is used as the word line WL6. The wiring layer 20 contains tungsten, for example. The insulator layer 40 contains silicon oxide, for example.

On the uppermost one of the insulator layers 40, the insulator layer 43′ is provided. The insulator layer 43′ contains TEOS, for example. On the insulator layer 43′, the wiring layers 24 and the insulator layers 44 are alternately stacked. The wiring layer 24 is formed in the shape of a plate that extends in the X direction in the XY plane, for example. Of the wiring layers 24, the one that is the closest to the insulator layer 43′ is used as the word line WL7, the one that is the second closest to the insulator layer 43′ is used as the word line WL8, the one that is the third closest to the insulator layer 43′ is used as the word line WL9, and the one that is the fourth closest to the insulator layer 43′ is used as the word line WL10. The wiring layer 24 contains tungsten, for example. The insulator layer 44 contains silicon oxide, for example.

On the upper most one of the insulator layers 44, the wiring layer 25, the insulator layer 45 and the insulator layer 46 are stacked in this order. The wiring layer 25 is formed in the shape of a plate that extends in the X direction in the XY plane, for example. The wiring layer 25 is used as the selection gate line SGD. The wiring layer 25 contains tungsten, for example. The insulator layers 45 and 46 contain silicon oxide, for example.

On the insulator layer 46, the wiring layer 26 is provided. The wiring layer 26 is formed in a linear shape that extends in the Y direction, for example. The wiring layer 26 is used as the bit line BL. In a region not shown in the drawing, a plurality of wiring layers 26 are arranged in the X direction. The wiring layer 26 contains copper, for example.

On the wiring layer 26, the wiring layer 27 is provided. The wiring layer 27 is wiring that relays the connection between the bit line BL and the sense amplifier module 16. The wiring layer 26 and the wiring layer 27 are connected to each other by the contact V1. A wiring layer 28 is provided above the wiring layer 27. The wiring layer 28 corresponds to the bonding pad BP used for bonding. The wiring layer 27 and the wiring layer 28 are connected to each other by the contact V2. A side face of each of the wiring layer 27 and the contacts V1 and V2 is covered by an insulator layer 47. The insulator layer 47 may be formed by a plurality of layers of insulating films. A side face of the wiring layer 28 is covered by an insulator layer 48. The memory cell array 10 may include a plurality of wiring layers 27 and a plurality of wiring layers 28. The wiring layers 27 and 28 contain copper, for example.

Each memory pillar MP is provided to extend in the Z direction and has a cylindrical shape, for example. Each memory pillar MP includes a lower pillar part MP_L, a middle pillar part MP_M and an upper pillar part MP_U. The lower pillar part MP_L penetrates the wiring layer 22 and the plurality of wiring layers 23 in the Z direction. The middle pillar part MP_M penetrates the plurality of wiring layers 20 in the Z direction. The upper pillar part MP_U penetrates the plurality of wiring layers 24 and the wiring layer 25 in the Z direction. The upper end of the lower pillar part MP_L and the lower end of the middle pillar part MP_M are in contact with each other at the interface between the insulator layer 42 and the insulator layer 43. The upper end of the middle pillar part MP_M and the lower end of the upper pillar part MP_U are in contact with each other at the interface between the insulator layer 40 and the insulator layer 43′. For example, each of the lower pillar part MP_L, the middle pillar part MP_M and the upper pillar part MP_U increases in cross-sectional area in the XY plane (XY cross-sectional area) from the bottom to the top. At the juncture between the lower pillar part MP_L and the middle pillar part MP_M, the side face of the lower pillar part MP_L and the side face of the middle pillar part MP_M are offset from each other. At the juncture between the middle pillar part MP_M and the upper pillar part MP_U, the side face of the middle pillar part MP_M and the side face of the upper pillar part MP_U are offset from each other. Note that the side face of the lower pillar part MP_L and the side face of the middle pillar part MP_M need not be offset from each other. The side face of the middle pillar part MP_M and the side face of the upper pillar part MP_U need not be offset from each other.

Furthermore, each memory pillar MP includes a core film 30, a semiconductor film 31 and a laminate film 32. The core film 30 is provided to extend in the Z direction. For example, the upper end of the core film 30 is located in the insulator layer 47, and the lower end of the core film 30 is located in the wiring layer 21. The core film 30 contains an insulator, such as silicon oxide, for example. The semiconductor film 31 covers the periphery of the core film 30, for example. At the lower end of the memory pillar MP, a part of the semiconductor film 31 is in contact with the wiring layer 21. The semiconductor film 31 contains silicon, for example. The laminate film 32 covers a side face and a bottom face of the semiconductor film 31 excluding the part of the semiconductor film 31 that is in contact with the wiring layer 21.

In the structure of the memory pillar MP shown in FIG. 6, the part of the memory pillar MP that intersects with the wiring layer 22 functions as the selection transistor ST2. The parts of the memory pillar MP that intersects with the wiring layers 23, 20 and 24 function as the memory cell transistors MT0 to MT10. The part of the memory pillar MP that intersects with the wiring layer 25 functions as the selection transistor ST1.

On an upper face of the semiconductor film 31 in the memory pillar MP, a contact CV having a columnar shape is provided. In the region shown in FIG. 6, two contacts CV associated with two memory pillars MP of the six memory pillars MP are shown. A memory pillar MP that is not overlaid with any member SHE and is not connected to any contact CV in this region is connected to another contact CV in a region not shown.

An upper face of each contact CV is in contact with one wiring layer 26, that is, one bit line BL. One contact CV is connected to one wiring layer 26 in each space partitioned by the members SLT and SHE. That is, each wiring layer 26 is electrically connected to one memory pillar MP in each of the regions between the members SLT and SHE adjacent to each other and to one memory pillar MP in each of the regions between two adjacent members SHE.

The member SLT is formed to spread along the XZ plane. The lower member SLT_L extends in the Z direction and the X direction and divides the wiring layer 22 and the plurality of wiring layers 23 in the Y direction. The middle member SLT_M extends in the Z direction and the X direction and divides the plurality of wiring layers 20 in the Y direction. The upper member SLT_U extends in the Z direction and the X direction and divides the plurality of wiring layers 24 and the wiring layer 25 in the Y direction. The upper end of the lower member SLT_L and the lower end of the middle member SLT_M are in contact with each other at the interface between the insulator layer 42 and the insulator layer 43. The upper end of the middle member SLT_M and the lower end of the upper member SLT_U are in contact with each other at the interface between the insulator layer 40 and the insulator layer 43′. For example, each of the lower member SLT_L, the middle member SLT_M and the upper member SLT_U increases in cross-sectional area in the XY plane (XY cross-sectional area) from the bottom to the top. At the juncture between the lower member SLT_L and the middle member SLT_M, the side face of the lower member SLT_L and the side face of the middle member SLT_M are offset from each other. At the juncture between the middle member SLT_M and the upper member SLT_U, the side face of the middle member SLT_M and the side face of the upper member SLT_U are offset from each other.

In the member SLT, the contact LI is provided to spread in the XZ plane, and the spacer SP is provided between the contact LI and the wiring layers 20 and 22 to 25. The upper end of the contact LI is located in the insulator layer 46, for example. The lower end of the contact LI is located in the wiring layer 21, for example. The spacer SP contains silicon oxide, for example. The contact LI contains tungsten, for example. Note that the contact LI may be omitted, depending on the structure of the memory cell array 10.

The member SHE is formed in the shape of a plate that spreads in the XZ plane and divides the wiring layer 25 in the Y direction, for example. The upper end of the member SHE is located in the insulator layer 46. The lower end of the member SHE is located in the uppermost one of the insulator layers 44, for example. The member SHE contains an insulator, such as silicon oxide, for example. Note that the upper end of the member SHE and the upper end of the member SLT may or may not be aligned with each other. Furthermore, the upper end of the member SHE and the upper end of the memory pillar MP may or may not be aligned with each other.

### 1.1.4.7 Cross-Sectional Structure of Memory Pillar

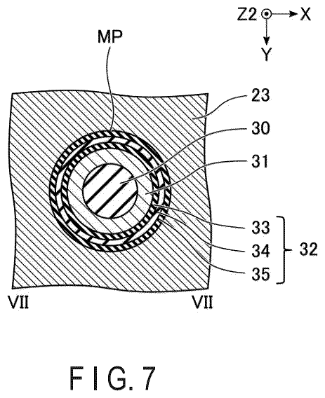

A cross-sectional structure of the memory pillar MP will be described with reference to FIG. 7. FIG. 7 is a cross-sectional view taken along the line VII-VII in FIG. 6, showing an example of the cross-sectional structure of the memory pillar MP included in the semiconductor storage device 3 according to the first embodiment. More specifically, FIG. 7 shows a cross-sectional structure of the memory pillar MP in a layer including the wiring layer 23. As shown in FIG. 7, the laminate film 32 includes a tunnel insulating film 33, an insulating film 34 and a block insulating film 35. The tunnel insulating film 33 surrounds a side face of the semiconductor film 31. The insulating film 34 surrounds a side face of the tunnel insulating film 33. The block insulating film 35 surrounds a side face of the insulating film 34. The wiring layer 23 surrounds a side face of the block insulating film 35. The tunnel insulating film 33 and the block insulating film 35 each contain silicon oxide, for example. The insulating film 34 is used as a charge storage layer of the memory cell transistor MT. The insulating film 34 contains silicon nitride (SiN), for example.

### 1.1.4.8 Cross-Sectional Structure of Contact Region

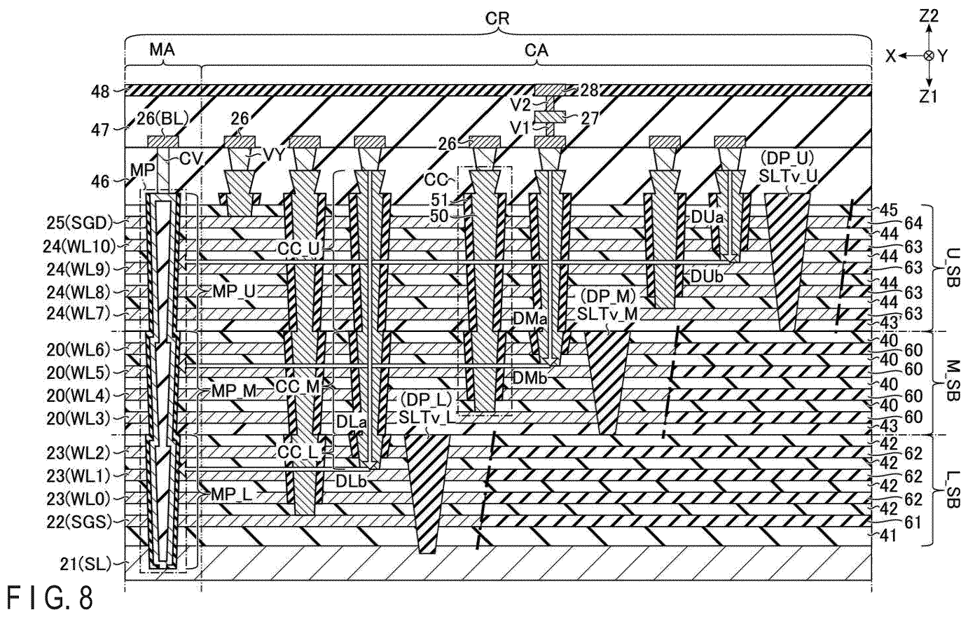

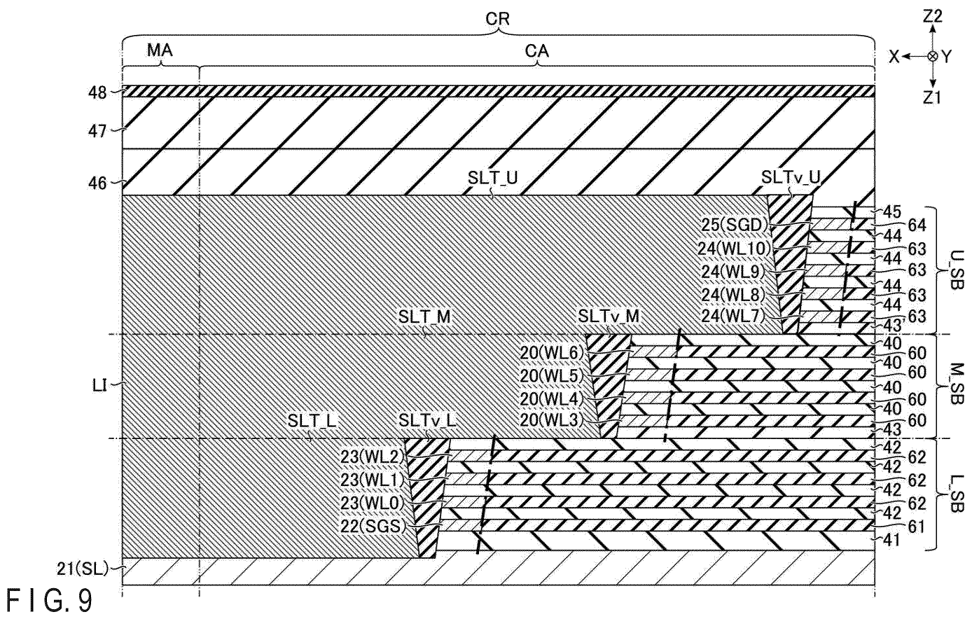

A cross-sectional structure of the contact region CA will be described with reference to FIGS. 8 and 9. FIG. 8 is a cross-sectional view taken along the line VIII-VIII in FIG. 5, showing an example of the cross-sectional structure in the contact region CA of the memory cell array 10 included in the semiconductor storage device 3 according to the first embodiment. FIG. 8 also shows a cross-sectional structure in the memory region MA in the vicinity of the contact region CA. The cross-sectional structure in the memory region MA is the same as that shown in FIG. 6. As shown in FIG. 8, in the contact region CA, the memory cell array 10 further includes the wiring layers 20 to 28, the insulator layers 40 to 43, 43′ and 44 to 48, insulator layers 60 to 64, a plurality of contacts VY, and the contacts V1 and V2. In the following description, it is assumed that the Z2 direction is the upward direction, and the Z1 direction is the downward direction.

The lower laminate L_SB further includes an insulator layer 61 and a plurality of insulator layers 62 provided in the same layers as the wiring layer 22 and the plurality of wiring layers 23, respectively. The middle laminate M_SB further includes a plurality of insulator layers 60 provided in the same layer as the plurality of wiring layers 20. The upper laminate U_SB further includes a plurality of insulator layers 63 and an insulator layer 64 provided in the same layers as the plurality of wiring layers 24 and the wiring layer 25, respectively.

Each contact CC is provided to extend in the Z direction and has a cylindrical shape, for example. The plurality of contacts CC are provided on the selection gate line SGS, the word lines WL0 to WL10 and the selection gate line SGD.

First, the contact CC provided on each of the selection gate line SGS and the word lines WL0 to WL2 (referred to as a “lower wiring contact CC” hereinafter) will be described. Each lower wiring contact CC includes a lower contact part CC_L, a middle contact part CC_M and an upper contact part CC_U.

The lower contact part CC_L extends in the Z direction and is connected to any of the wiring layer 22 and the plurality of wiring layers 23. In other words, the lower contact part CC_L penetrates the wiring layers 23 and the insulator layers 42 above the wiring layer to which the contact CC is connected (any of the selection gate line SGS and the word lines WL0 to WL2). The lower contact part CC_L includes the conductor 50 and the insulator 51 that covers at least a part of the side face of the conductor 50. The middle contact part CC_M is provided on the lower contact part CC_L and penetrates the plurality of wiring layers 20, the insulator layer 43 and the plurality of insulator layers 40 in the Z direction. The upper end of the lower contact part CC_L and the lower end of the middle contact part CC_M are in contact with each other at the interface between the insulator layer 42 and the insulator layer 43. The middle contact part CC_M includes the conductor 50 and the insulator 51 that covers a side face of the conductor 50. The upper contact part CC_U is provided on the middle contact part CC_M and penetrates the plurality of wiring layers 24, the wiring layer 25, the insulator layer 43′, the plurality of insulator layers 44 and the insulator layer 45 in the Z direction. The upper end of the middle contact part CC_M and the lower end of the upper contact part CC_U are in contact with each other at the interface between the insulator layer 40 and the insulator layer 43′. The upper contact part CC_U includes the conductor 50 and the insulator 51 that covers at least a part of the side face of the conductor 50.

The upper end of the conductor 50 is located in the insulator layer 46, and the lower end of the conductor 50 is in contact with the wiring layer to which the conductor 50 is connected. The upper end of the insulator 51 is located at a lower level than the upper end of the conductor 50 in the insulator layer 46, and the lower end of the insulator 51 is in contact with the insulator layer 42 on the wiring layer to which the conductor 50 is connected. That is, the insulator 51 covers the side face of the conductor 50 excluding the top part and the bottom part of the conductor 50.

As described above, the lower wiring contact CC extends in the Z direction, penetrates the middle laminate M_SB (the plurality of wiring layers 20) and the upper laminate U_SB (the plurality of wiring layers 24 and the wiring layer 25) and is connected to any of the wiring layer 22 and the plurality of wiring layers 23, and at least a part of the side face of the lower wiring contact CC is covered by the insulator 51.

Next, the contact CC provided on each of the word lines WL3 to WL6 (referred to as a “middle wiring contact CC” hereinafter) will be described. Each middle wiring contact CC includes a middle contact part CC_M and an upper contact part CC_U.

The middle contact part CC_M extends in the Z direction and is connected to any of the plurality of wiring layers 20. In other words, the middle contact part CC_M penetrates the wiring layers 20 and the insulator layers 40 above the wiring layer to which the contact CC is connected (any of the word lines WL3 to WL6). The middle contact part CC_M includes the conductor 50 and the insulator 51 that covers at least a part of the side face of the conductor 50. The upper contact part CC_U is provided on the middle contact part CC_M and penetrates the plurality of wiring layers 24, the wiring layer 25, the insulator layer 43′, the plurality of insulator layers 44 and the insulator layer 45 in the Z direction. The upper end of the middle contact part CC_M and the lower end of the upper contact part CC_U are in contact with each other at the interface between the insulator layer 40 and the insulator layer 43′. The upper contact part CC_U includes the conductor 50 and the insulator 51 that covers at least a part of the side face of the conductor 50.

The upper end of the conductor 50 is located in the insulator layer 46, and the lower end of the conductor 50 is in contact with the wiring layer to which the conductor 50 is connected. The upper end of the insulator 51 is located at a lower level than the upper end of the conductor 50 in the insulator layer 46, and the lower end of the insulator 51 is in contact with the insulator layer 40 on the wiring layer to which the conductor 50 is connected. That is, the insulator 51 covers the side face of the conductor 50 excluding the top part and the bottom part of the conductor 50.

As described above, the middle wiring contact CC extends in the Z direction, penetrates the upper laminate U_SB (the plurality of wiring layers 24 and the wiring layer 25) and is connected to any of the plurality of wiring layers 20, and at least a part of the side face of the middle wiring contact CC is covered by the insulator 51.

Next, the contact CC provided on each of the word lines WL7 to WL10 and the selection gate line SGD (referred to as an “upper wiring contact CC” hereinafter) will be described. Each upper wiring contact CC includes an upper contact part CC_U.

The upper contact part CC_U extends in the Z direction and is connected to any of the plurality of wiring layers 24 and the wiring layer 25. In other words, the upper contact part CC_U associated with any of the word lines WL7 to WL10 penetrates the wiring layers 24, the wiring layer 25 and the insulator layers 44 and 45 above the wiring layer to which the contact CC is connected. The upper contact part CC_U associated with the selection gate line SGD penetrates the insulator layer 45 on the selection gate line SGD. The upper contact part CC_U includes the conductor 50 and the insulator 51 that covers at least a part of the side face of the conductor 50.

The upper end of the conductor 50 is located in the insulator layer 46, and the lower end of the conductor 50 is in contact with the wiring layer to which the conductor 50 is connected. The upper end of the insulator 51 is located at a lower level than the upper end of the conductor 50 in the insulator layer 46, and the lower end of the insulator 51 is in contact with the insulator layer 44 or 45 on the wiring layer to which the conductor 50 is connected. That is, the insulator 51 covers the side face of the conductor 50 excluding the top part and the bottom part of the conductor 50.

As described above, the upper wiring contact CC extends in the Z direction and is connected to any of the plurality of wiring layers 24 and the wiring layer 25, and at least a part of the side face of the upper wiring contact CC is covered by the insulator 51.

For example, each of the lower contact part CC_L and the middle contact part CC_M increases in cross-sectional area in the XY plane (XY cross-sectional area) from the bottom to the top. In addition, the part of the upper contact part CC_U below the top part in which the conductor 50 is not covered by the insulator 51 increases in cross-sectional area in the XY plane from the bottom to the top. The top part of the upper contact part CC_U in which the conductor 50 is not covered by the insulator 51 also increases in cross-sectional area in the XY plane from the bottom to the top. At the juncture between the lower contact part CC_L and the middle contact part CC_M, the side face of the lower contact part CC_L and the side face of the middle contact part CC_M are offset from each other. At the juncture between the middle contact part CC_M and the upper contact part CC_U, the side face of the middle contact part CC_M and the side face of the upper contact part CC_U are offset from each other.

Each of the member SLTv_L (dividing portion DP_L), the member SLTv_M (dividing portion DP_M) and the member SLTv_U (dividing portion DP_U) is formed to spread in the YZ plane, for example. The member SLTv_L extends in the Z direction and the Y direction and divides the wiring layer 22 and the plurality of wiring layers 23 in the X direction. The position of the upper end of the member SLTv_L is at the same level as the interface between the insulator layer 42 and the insulator layer 43, for example. The lower end of the member SLTv_L is located in the wiring layer 21, for example. The member SLTv_M extends in the Z direction and the Y direction and divides the plurality of wiring layers 20 in the X direction. The position of the upper end of the member SLTv_M is at the same level as the interface between the insulator layer 40 and the insulator layer 43′, for example. The position of the lower end of the member SLTv_M is at the same level as the interface between the insulator layer 42 and the insulator layer 43, for example. The member SLTv_U extends in the Z direction and the Y direction and divides the plurality of wiring layers 24 and the wiring layer 25 in the X direction. The upper end of the member SLTv_U is located in the insulator layer 46, for example. The position of the lower end of the member SLTv_U is at the same level as the interface between the insulator layer 40 and the insulator layer 43′, for example. For example, each of the member SLTv_L, the member SLTv_M and the member SLTv_U increases in cross-sectional area in the XY plane (XY cross-sectional area) from the bottom to the top. The members SLTv_L, SLTv_M and SLTv_U each contain silicon oxide, for example.

The member SLTv_L is disposed at a position closer to the memory pillar MP than the member SLTv_M. The member SLTv_M is disposed at a position closer to the memory pillar MP than the member SLTv_U. In other words, the member SLTv_U does not overlap with the member SLTv_L and the member SLTv_M in the Z direction, and the member SLTv_M does not overlap with the member SLTv_L in the Z direction.

The lower wiring contacts CC and the contact CC connected to the selection gate line SGD among the upper wiring contacts CC are disposed in the region between (e.g., laterally between) the memory pillar MP and the member SLTv_L. The middle wiring contacts are disposed in the region between the member SLTv_L and the member SLTv_M. The upper wiring contacts CC excluding the contact CC connected to the selection gate line SGD are disposed in the region between the member SLTv_M and the member SLTv_U.

The insulator layer 61 and the plurality of insulator layers 62 are disposed at positions farther from the memory pillar MP than the member SLTv_L. In other words, the member SLTv_L is disposed closer to the memory pillar MP than the insulator layer 61 and the plurality of insulator layers 62. In a region farther from the memory pillar MP than the member SLTv_L, the insulator layer 41 and the insulator layer 61 are stacked on the wiring layer 21 in this order. The insulator layer 61 is provided in the same layer as the wiring layer 22. On the insulator layer 61, the insulator layers 42 and the insulator layers 62 are alternately stacked. Each of the plurality of insulator layers 62 is provided in the same layer as one of the plurality of wiring layers 23. The insulator layer 61 and the plurality of insulator layers 62 are in contact with the wiring layer 22 and the plurality of wiring layers 23, respectively, at positions farther from the memory pillar MP than the member SLTv_L. In other words, in a region farther from the memory pillar MP than the member SLTv_L, the lower laminate L_SB includes the wiring layer 22, the plurality of wiring layers 23, the insulator layer 61 and the plurality of insulator layers 62. The insulator layers 61 and 62 contain silicon nitride, for example.

The plurality of insulator layers 60 are disposed at positions farther from the memory pillar MP than the member SLTv_M. In other words, the member SLTv_M is disposed closer to the memory pillar MP than the plurality of insulator layers 60. In addition, the member SLTv_M is disposed above the insulator layer 61 and the plurality of insulator layers 62. In a region farther from the memory pillar MP than the member SLTv_M, the insulator layer 43 is stacked on the uppermost one of the insulator layers 42. On the insulator layer 43, the insulator layers 60 and the insulator layers 40 are alternately stacked. Each of the plurality of insulator layers 60 is provided in the same layer as one of the plurality of wiring layers 20. The plurality of insulator layers 60 are in contact with the plurality of wiring layers 20, respectively, at positions farther from the memory pillar MP than the member SLTv_M. In other words, in a region farther from the memory pillar MP than the member SLTv_M, the middle laminate M_SB includes the plurality of wiring layers 20 and the plurality of insulator layers 60. The insulator layers 60 contain silicon nitride, for example.

The plurality of insulator layers 63 and the insulator layer 64 are disposed at positions farther from the memory pillar MP than the member SLTv_U. In other words, the member SLTv_U is disposed closer to the memory pillar MP than the plurality of insulator layers 63 and the insulator layer 64. In addition, the member SLTv_U is disposed above the plurality of insulator layers 60. In a region farther from the memory pillar MP than the member SLTv_U, the insulator layer 43′ is stacked on the uppermost one of the insulator layers 40. On the insulator layer 43′, the insulator layers 63 and the insulator layers 44 are alternately stacked. Each of the plurality of insulator layers 63 is provided in the same layer as one of the plurality of wiring layers 24. On the uppermost one of the insulator layers 44, the insulator layer 64, the insulator layer 45 and the insulator layer 46 are stacked in this order. The insulator layer 64 is provided in the same layer as the wiring layer 25. The plurality of insulator layers 63 and the insulator layer 64 are in contact with the plurality of wiring layers 24 and the wiring layer 25, respectively, at positions farther from the memory pillar MP than the member SLTv_U. In other words, in a region farther from the memory pillar MP than the member SLTv_U, the upper laminate U_SB includes the plurality of wiring layers 24, the wiring layer 25, the plurality of insulator layers 63 and the insulator layer 64. The insulator layers 63 and 64 contain silicon nitride, for example.

On each of the plurality of contacts CC (the plurality of conductors 50), one contact VY is provided. That is, a contact VY is connected to the upper end of each of the lower wiring contacts CC. A contact VY is connected to the upper end of each of the middle wiring contacts CC. A contact VY is connected to the upper end of each of the upper wiring contacts CC. On each of the plurality of contacts VY, one wiring layer 26 is provided. On each wiring layer 26, a contact V1 is provided. FIG. 8 shows only the contact V1 associated with the word line WL5 among the plurality of contacts V1. On the contact V1, the wiring layer 27 is provided. On the wiring layer 27, a contact V2 is provided. The wiring layers 26 and 27 and the contacts V1 and V2 are covered by the insulator layer 47. On the contact V2, the wiring layer 28 penetrating the insulator layer 48 is provided.

Here, the distance from the upper end of the lower wiring contact CC to the lower end of the lower wiring contact CC that is in contact with the wiring layer is referred to as a “distance DLa”, and the distance from the lower end of the lower wiring contact CC to the memory pillar MP is referred to as a “distance DLb”. The distance from the upper end of the middle wiring contact CC to the lower end of the middle wiring contact CC that is in contact with the wiring layer is referred to as a “distance DMa”, and the distance from the lower end of the middle wiring contact CC to the memory pillar MP is referred to as a “distance DMb”. The distance from the upper end of the upper wiring contact CC to the lower end of the upper wiring contact CC that is in contact with the wiring layer is referred to as a “distance DUa”, and the distance from the lower end of the upper wiring contact CC to the memory pillar MP is referred to as a “distance DUb”. The sum of the distance DLa and the distance DLb, the sum of the distance DMa and the distance DMb and the sum of the distance DUa and the distance DUb are balanced (e.g., about equal).

The set of the wiring layers 26, 27 and 28 and the contacts CC, VY, V1 and V2 described above corresponds to wiring and contacts for connecting any of the wiring layers 20 and 22 to 25 and the row decoder module 15 to each other. Although not shown, each of the wiring layers 20 and 22 to 25 other than the word line WL5 is also connected to the row decoder module 15 via a set of wiring layers 26, 27 and 28 and contacts CC, VY, V1 and V2.

FIG. 9 is a cross-sectional view taken along the line IX-IX in FIG. 5, showing an example of the cross-sectional structure in the contact region CA of the memory cell array 10 included in the semiconductor storage device 3 according to the first embodiment. FIG. 9 also shows a cross-sectional structure in the memory region MA in the vicinity of the contact region CA. As shown in FIG. 9, in the contact region CA, the cross-sectional structure in the region farther from the memory region MA than the member SLTv_L, the cross-sectional structure in the region farther from the memory region MA than the member SLTv_M and the cross-sectional structure in the region farther from the memory region MA than the member SLTv_U are the same as those shown in FIG. 8.

In the region closer to the memory region MA than the member SLTv in the contact region CA, the lower member SLT_L is in contact with the member SLTv_L and penetrates the wiring layer 22 and the plurality of wiring layers 23. The position of the upper end of the lower member SLT_L is at the same level as the position of the upper end of the member SLTv_L, for example. The position of the lower end of the lower member SLT_L is at the same level as the position of the lower end of the member SLTv_L, for example. The middle member SLT_M is in contact with the member SLTv_M and penetrates the plurality of wiring layers 20. The position of the upper end of the middle member SLT_M is at the same level as the position of the upper end of the member SLTv_M, for example. The position of the lower end of the middle member SLT_M is at the same level as the position of the lower end of the member SLTv_M, for example. The upper member SLT_U is in contact with the member SLTv_U and penetrates the plurality of wiring layers 24 and the wiring layer 25. The position of the upper end of the upper member SLT_U is at the same level as the position of the upper end of the member SLTv_U, for example. The position of the lower end of the upper member SLT_U is at the same level as the position of the lower end of the member SLTv_U, for example. The cross-sectional structure in the memory region MA has the same structure.

Note that the member SLTv_L may be provided directly below the middle wiring contact CC. The member SLTv_M may be provided directly below the upper wiring contact CC.

### 1.2 Production Method for Semiconductor Storage Device

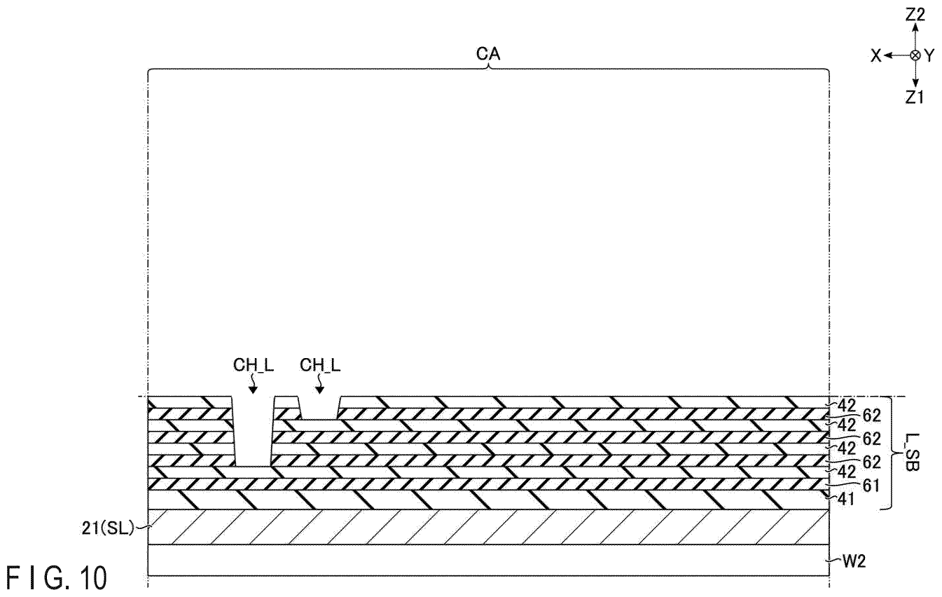

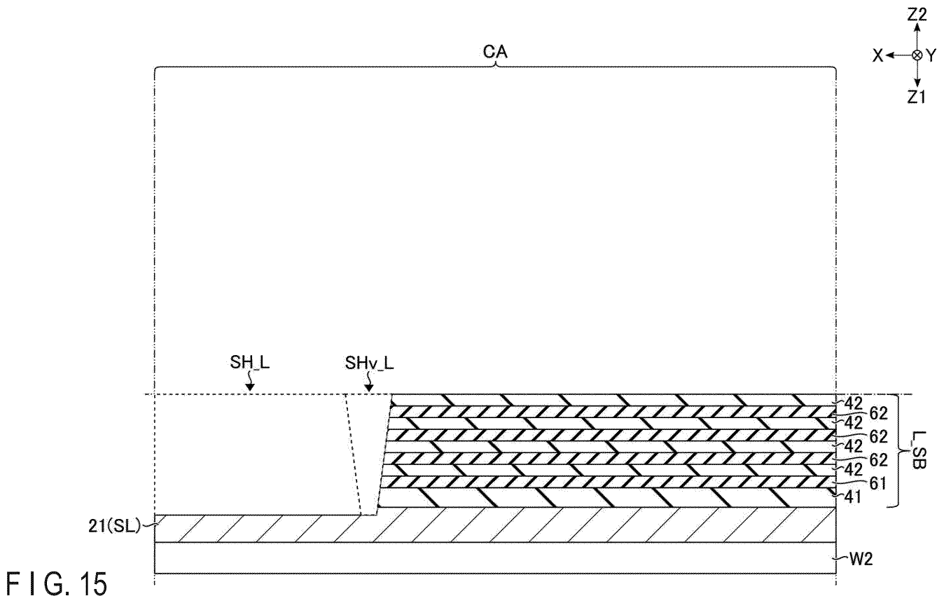

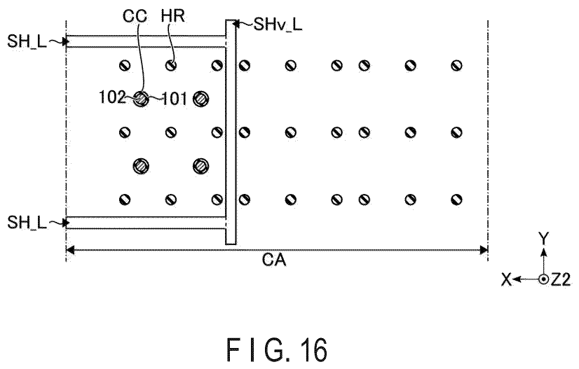

A production method for the semiconductor storage device 3 according to the first embodiment will be described with reference to FIGS. 10 to 37. FIGS. 10 to 15, 17, 18, 20, 21, 23, 24, 26, 27, 29 to 32 and 34 to 36 are cross-sectional views showing examples of the cross-sectional structure during production of the semiconductor storage device 3 according to the first embodiment. FIGS. 10 to 14, 17, 20, 23, 26, 29, 31 and 34 to 36 show cross-sectional structures corresponding to FIG. 8. FIGS. 15, 18, 21, 24, 27, 30 and 32 show cross-sectional structures corresponding to FIG. 9. FIGS. 16, 19, 22, 25, 28, 33 and 37 are plan views showing examples of the plan structure during production of the semiconductor storage device 3 according to the first embodiment. In FIGS. 16, 19, 22, 25, 28, 33 and 37, illustration of the interlayer insulating film is omitted. In the following, description of the step of forming the supporting pillar HR will be omitted.

In this embodiment, a case will be described in which as a method of forming the wiring layers 20 and 22 to 25 that correspond to the selection gate line SGS, the word lines WL0 to WL10 and the selection gate line SGD, for example, a method of forming structures corresponding to the wiring layers 22, 23, 20, 24 and 25 by the insulator layers 61, 62, 60, 63 and 64, respectively, and then replacing the insulator layers 61, 62, 60, 63 and 64 with a conductive material to form the wiring layers 22, 23, 20, 24 and 25 (referred to as a “replacement process” hereinafter) is used. In the following, the insulator layers 60 to 64 may be referred to also as “sacrificial members 60 to 64”.

First, as shown in FIG. 10, on the semiconductor substrate W2, the wiring layer 21, the insulator layer 41 and the sacrificial member 61 are stacked in this order. Then, on the sacrificial member 61, four insulator layers 42 and three sacrificial members 62 are alternately stacked one on another. The wiring layer 21 contains polysilicon, for example. The insulator layers 41 and 42 contains silicon oxide, for example. The sacrificial members 61 and 62 contain silicon nitride, for example. Then, although not shown, a hole corresponding to the lower pillar part MP_L is formed, and the hole is filled with a sacrificial member.

Then, as shown in FIG. 10, a hole CH_L corresponding to the lower contact part CC_L is provided. For example, a mask having an opening in a region corresponding to the hole CH_L is formed by photolithography or the like, and the hole CH_L is formed by anisotropic etching using the mask. The lower end of the hole CH_L corresponding to the selection gate line SGS reaches the upper face of the lowermost one of the insulator layers 42. The lower end of the hole CH_L corresponding to the word line WL1 reaches the upper face of the second uppermost one of the insulator layers 42.

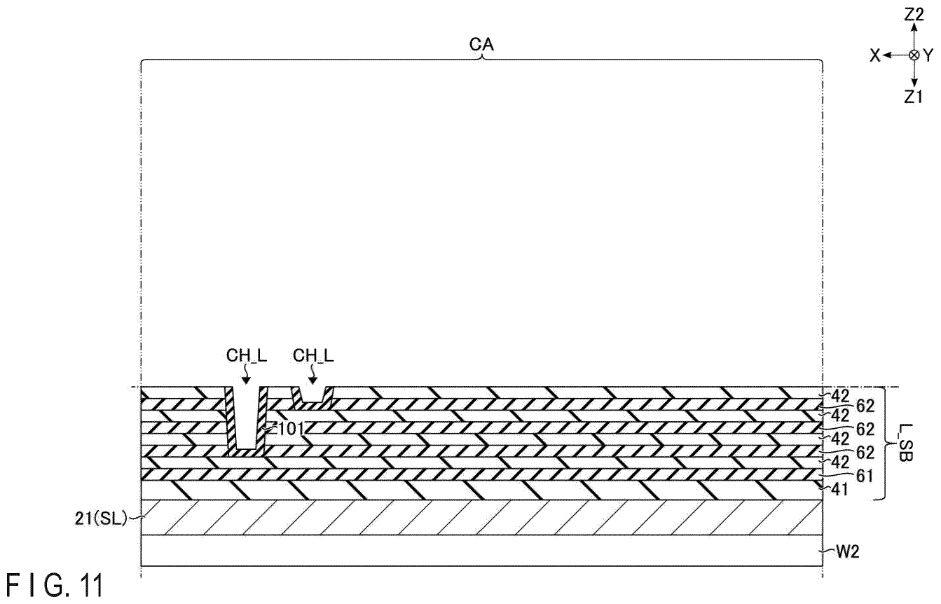

Then, as shown in FIG. 11, an insulator 101 is provided in the hole CH_L. In this way, the side face and the bottom face of the hole CH_L are covered by the insulator 101. The insulator 101 contains silicon oxide, for example.

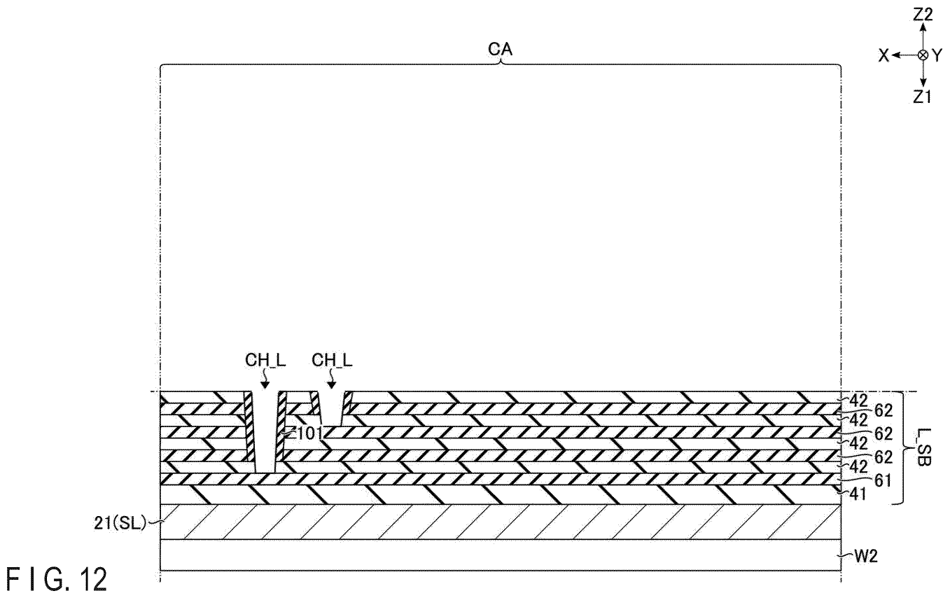

Then, as shown in FIG. 12, the insulator 101 on the bottom face of the hole CH_L is removed by anisotropic etching, for example. In this step, of the insulator layer 42 in contact with the bottom face of the hole CH_L corresponding to the selection gate line SGS, a part located below the removed insulator 101 is also removed. As a result, in the hole CH_L corresponding to the selection gate line SGS, the insulator layer 61 is exposed. In addition, of the insulator layer 42 in contact with the bottom face of the hole CH_L corresponding to the word line WL1, a part located below the removed insulator 101 is also removed. As a result, in the hole CH_L corresponding to the word line WL1, the second uppermost one of the insulator layers 62 is exposed. In the following, this step may be referred to also as a “bottom removal step”.

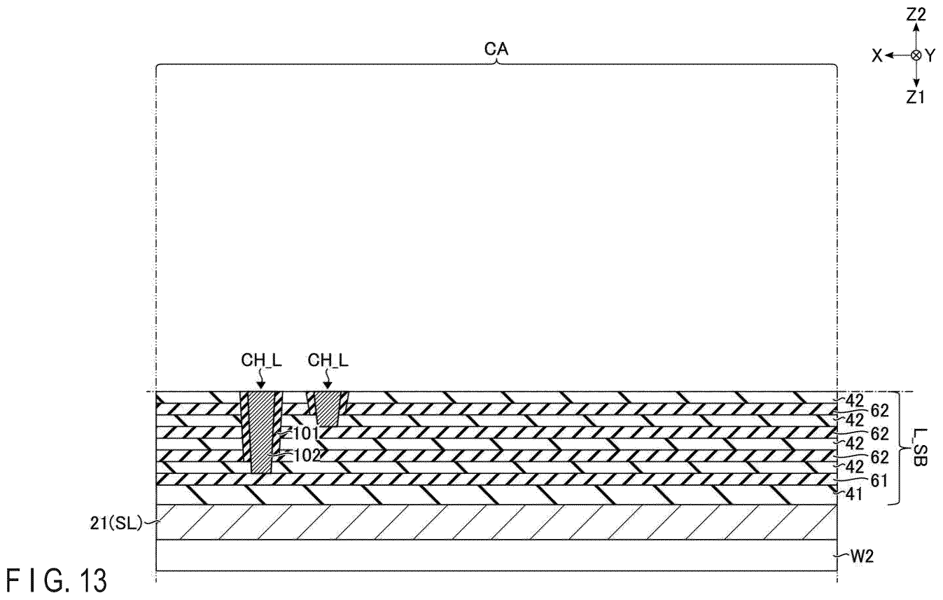

Then, as shown in FIG. 13, the hole CH_L is filled with a sacrificial member 102. The sacrificial member 102 contains polysilicon, for example.

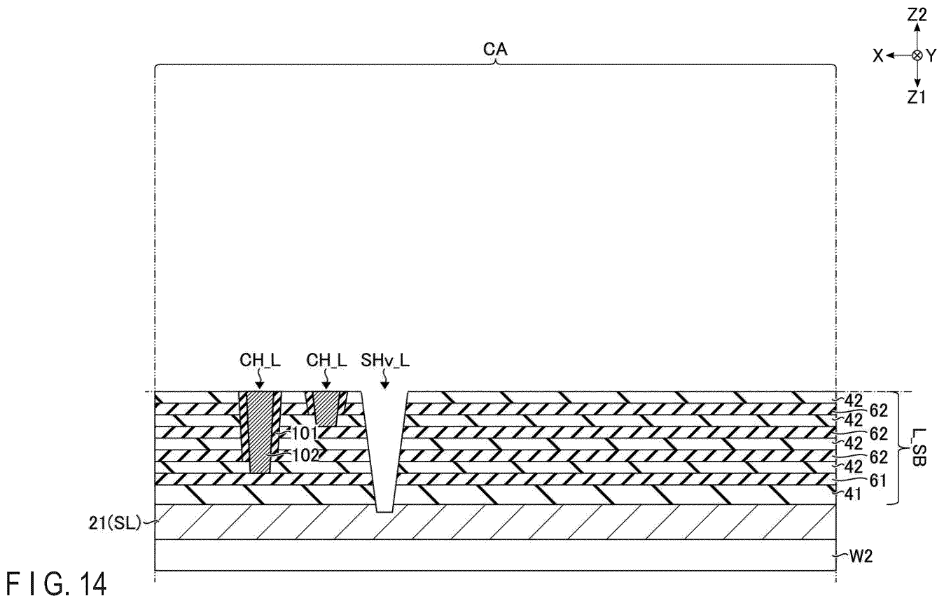

Then, as shown in FIGS. 14 and 15, a hole SHv_L corresponding to the member SLTv_L and a hole SH_L corresponding to the lower member SLT_L are provided. For example, a mask having openings in regions corresponding to the holes SHv_L and SH_L is formed by photolithography or the like, and the holes SHv_L and SH_L are formed by anisotropic etching using the mask. The lower ends of the holes SHv_L and SH_L reach into the wiring layer 21. FIG. 16 shows a plan structure of the lower laminate L_SB after the holes SHv_L and SH_L are formed viewed from above.

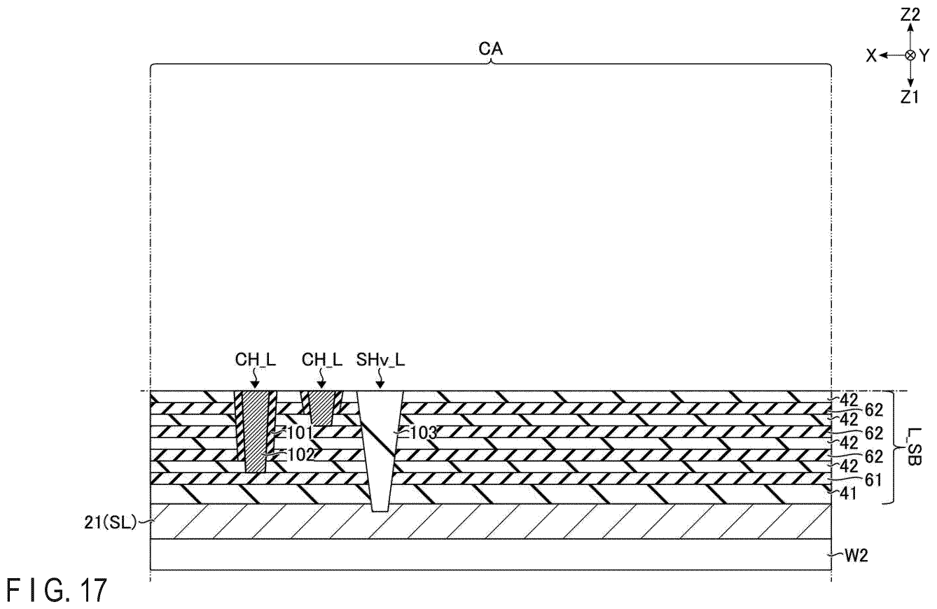

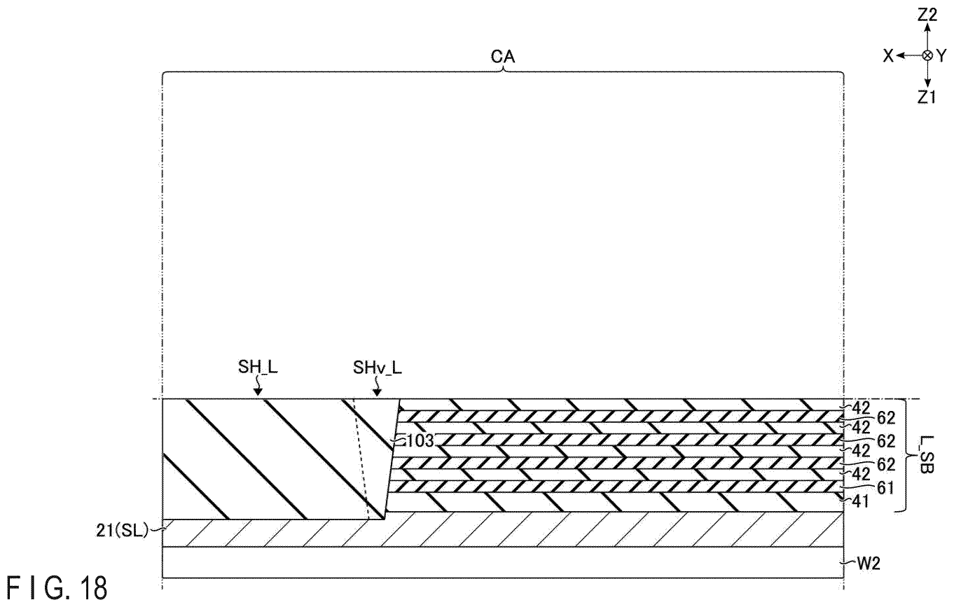

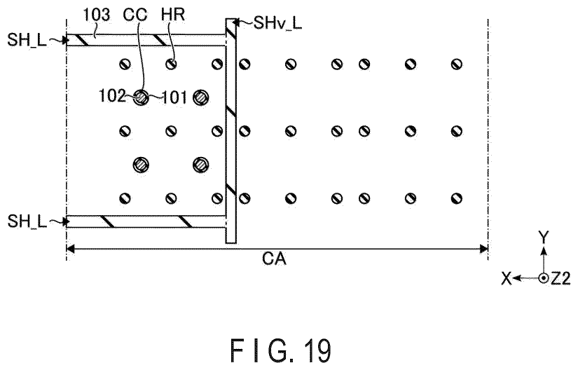

Then, as shown in FIGS. 17 and 18, the holes SHv_L and SH_L are filled with a sacrificial member 103. FIG. 19 shows a plan structure of the lower laminate L_SB after the holes SHv_L and SH_L are filled with the sacrificial member 103 viewed from above.

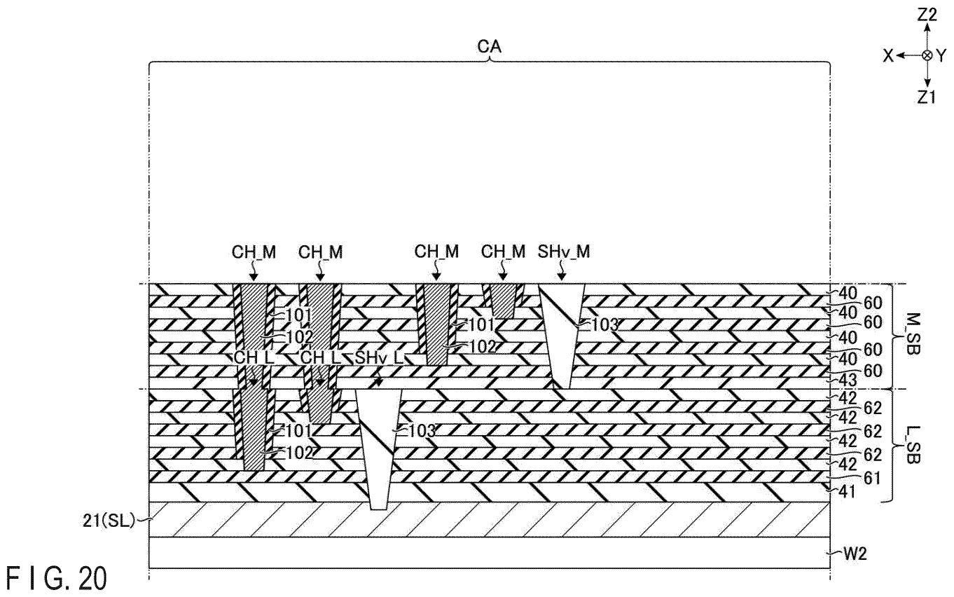

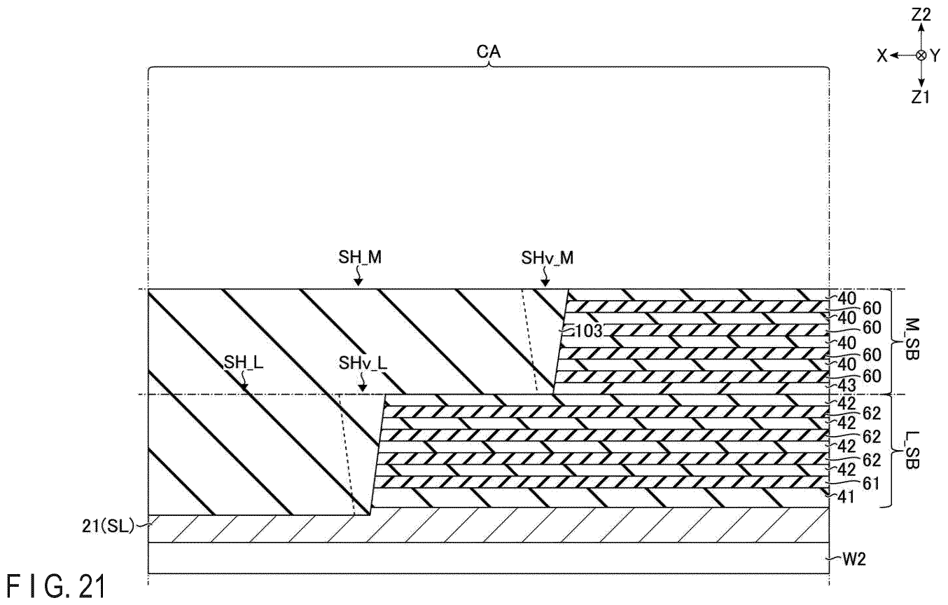

Then, as shown in FIGS. 20 and 21, on the uppermost one of the insulator layers 42, the insulator layer 43 is provided. Then, on the insulator layer 43, four sacrificial members 60 and four insulator layers 40 are alternately stacked one on another. The insulator layer 43 contains TEOS, for example. The insulator layers 40 contain silicon oxide, for example. The sacrificial member 60 contains silicon nitride, for example. Then, although not shown, a hole corresponding to the middle pillar part MP_M is formed, and the hole is filled with a sacrificial member.

Then, as shown in FIGS. 20 and 21, as with the hole CH_L, a hole CH_M corresponding to the middle contact part CC_M is provided. The lower end of the hole CH_M corresponding to the selection gate line SGS and the lower end of the hole CH_M corresponding to the word line WL1 reach the upper face of the hole CH_L. The lower end of the hole CH_M corresponding to the word line WL3 reaches the upper face of the lowermost one of the insulator layers 40. The lower end of the hole CH_M corresponding to the word line WL5 reaches the upper face of the second uppermost one of the insulator layers 40. Then, as with the holes CH_L, after the forming step for the insulator 101 and the bottom removal step are performed for the holes CH_M, the holes CH_M are filled with the sacrificial member 102.

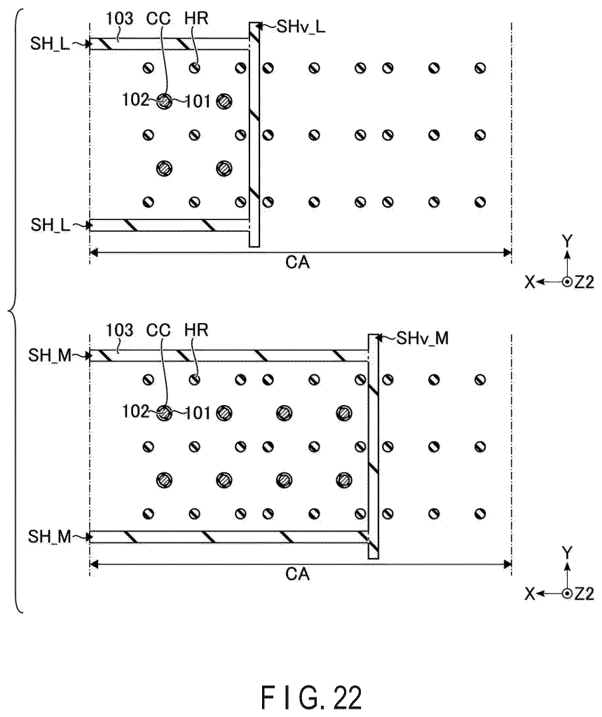

Then, as shown in FIGS. 20 and 21, as with the holes SHv_L and SH_L, a hole SHv_M corresponding to the member SLTv_M and a hole SH_M corresponding to the middle member SLT_M are provided. The lower ends of the holes SHv_M and SH_M reach the interface between the insulator layer 42 and the insulator layer 43. After that, as with the holes SHv_L and SH_L, the holes SHv_M and SH_M are filled with the sacrificial member 103. FIG. 22 shows a plan structure of the lower laminate L_SB after the holes SHv_M and SH_M are filled with the sacrificial member 103 viewed from above (the first structure from the top of the sheet) and a plan structure of the middle laminate M_SB after the holes SHv_M and SH_M are filled with the sacrificial member 103 viewed from above (the second structure from the top of the sheet).

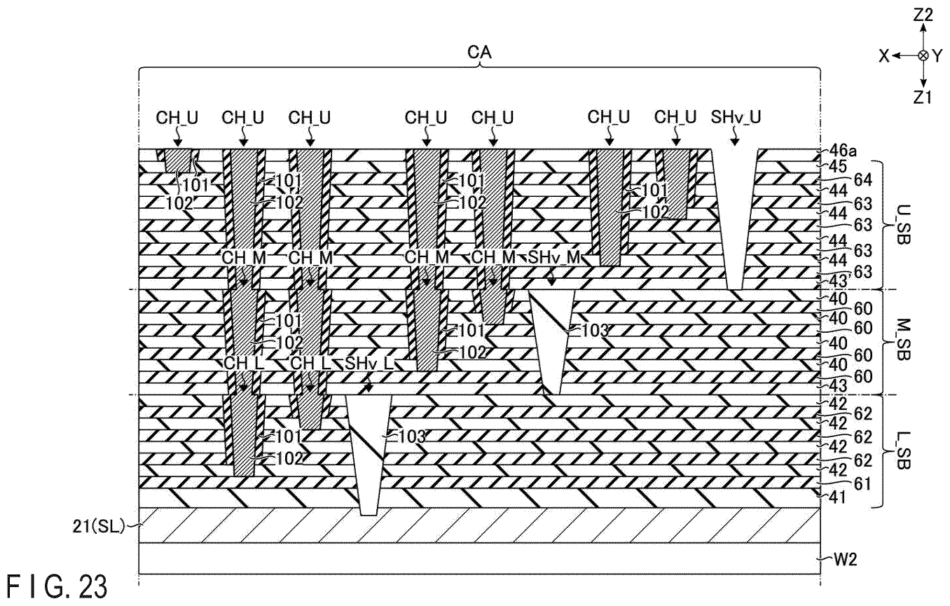

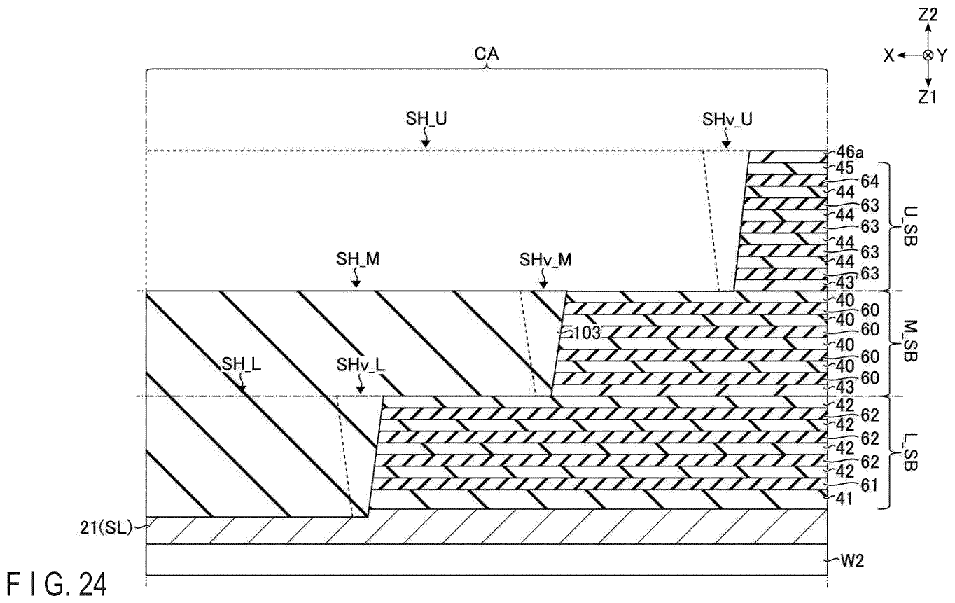

Then, as shown in FIGS. 23 and 24, on the uppermost one of the insulator layers 40, the insulator layer 43′ is provided. Then, on the insulator layer 43′, four sacrificial members 63 and four insulator layers 44 are alternately stacked one on another. Then, on the uppermost one of the insulator layers 44, a sacrificial member 64, the insulator layer 45 and an insulator layer 46a are stacked in this order. The insulator layer 43′ contains TEOS, for example. The insulator layers 44, 45 and 46a contain silicon oxide, for example. The sacrificial members 63 and 64 contains silicon nitride, for example. Then, although not shown, as with the hole CH_L, a hole corresponding to the upper pillar part MP_U is provided. Then, after the sacrificial members in the holes corresponding to the lower pillar part MP_L and the middle pillar part MP_M are removed, the memory pillar MP is formed in the holes corresponding to the lower pillar part MP_L, the middle pillar part MP_M and the upper pillar part MP_U.

Then, as shown in FIGS. 23 and 24, as with the hole CH_L, a hole CH_U corresponding to the upper contact part CC_U is provided. The lower end of the hole CH_U corresponding to the selection gate line SGS, the lower end of the hole CH_U corresponding to the word line WL1, the lower end of the hole CH_U corresponding to the word line WL3, and the lower end of the hole CH_U corresponding to the word line WL5 each reach the upper face of a corresponding one of the holes CH_M. The lower end of the hole CH_U corresponding to the word line WL7 reaches the upper face of the lowermost one of the insulator layers 44. The lower end of the hole CH_U corresponding to the word line WL9 reaches the upper face of the second uppermost insulator layer 44. The lower end of the hole CH_U corresponding to the selection gate line SGD reaches the upper face of the insulator layer 45. Then, as with the hole CH_L, after the forming step for the insulator 101 and the bottom removal step are performed for the holes CH_U, the holes CH_U are filled with the sacrificial member 102.

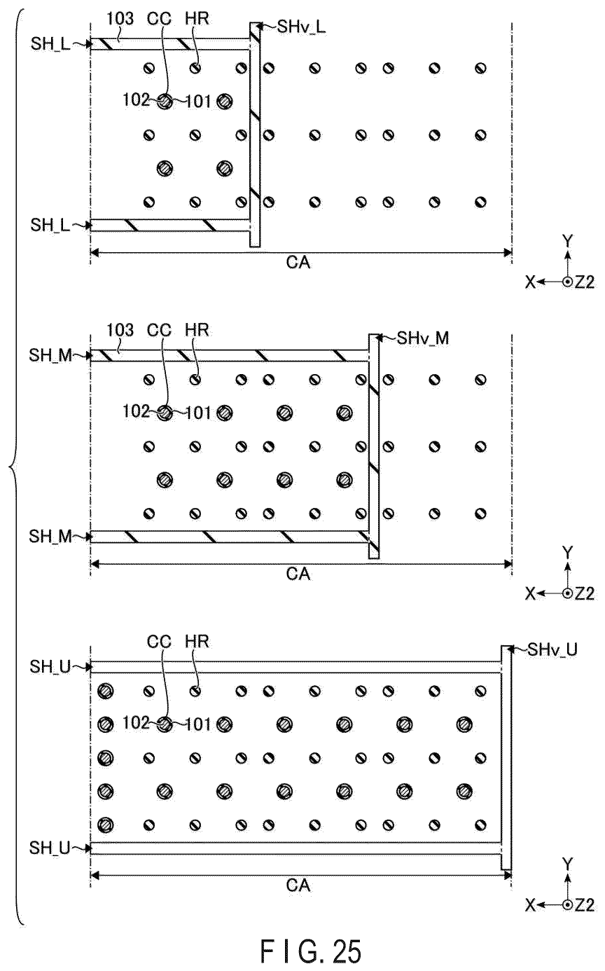

Then, as shown in FIGS. 23 and 24, as with the holes SHv_L and SH_L, a hole SHv_U corresponding to the member SLTv_U and a hole SH_U corresponding to the upper member SLT_U are provided. The lower ends of the holes SHv_U and SH_U reach the interface between the insulator layer 40 and the insulator layer 43′. FIG. 25 shows a plan structure of the lower laminate L_SB after the holes SHv_U and SH_U are formed viewed from above (the first structure from the top of the sheet), a plan structure of the middle laminate M_SB after the holes SHv_U and SH_U are formed viewed from above (the second structure from the top of the sheet) and a plan structure of the upper laminate U_SB after the holes SHv_U and SH_U are formed viewed from above (the third structure from the top of the sheet).

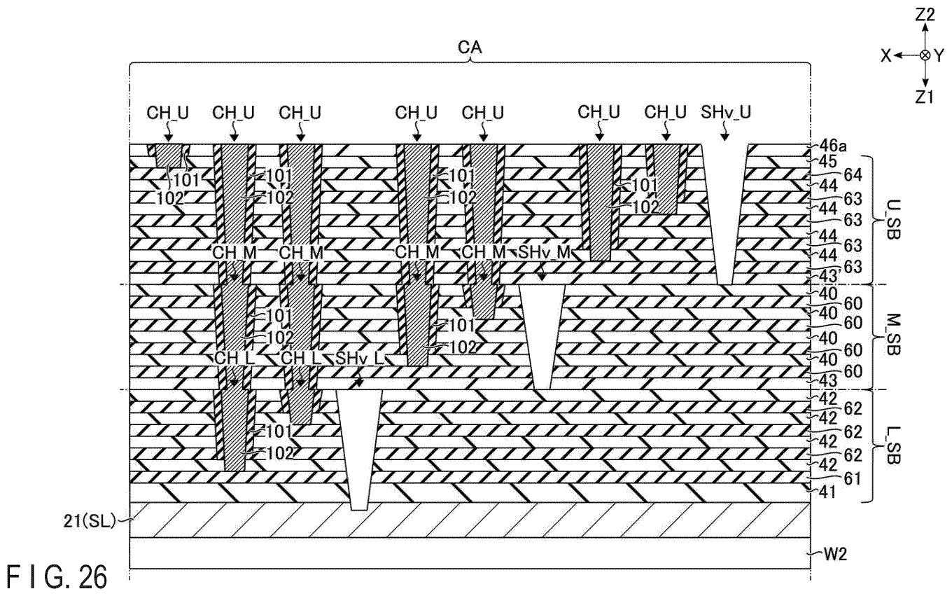

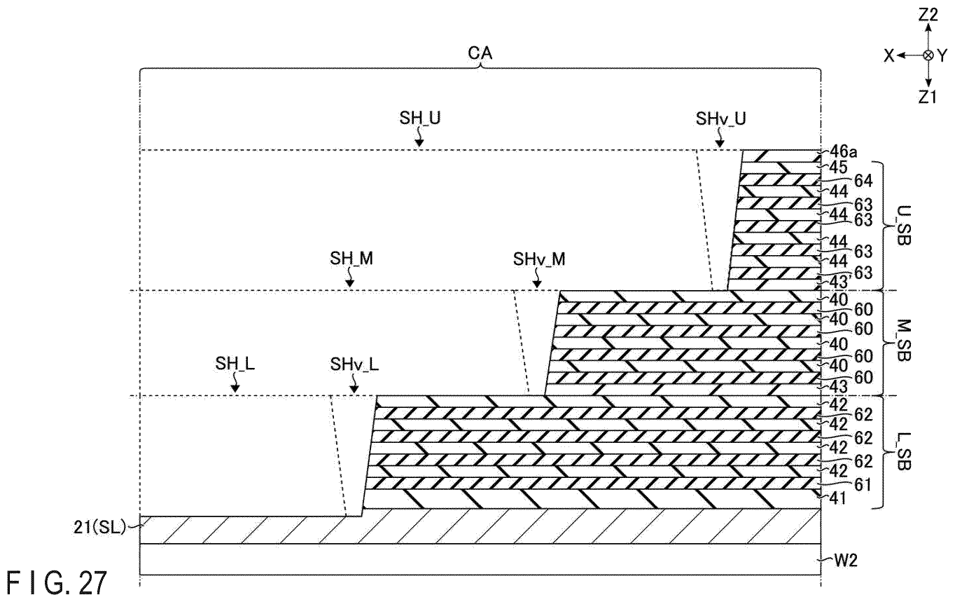

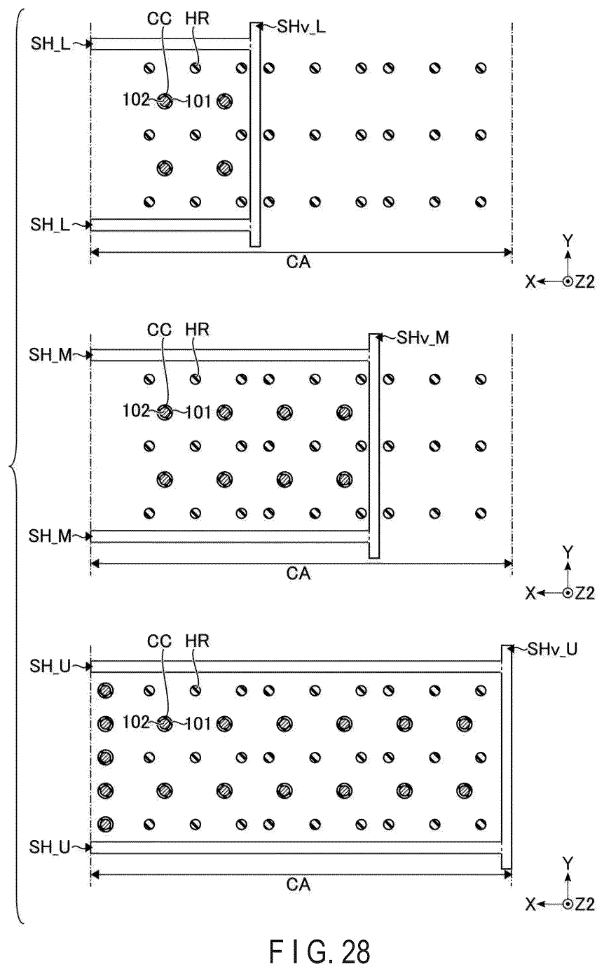

Then, as shown in FIGS. 26 and 27, the sacrificial members 103 filling the holes SHv_L, SHv_M, SH_L and SH_M are removed by wet etching, for example. FIG. 28 shows a plan structure of the lower laminate L_SB after the sacrificial members 103 are removed viewed from above (the first structure from the top of the sheet), a plan structure of the middle laminate M_SB after the sacrificial members 103 are removed viewed from above (the second structure from the top of the sheet) and a plan structure of the upper laminate U_SB after the sacrificial members 103 are removed viewed from above (the third structure from the top of the sheet).

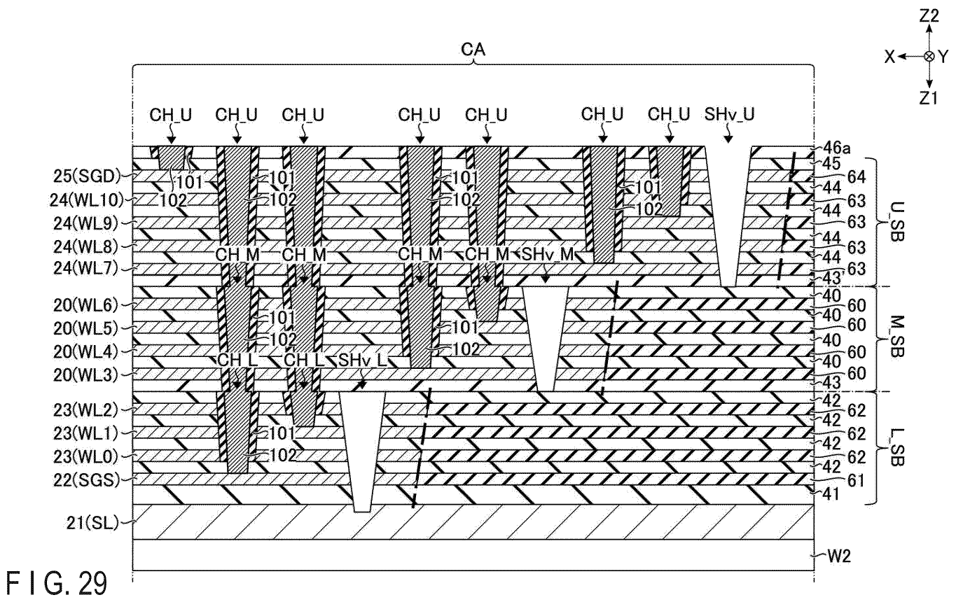

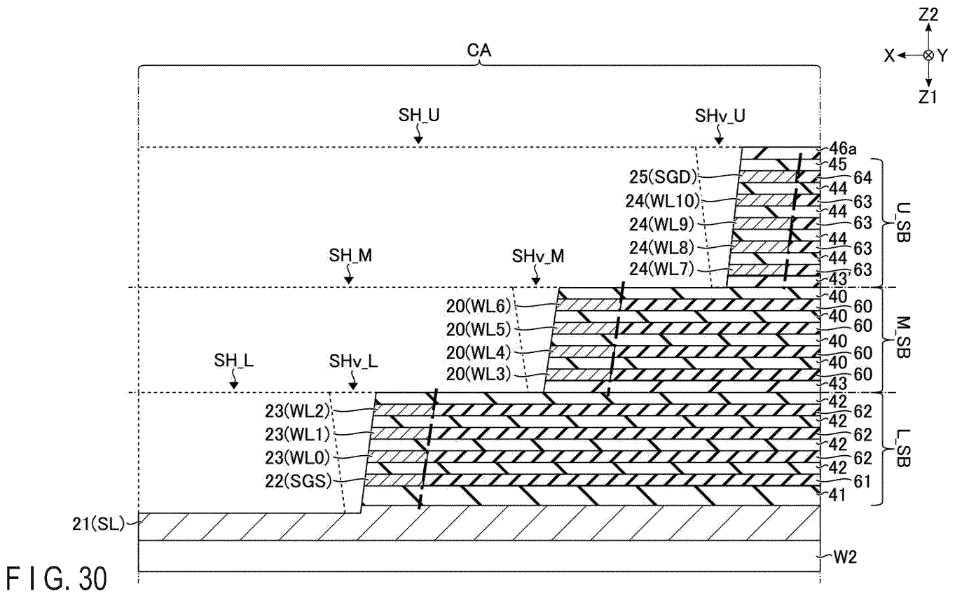

Then, as shown in FIGS. 29 and 30, the sacrificial members 60 to 64 are removed by wet etching using phosphoric acid, for example. In this step, the etchant reaches regions farther from the memory pillar MP than the holes SHv_L, SHv_M and SHv_U in the X direction. As a result, in a region farther from the memory pillar MP than the hole SHv_L, each of the sacrificial member 61 and the plurality of sacrificial members 62 is partially removed. More specifically, each of the sacrificial member 61 and the plurality of sacrificial members 62 is removed over an equal length from the hole SHv_L. In a region farther from the memory pillar MP than the hole SHv_M, each of the plurality of sacrificial members 60 is partially removed. More specifically, each of the plurality of sacrificial members 60 is removed over an equal length from the hole SHv_M. In a region farther from the memory pillar MP than the hole SHv_U, each of the plurality of sacrificial members 63 and the sacrificial member 64 is partially removed. More specifically, each of the plurality of sacrificial members 63 and the sacrificial member 64 is removed over an equal length from the hole SHv_U. In this way, in each of the regions farther from the memory pillar MP than the holes SHv_L, SHv_M and SHv_U, a region (gap) in which the sacrificial members 60 to 64 are removed and a region in which the sacrificial members 60 to 64 are not removed (that is, the sacrificial members 60 to 64 remain) are formed. In the regions (gaps) in which the sacrificial members 60 to 64 are removed, the wiring layers 20 and 22 to 25 are provided (replacement process). The wiring layers 20 and 22 to 25 contain tungsten, for example.

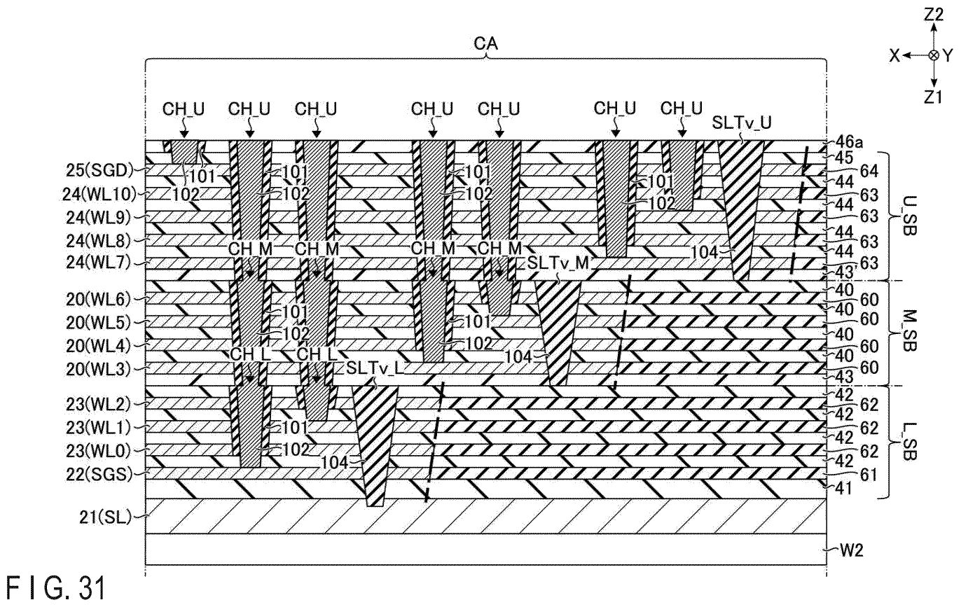

Then, as shown in FIG. 31, the holes SHv_L, SHv_M and SHv_U are each filled with an insulator 104. In this way, the members SLTv_L, SLTv_M and SLTv_U are formed. The insulator 104 contains silicon oxide, for example.

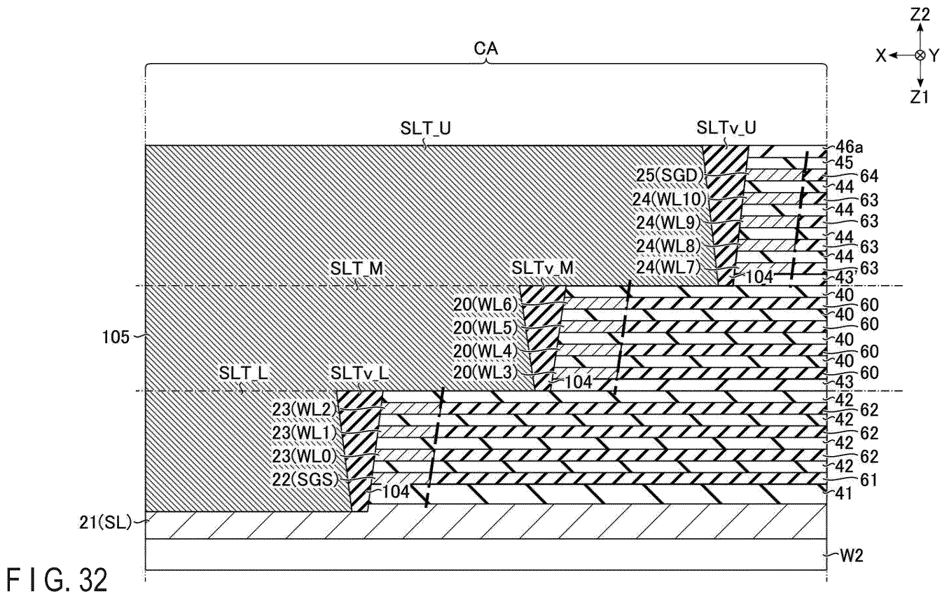

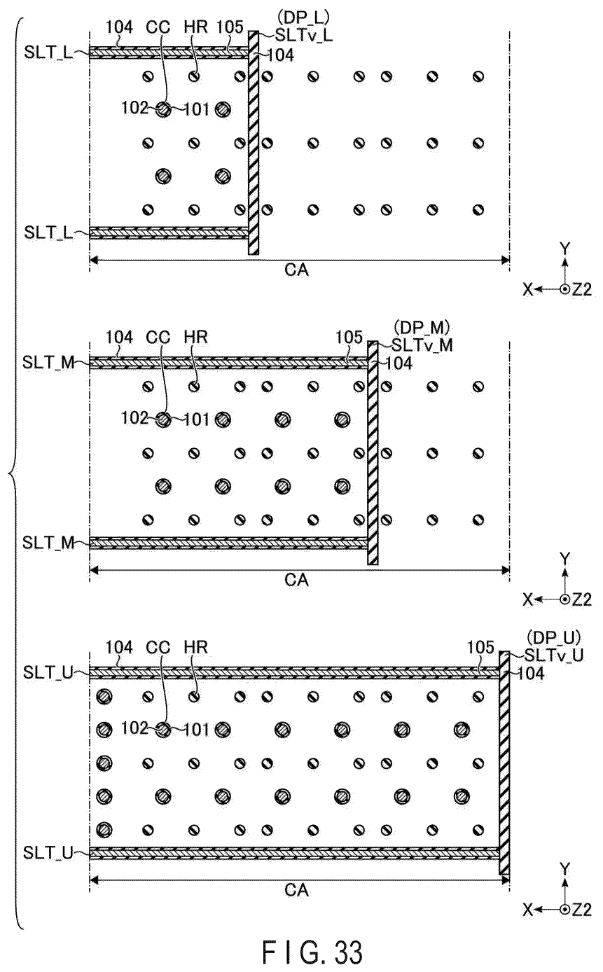

Then, as shown in FIG. 32, the holes SH_L, SH_M and SH_U are each filled with the spacer SP and a conductor 105 (contact LI). In this way, the members SLT are formed. The spacer SP contains silicon oxide, for example. The conductor 105 contains tungsten, for example. FIG. 33 shows a plan structure of the lower laminate L_SB after the members SLTv and SLT are formed viewed from above (the first structure from the top of the sheet), a plan structure of the middle laminate M_SB after the members SLTv and SLT are formed viewed from above (the second structure from the top of the sheet) and a plan structure of the upper laminate U_SB after the members SLTv and SLT are formed viewed from above (the third structure from the top of the sheet).

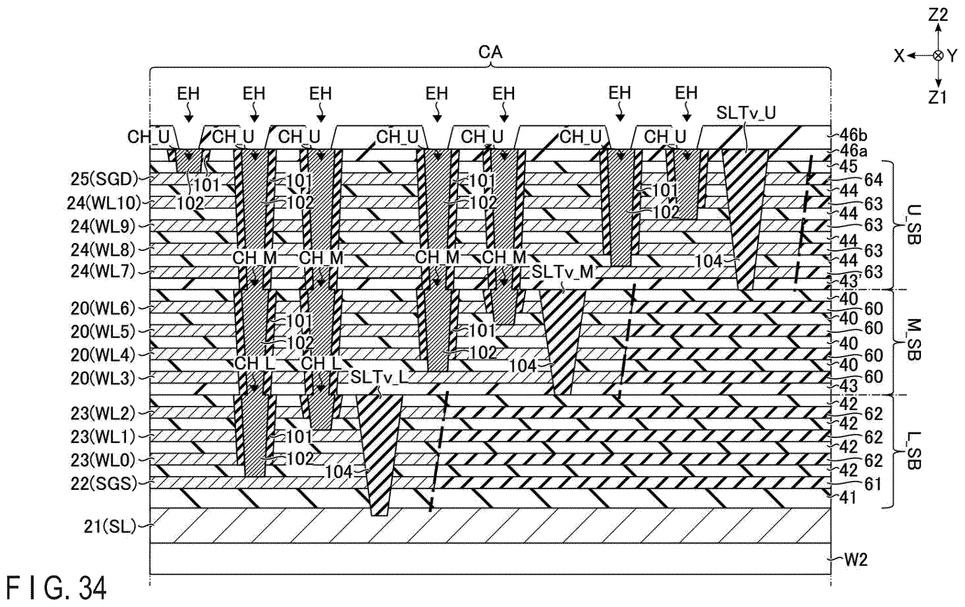

Then, as shown in FIG. 34, an insulator layers 46b is provided on the insulator layer 46a, and then holes EH corresponding to the contacts CC are provided. For example, a mask having openings in regions corresponding to the holes EH is formed by photolithography or the like, and the holes EH are formed by anisotropic etching using the mask. The lower end of the hole EH reaches the upper face of the hole CH_U. The insulator layer 46b contains silicon oxide, for example. The insulator layers 46a and 46b correspond to the insulator layer 46.

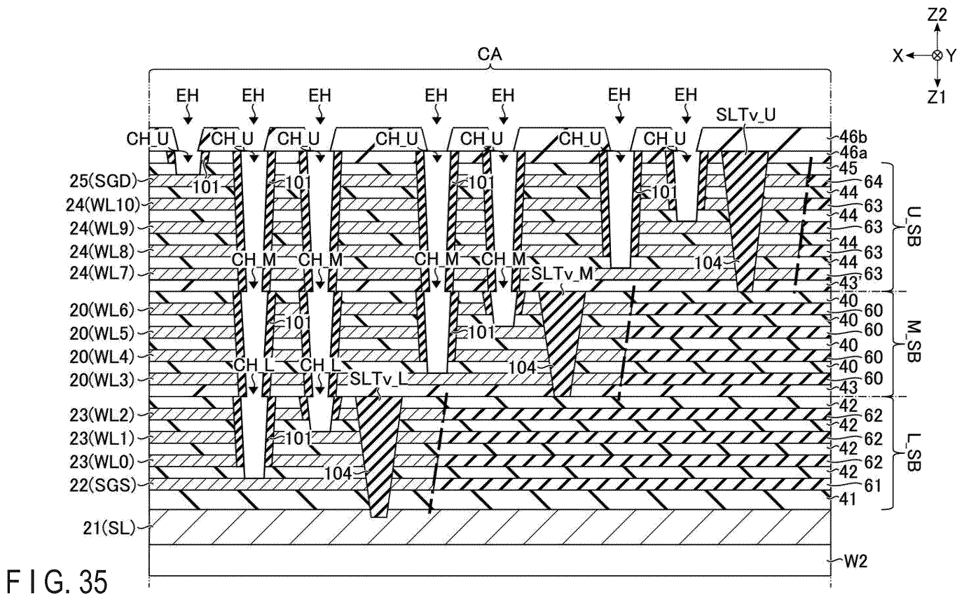

Then, as shown in FIG. 35, the sacrificial member 102 in each of the holes CH_L, CH_M and CH_U is removed. As a result, the holes CH_L, CH_M, and CH_U corresponding to the selection gate line SGS are connected to each other, and the wiring layer 22 is exposed. The holes CH_L, CH_M, and CH_U corresponding to the word line WL1 are connected to each other, and the wiring layer 23 corresponding to the word line WL1 is exposed. The holes CH_M and CH_U corresponding to the word line WL3 are connected to each other, and the wiring layer 20 corresponding to the word line WL3 is exposed. The holes CH_M and CH_U corresponding to the word line WL5 are connected to each other, and the wiring layer 20 corresponding to the word line WL5 is exposed. The wiring layer 24 corresponding to the word line WL7 is exposed. The wiring layer 24 corresponding to the word line WL9 is exposed. The wiring layer 25 corresponding to the selection gate line SGD is exposed.

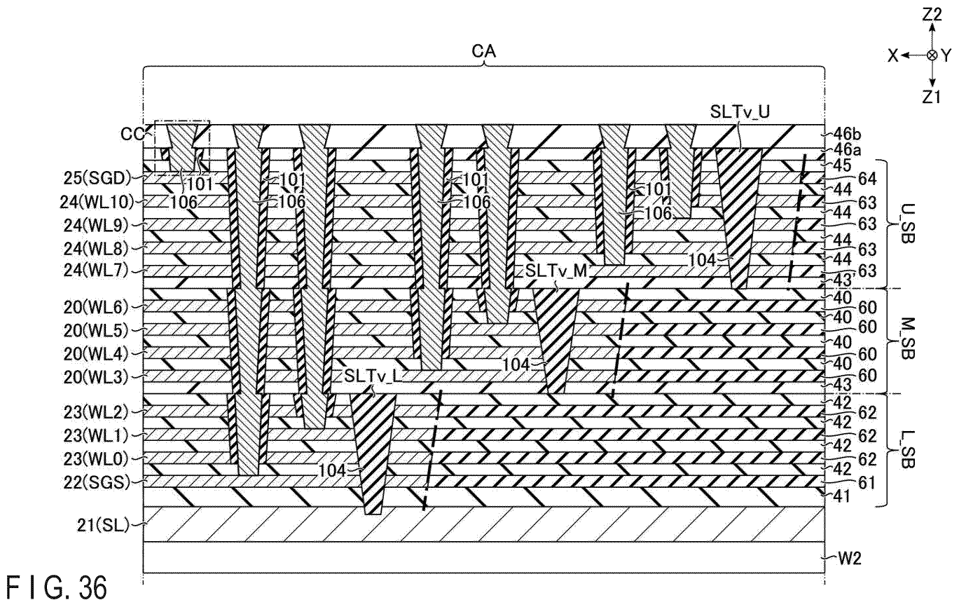

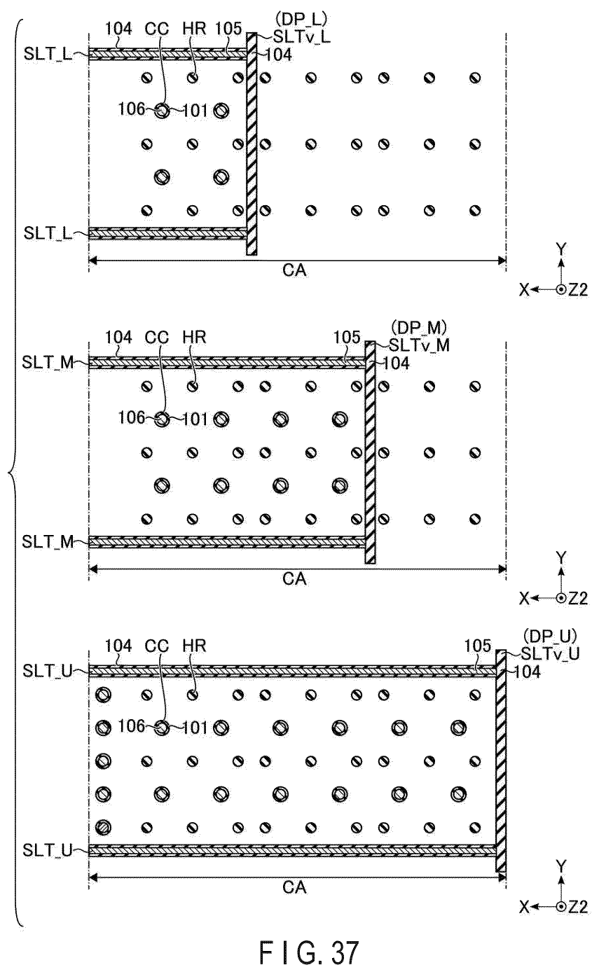

Then, as shown in FIG. 36, each of the holes CH_L, CH_M, CH_U and EH is filled with a conductor 106. In this way, the contacts CC are formed. The conductor 106 contains tungsten, for example. The insulator 101 and the conductor 106 included in each contact CC correspond to the insulator 51 and the conductor 50, respectively. FIG. 37 shows a plan structure of the lower laminate L_SB after the contacts CC are formed viewed from above (the first structure from the top of the sheet), a plan structure of the middle laminate M_SB after the contacts CC are formed viewed from above (the second structure from the top of the sheet) and a plan structure of the upper laminate U_SB after the contacts CC are formed viewed from above (the third structure from the top of the sheet).

1.3 Effects of this Embodiment

In the array chip 100 that has a structure in which in the contact region CA, the multilayer wiring and the row decoder module are connected to each other by a contact including a conductor and an insulator that covers the side face of the conductor (referred to as a “through contact” hereinafter), for example, the multilayer wiring is divided in each block BLK by the members SLT extending in the Z direction and the Y direction and the members SLTv extending in the Z direction and the X direction.

In the step of forming holes corresponding to the members SLT and the members SLTv, the processing rate is high at intersections of members SLT and SLTv. Therefore, the amount of digging of the semiconductor substrate W2 is high, and penetration through the semiconductor substrate W2 may occur. In addition, the more the layers of the multilayer wiring, the greater the amount of digging of the semiconductor substrate W2 may be.

In the bonded structure of the array chip 100 and the circuit chip 200, since the array chip 100 starts being processed from the back face side (the opposite side to the face bonded) after bonding, the amount of digging of the semiconductor substrate W2 inhibits the processing.

With the semiconductor storage device 3 according to this embodiment, holes corresponding to the members SLT and SLTv are formed in each of the lower laminate L_SB, the middle laminate M_SB and the upper laminate U_SB. Therefore, compared with the case where holes corresponding to the members SLT and SLTv are formed by batch in the lower laminate L_SB, the middle laminate M_SB and the upper laminate U_SB, the amount of digging of the semiconductor substrate W2 is lower. Therefore, with the semiconductor storage device 3 according to this embodiment, the amount of digging of the substrate can be reduced.

With the semiconductor storage device 3 according to this embodiment, the hole SH_L corresponding to the lower member SLT_L and the hole SHv_L corresponding to the member SLTv_L are formed at the same time. Therefore, in the processing of the holes SH_L and SHv_L, no region is doubly processed. Therefore, the occurrence of penetration through the substrate can be reduced. In addition, the hole SH_M corresponding to the middle member SLT_M and the hole SHv_M corresponding to the member SLTv_M are formed at the same time. The hole SH_U corresponding to the upper member SLT_U and the hole SHv_U corresponding to the member SLTv_U are formed at the same time. Therefore, compared with the case where the holes corresponding to the members SLT and SLTv are separately formed in the lower laminate L_SB, the middle laminate M_SB and the upper laminate U_SB, the number of production steps can be reduced.

With the semiconductor storage device 3 according to this embodiment, the member SLTv_M is arranged above the insulator layer 61 and the plurality of insulator layers 62. The member SLTv_U is arranged above the plurality of insulator layers 60. Therefore, compared with the case where the wiring layers are arranged below each of the members SLTv_M and SLTv_U, the amount of digging need not be considered in the processing of the holes SHv_M and SHv_U.

With the semiconductor storage device 3 according to this embodiment, the sum of the distance DLa and the distance DLb for the lower wiring contacts CC, the sum of the distance DMa and the distance DMb for the middle wiring contacts CC, and the sum of the distance DUa and the distance DUb for the upper wiring contacts CC are balanced. Therefore, the RC delay time (the time required for the voltage on a wire to rise or fall to a target value since the voltage is applied to the wire) can be reduced.

### 1.4 First Variation

A semiconductor storage device according to a first variation of the first embodiment will be described. A semiconductor storage device 3 according to this variation differs from the semiconductor storage device 3 according to the first embodiment in the structures of the lower laminate L_SB, the middle laminate M_SB and the upper laminate U_SB and the production method. In the following, differences from the first embodiment will be mainly described.

### 1.4.1 Cross-Sectional Structure of Contact Region

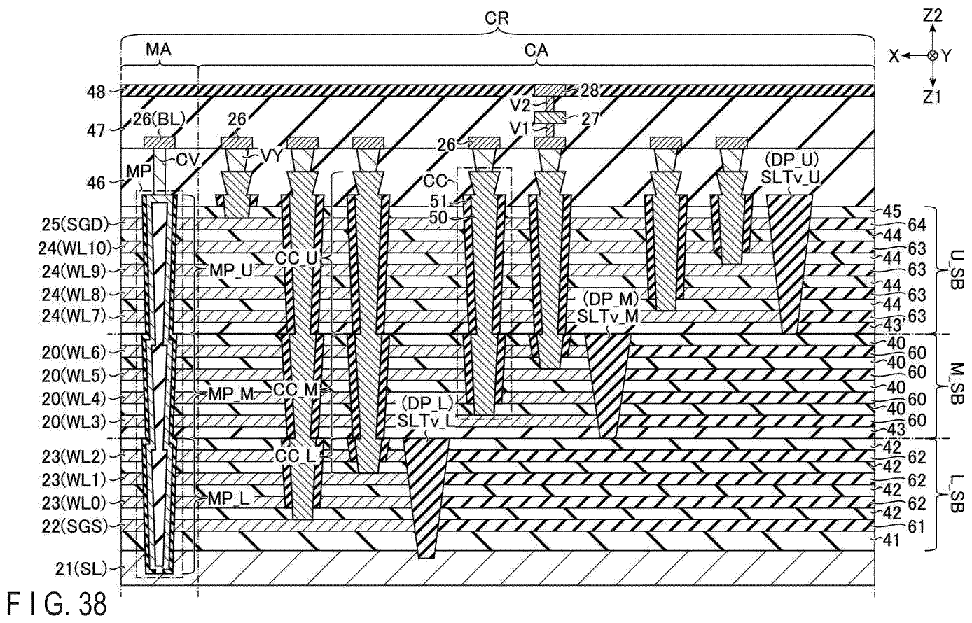

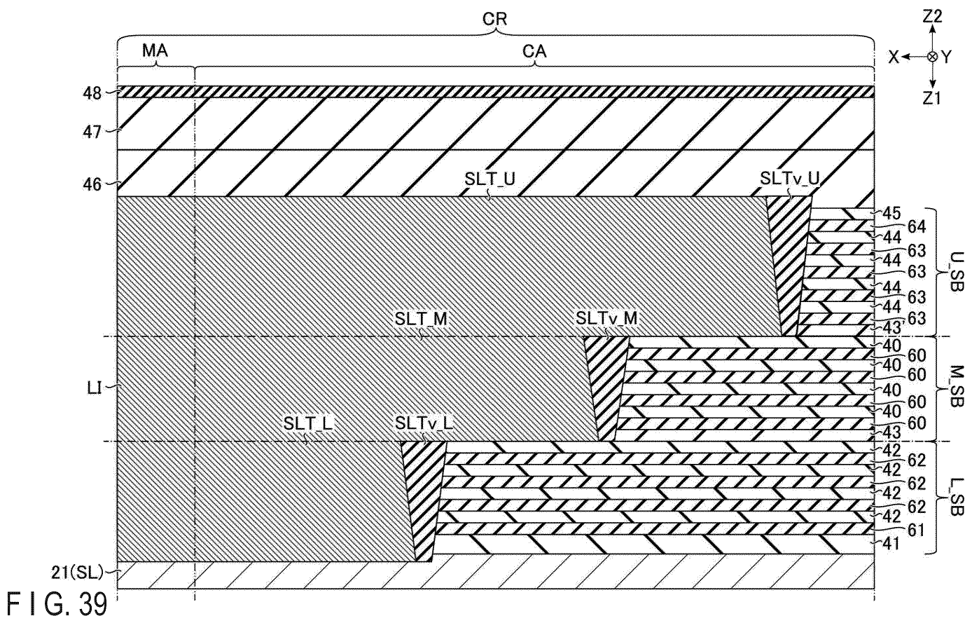

A cross-sectional structure of the contact region CA will be described with reference to FIGS. 38 and 39. FIG. 38 is a cross-sectional view taken along the line VIII-VIII in FIG. 5, showing an example of the cross-sectional structure in the contact region CA of the memory cell array 10 included in the semiconductor storage device 3 according to the first variation of the first embodiment. FIG. 38 also shows a cross-sectional structure in the memory region MA in the vicinity of the contact region CA. The cross-sectional structure in the memory region MA is the same as that shown in FIG. 6. In the following description, it is assumed that the Z2 direction is the upward direction, and the Z1 direction is the downward direction.

As shown in FIG. 38, the member SLTv_L is in contact with the wiring layer 22, the plurality of wiring layers 23, the insulator layer 61 and the plurality of insulator layers 62. In other words, in the region farther from the memory pillar MP than the member SLTv_L, the lower laminate L_SB does not include the wiring layer 22 and the plurality of wiring layers 23, although the lower laminate L_SB includes the insulator layer 61 and the plurality of insulator layers 62. The member SLTv_M is in contact with the plurality of wiring layers 20 and the plurality of insulator layers 60. In other words, in the region farther from the memory pillar MP than the member SLTv_M, the middle laminate M_SB does not include the plurality of wiring layers 20, although the middle laminate M_SB includes the plurality of insulator layers 60. The member SLTv_U is in contact with the plurality of wiring layers 24, the wiring layer 25, the plurality of insulator layers 63 and the insulator layer 64. In other words, in the region farther from the memory pillar MP than the member SLTv_U, the upper laminate U_SB does not include the plurality of wiring layers 24 and the wiring layer 25, although the upper laminate U_SB includes the plurality of insulator layers 63 and the insulator layer 64.

The middle wiring contacts CC are arranged above the insulator layer 61 and the plurality of insulator layers 62. The upper wiring contacts CC are arranged above the plurality of insulator layers 60.

The structures of the contact CC and the members SLTv_L, SLTv_M and SLTv_U are the same as those in FIG. 8.

The cross-sectional structure above the insulator layer 46 is the same as that in FIG. 8.

FIG. 39 is a cross-sectional view taken along the line IX-IX in FIG. 5, showing an example of the cross-sectional structure in the contact region CA of the memory cell array 10 included in the semiconductor storage device 3 according to the first variation of the first embodiment. FIG. 39 also shows a cross-sectional structure in the memory region MA in the vicinity of the contact region CA. In the contact region CA, the cross-sectional structure in the region farther from the memory region MA than the SLTv_L the cross-sectional structure in the region farther from the memory region MA than the SLTv_M and the cross-sectional structure in the region farther from the memory region MA than the member SLTv_U are the same as those in FIG. 38. In the contact region CA, the cross-sectional structure in the region closer to the memory region MA than the SLTv_L, the cross-sectional structure in the region closer to the memory region MA than the SLTv_M and the cross-sectional structure in the region closer to the memory region MA than the member SLTv_U are the same as those in FIG. 9. The cross-sectional structure in the memory region MA is also the same as that in FIG. 9. The cross-sectional structure above the insulator layer 46 is the same as that in FIG. 9.

### 1.4.2 Production Method for Semiconductor Storage Device

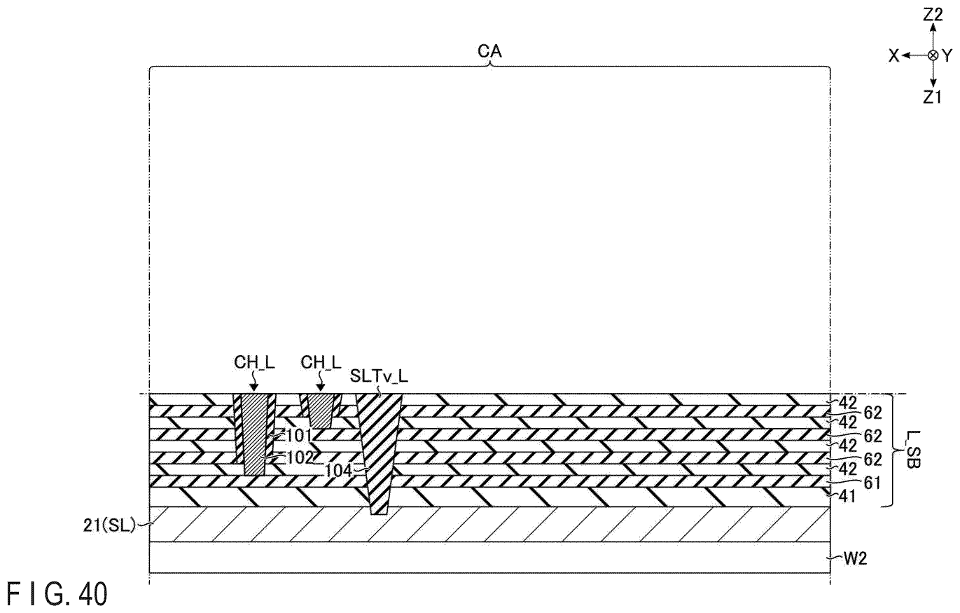

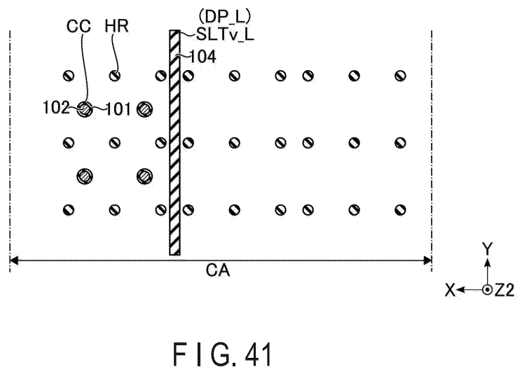

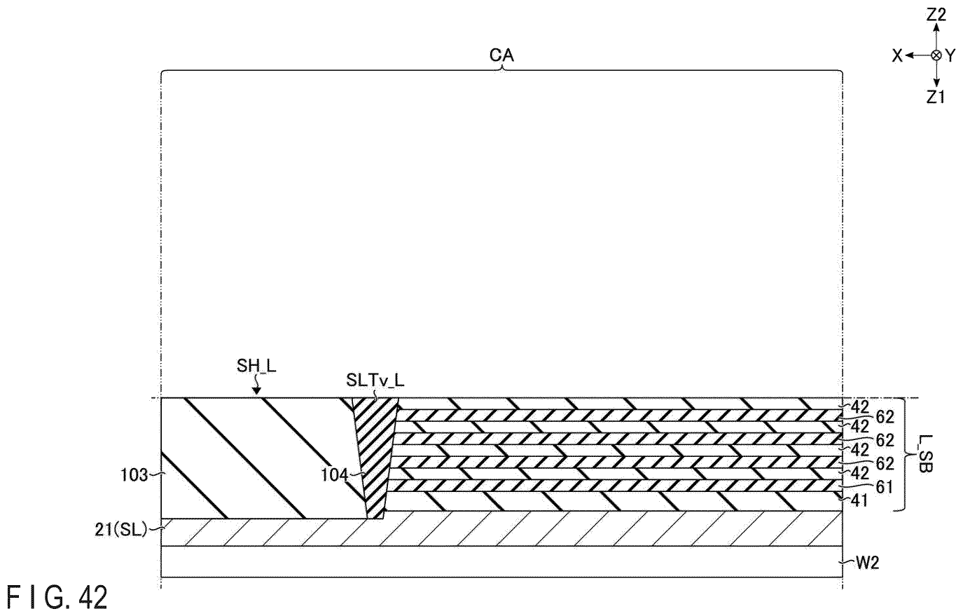

A production method for the semiconductor storage device 3 according to the first variation of the first embodiment will be described with reference to FIGS. 40 to 55. FIGS. 40, 42, 44, 46, 48, 50, 52, 54 and 55 are cross-sectional views showing examples of the cross-sectional structure during production of the semiconductor storage device 3 according to the first variation of the first embodiment. FIGS. 40, 44, 48 and 54 show cross-sectional structures corresponding to FIG. 38. FIGS. 42, 46, 50, 52 and 55 show cross-sectional structures corresponding to FIG. 39. FIGS. 41, 43, 45, 47, 49, 51 and 53 are plan views showing examples of the plan structure during production of the semiconductor storage device 3 according to the first variation of the first embodiment. In FIGS. 41, 43, 45, 47, 49, 51 and 53, illustration of the interlayer insulating film is omitted. In the following, description of the step of forming the memory pillar MP and the supporting pillar HR will be omitted.

First, as shown in FIG. 40, as in the first embodiment, on the semiconductor substrate W2, the wiring layer 21, the insulator layer 41 and the sacrificial member 61 are stacked, and then, on the sacrificial member 61, four insulator layers 42 and three sacrificial members 62 are alternately stacked one on another.

Then, as shown in FIG. 40, as in the first embodiment, a hole CH_L corresponding to the lower contact part CC_L is provided. Then, as in the first embodiment, the forming step for the insulator 101 and the bottom removal step are performed for the hole CH_L, and then, the hole CH_L is filled with the sacrificial member 102.

Then, as shown in FIG. 40, as in the first embodiment, a hole SHv_L corresponding to the member SLTv_L is provided. The lower end of the hole SHv_L reaches into the wiring layer 21. Then, the hole SHv_L is filled with the insulator 104. In this way, the member SLTv_L is formed. The insulator 104 contains silicon oxide, for example. FIG. 41 shows a plan structure of the lower laminate L_SB after the hole SHv_L is filled with the insulator 104 viewed from above.

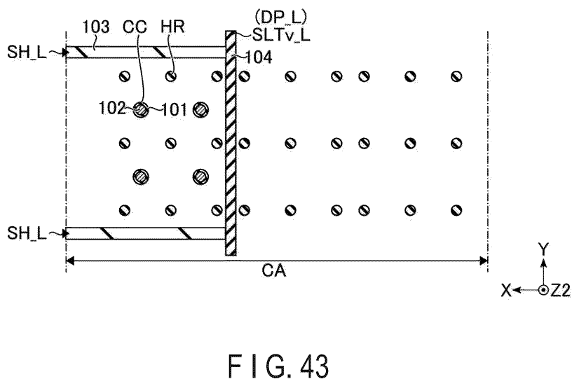

Then, as shown in FIG. 42, as in the first embodiment, a hole SH_L corresponding to the lower member SLT_L is provided. The lower end of the hole SH_L reaches into the wiring layer 21. After that, the holes SH_L is filled with the sacrificial member 103. FIG. 43 shows a plan structure of the lower laminate L_SB after the hole SH_L is filled with the sacrificial member 103 viewed from above.

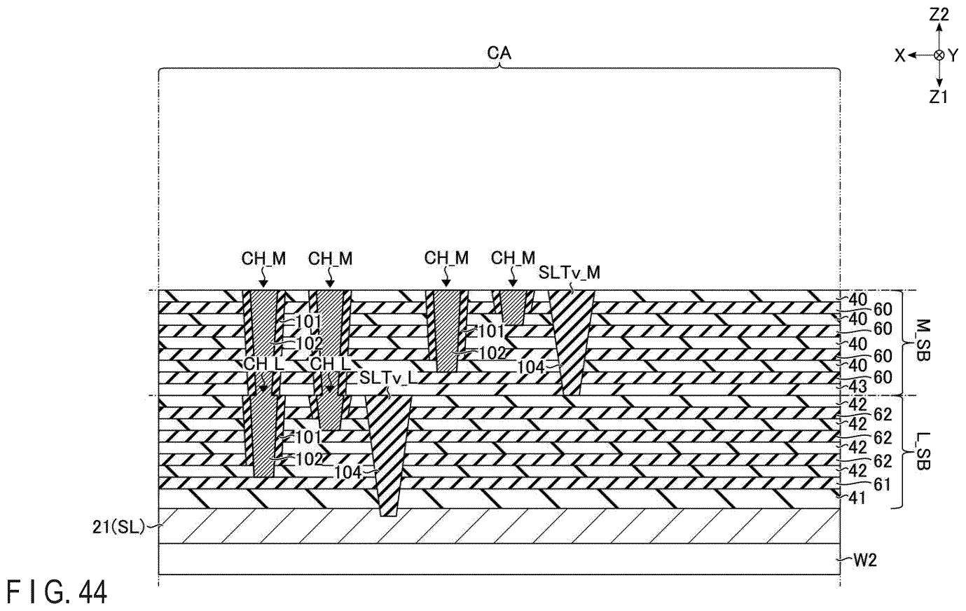

Then, as shown in FIG. 44, as in the first embodiment, on the uppermost one of the insulator layers 42, the insulator layer 43 is provided. Then, as in the first embodiment, on the insulator layer 43, four sacrificial members 60 and four insulator layers 40 are alternately stacked one on another.

Then, as shown in FIG. 44, as with the hole CH_L, a hole CH_M corresponding to the middle contact part CC_M is provided. Then, as with the hole CH_L, the forming step for the insulator 101 and the bottom removal step are performed for the hole CH_M, and then, the hole CH_M is filled with the sacrificial member 102.

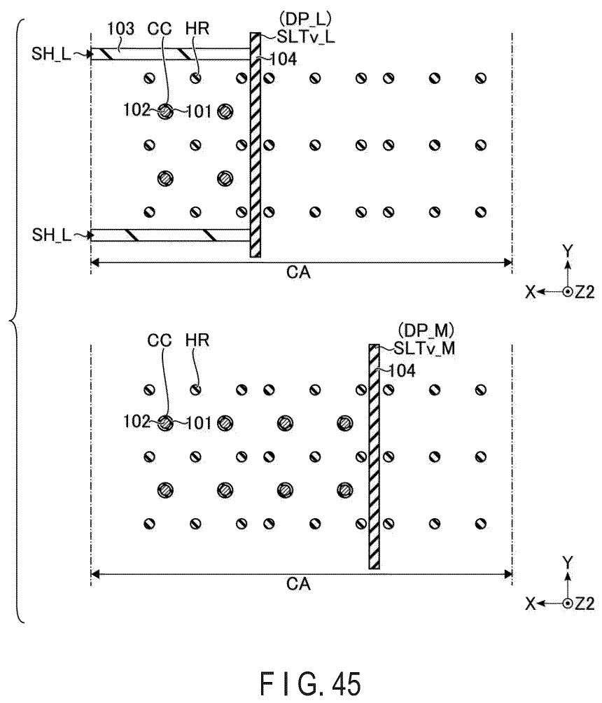

Then, as shown in FIG. 44, as with the hole SHv_L, a hole SHv_M corresponding to the member SLTv_M is provided. The lower end of the hole SHv_M reaches the interface between the insulator layer 42 and the insulator layer 43. After that, as with the hole SHv_L, the hole SHv_M is filled with the insulator 104. In this way, the member SLTv_M is formed. FIG. 45 shows a plan structure of the lower laminate L_SB after the hole SHv_M is filled with the insulator 104 viewed from above (the first structure from the top of the sheet) and a plan structure of the middle laminate M_SB after the hole SHv_M is filled with the insulator 104 viewed from above (the second structure from the top of the sheet).

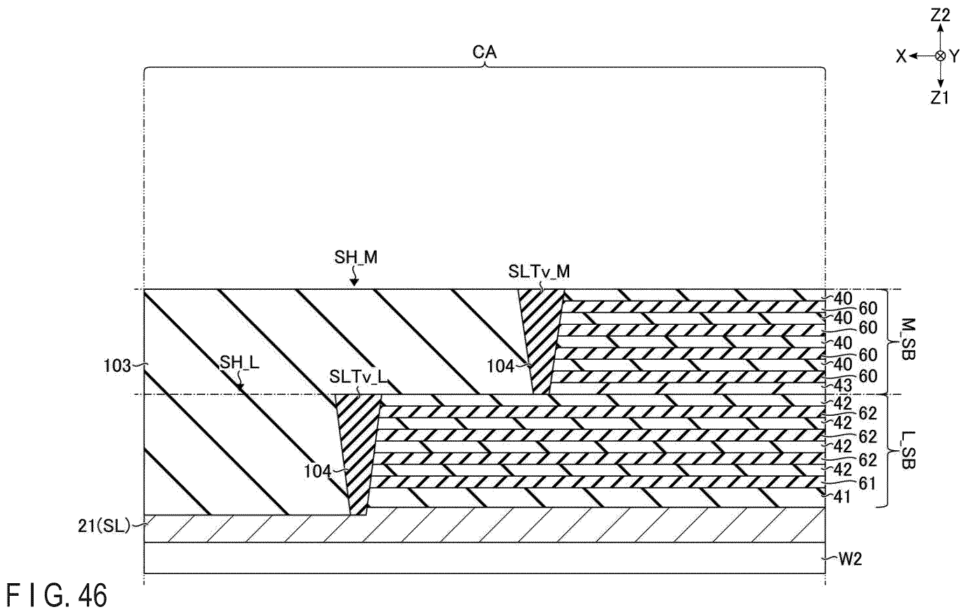

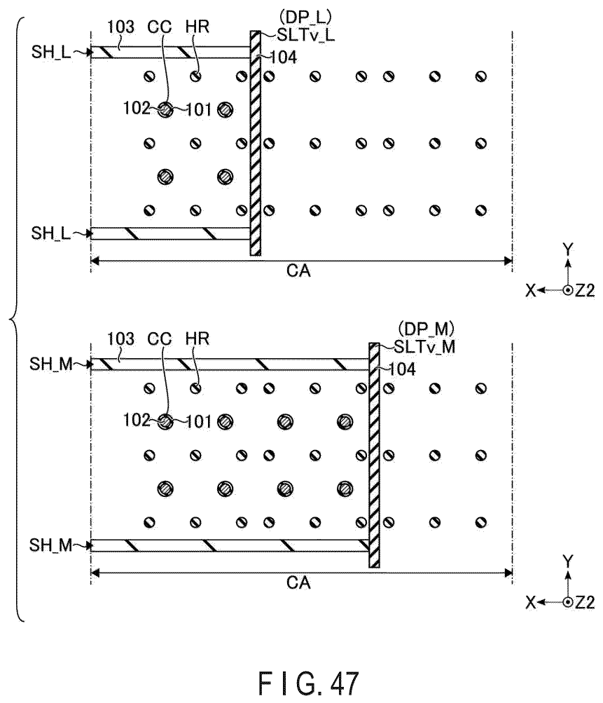

Then, as shown in FIG. 46, as with the hole SH_L, a hole SH_M corresponding to the middle member SLT_M is provided. The lower end of the hole SH_M reaches the interface between the insulator layer 42 and the insulator layer 43. After that, as with the holes SH_L, the hole SH_M is filled with the sacrificial member 103. FIG. 47 shows a plan structure of the lower laminate L_SB after the hole SH_M is filled with the sacrificial member 103 viewed from above (the first structure from the top of the sheet) and a plan view of the middle laminate M_SB after the hole SH_M is filled with the sacrificial member 103 viewed from above (the second structure from the top of the sheet).

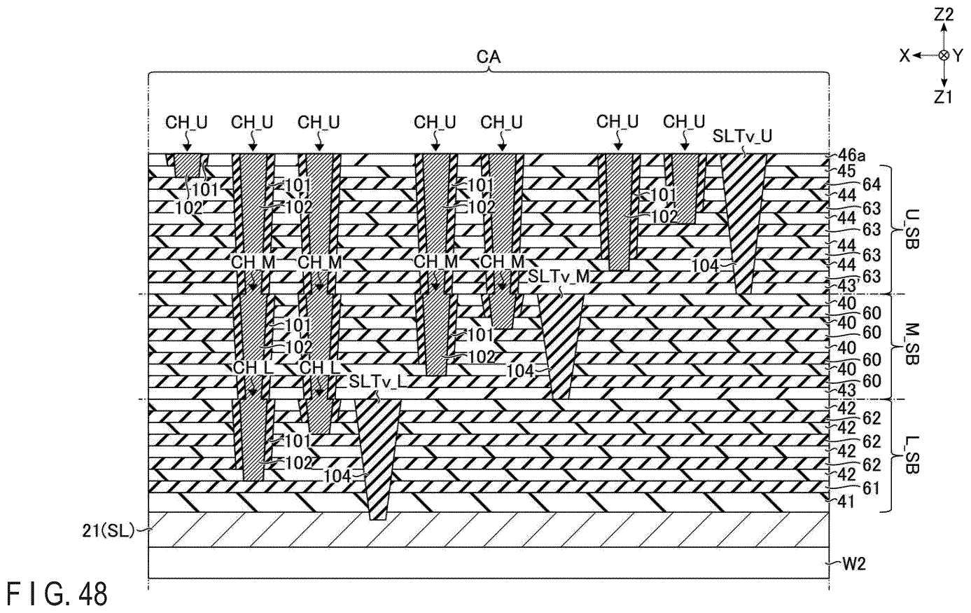

Then, as shown in FIG. 48, as in the first embodiment, on the uppermost one of the insulator layers 40, the insulator layer 43′ is provided. Then, as in the first embodiment, on the insulator layer 43′, four sacrificial members 63 and four insulator layers 44 are alternately stacked one on another. Then, as in the first embodiment, on the uppermost one of the insulator layers 44, the sacrificial member 64, the insulator layer 45 and the insulator layer 46a are stacked in this order.

Then, as shown in FIG. 48, as with the hole CH_L, a hole CH_U corresponding to the upper contact part CC_U is provided. Then, as with the hole CH_L, the forming step for the insulator 101 and the bottom removal step are performed for the hole CH_U, and then, the hole CH_U is filled with the sacrificial member 102.

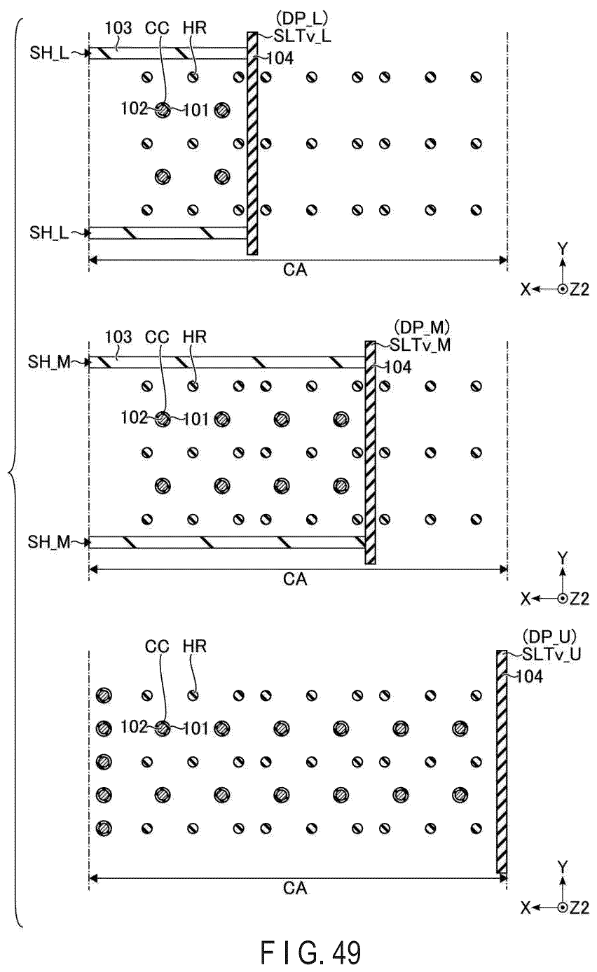

Then, as shown in FIG. 48, as with the hole SHv_L, a hole SHv_U corresponding to the member SLTv_U is provided. The lower end of the hole SHv_U reaches the interface between the insulator layer 40 and the insulator layer 43′. After that, as with the hole SHv_L, the hole SHv_U is filled with the insulator 104. In this way, the member SLTv_U is formed. FIG. 49 shows a plan structure of the lower laminate L_SB after the hole SHv_U is filled with the insulator 104 viewed from above (the first structure from the top of the sheet), a plan structure of the middle laminate M_SB after the hole SHv_U is filled with the insulator 104 viewed from above (the second structure from the top of the sheet) and a plan structure of the upper laminate U_SB after the hole SHv_U is filled with the insulator 104 viewed from above (the third structure from the top of the sheet).

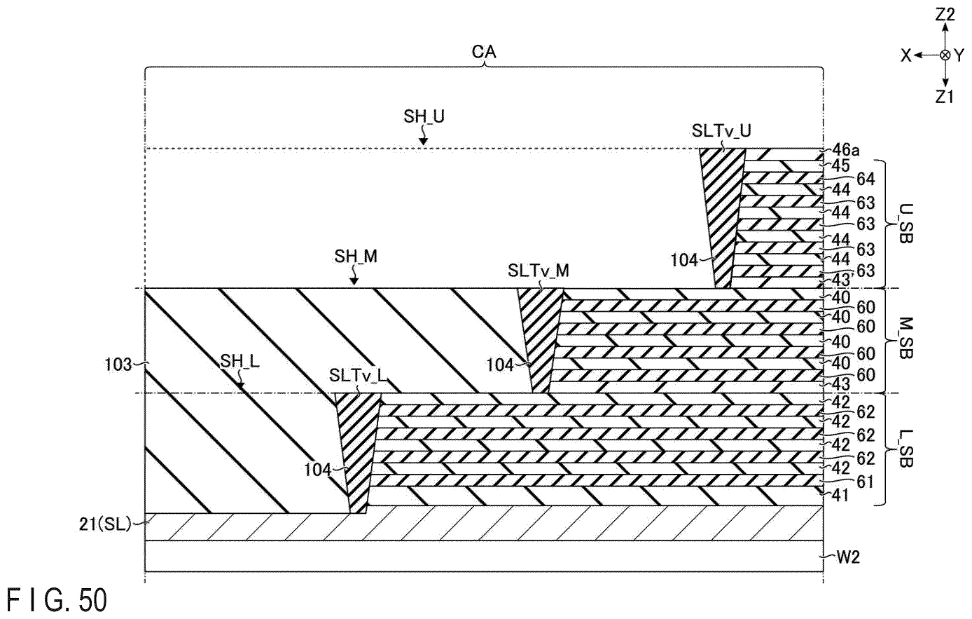

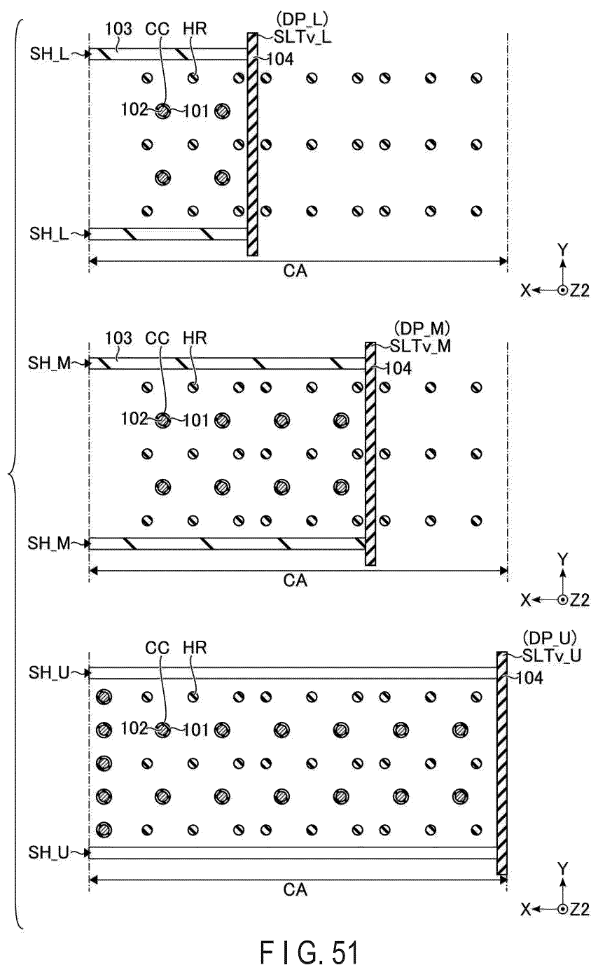

Then, as shown in FIG. 50, as with the hole SH_L, a hole SH_U corresponding to the upper member SLT_U is provided. The lower end of the hole SH_U reaches the interface between the insulator layer 40 and the insulator layer 43′. FIG. 51 shows a plan structure of the lower laminate L_SB after the hole SH_U is formed viewed from above (the first structure from the top of the sheet), a plan view of the middle laminate M_SB after the hole SH_U is formed viewed from above (the second structure from the top of the sheet) and a plan view of the upper laminate U_SB after the hole SH_U is formed viewed from above (the third structure from the top of the sheet).

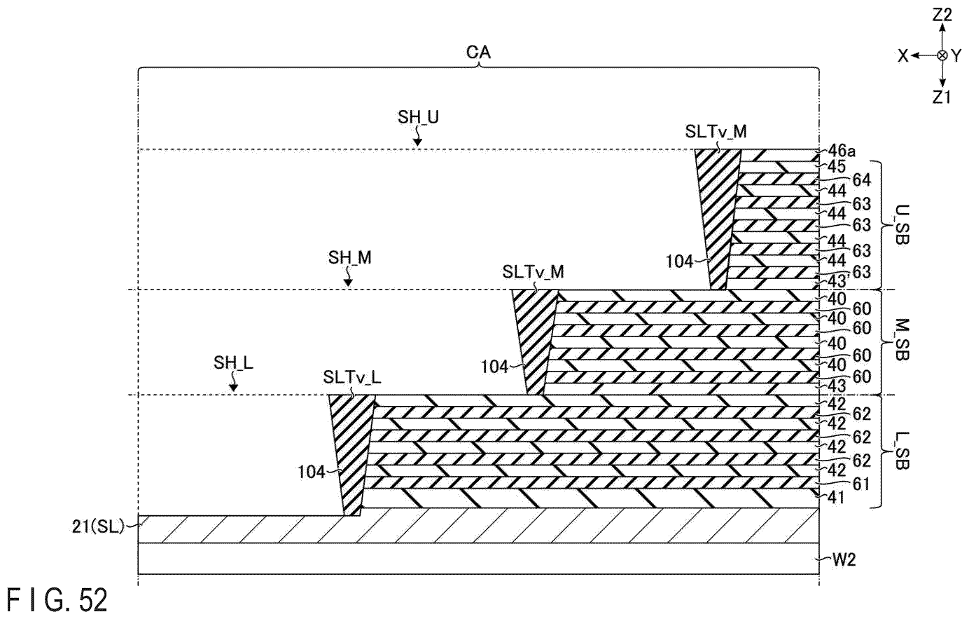

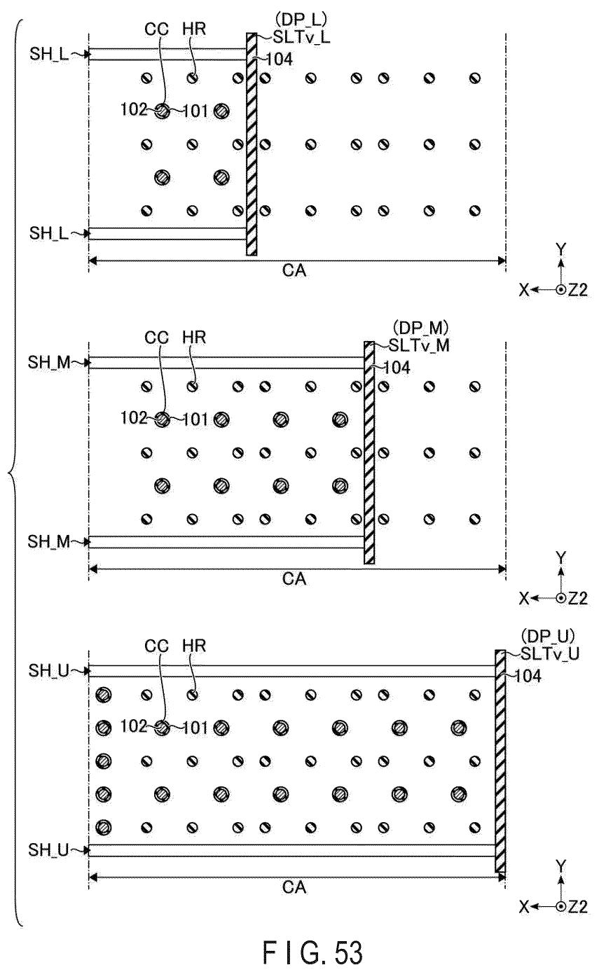

Then, as shown in FIG. 52, as in the first embodiment, the sacrificial members 103 filling the holes SH_L and SH_M are removed. FIG. 53 shows a plan structure of the lower laminate L_SB after the sacrificial members 103 are removed viewed from above (the first structure from the top of the sheet), a plan structure of the middle laminate M_SB after the sacrificial members 103 are removed viewed from above (the second structure from the top of the sheet) and a plan structure of the upper laminate U_SB after the sacrificial members 103 are removed viewed from above (the third structure from the top of the sheet).

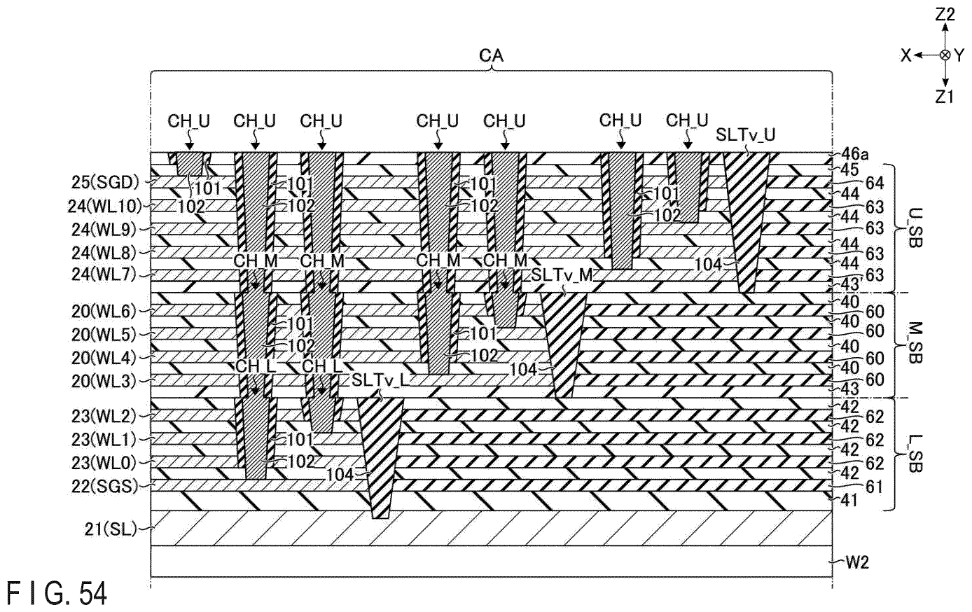

Then, as shown in FIG. 54, as in the first embodiment, the sacrificial members 60 to 64 are removed. In this step, the etchant does not reach regions farther from the memory pillar MP than the members SLTv_L, SLTv_M and SLTv_U. Therefore, in the region farther from the memory pillar MP than the member SLTv_L, each of the sacrificial member 61 and the plurality of sacrificial members 62 are not removed and remain. In the region farther from the memory pillar MP than the member SLTv_M, each of the plurality of sacrificial members 60 are not removed and remain. In the region farther from the memory pillar MP than the member SLTv_U, each of the plurality of sacrificial members 63 and the sacrificial member 64 are not removed and remain. After that, as in the first embodiment, in the regions (gaps) in which the sacrificial members 60 to 64 are removed, the wiring layers 20 and 22 to 25 are provided (replacement process).

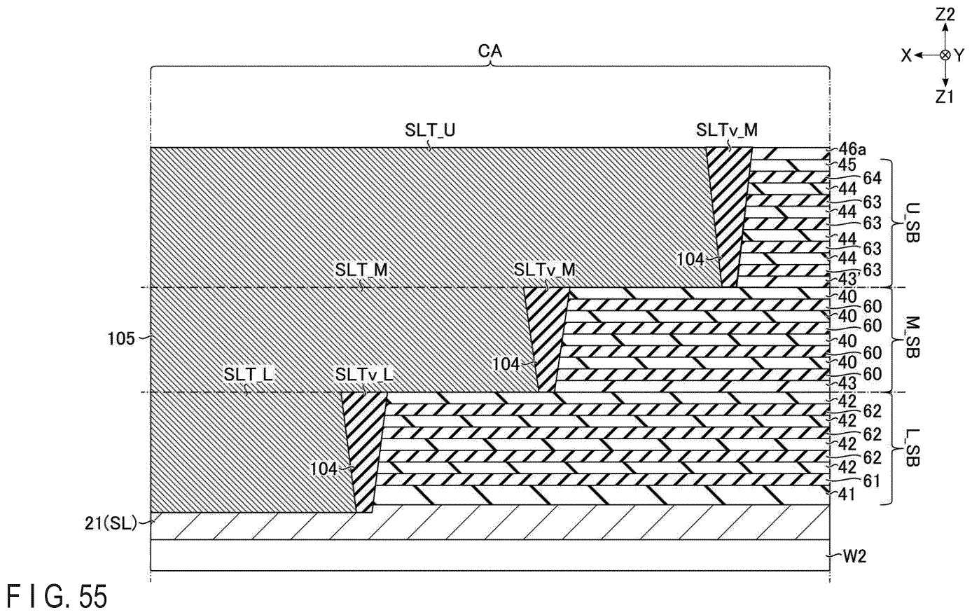

Then, as shown in FIG. 55, as in the first embodiment, the holes SH_L, SH_M and SH_U are each filled with the spacer SP and the conductor 105 (contact LI). In this way, the members SLT are formed. The plan structure of the lower laminate L_SB after the members SLT are formed viewed from above (the first structure from the top of the sheet), the plan structure of the middle laminate M_SB after the members SLT are formed viewed from above (the second structure from the top of the sheet) and the plan structure of the upper laminate U_SB after the members SLT are formed viewed from above (the third structure from the top of the sheet) are the same as those in the first embodiment shown in FIG. 33.

The subsequent steps are the same as those in the first embodiment shown in FIGS. 34 to 37.

Note that the step of forming the hole SH_L may be performed before the step of forming the hole SHv_L. The step of forming the hole SH_M may be performed before the step of forming the hole SHv_M. The step of forming the hole SH_U may be performed before the step of forming the hole SHv_U.

1.4.3 Effects of this Variation

With the semiconductor storage device 3 according to this embodiment, holes corresponding to the members SLT and SLTv are formed in each of the lower laminate L_SB, the middle laminate M_SB and the upper laminate U_SB. Therefore, with the semiconductor storage device 3 according to this variation, as in the first embodiment, the amount of digging of the substrate can be reduced.

Furthermore, with the semiconductor storage device 3 according to this variation, after the hole SHv_L corresponding to the member SLTv_L is formed and is filled with the insulator 104, the hole SH_L corresponding to the lower member SLT_L is formed. Therefore, in the processing of the holes SH_L and SHv_L, no region is doubly processed. Therefore, the occurrence of penetration through the substrate can be reduced.

With the semiconductor storage device 3 according to this variation, the member SLTv_L is in contact with the wiring layer 22, the plurality of wiring layers 23, the insulator layer 61 and the plurality of insulator layers 62. The member SLTv_M is in contact with the plurality of wiring layers 20 and the plurality of insulator layers 60. The member SLTv_U is in contact with the plurality of wiring layers 24, the wiring layer 25, the plurality of insulator layers 63 and the insulator layer 64. In other words, in the region farther from the memory pillar MP than the members SLTv, the wiring layers 20 and 22 to 25 do not exist. Therefore, the size of the region farther from the memory pillar MP than the members SLTv can be reduced. Therefore, the chip size of the semiconductor storage device 3 can be reduced.

### 1.5 Second Variation

A semiconductor storage device according to a second variation of the first embodiment will be described. A semiconductor storage device 3 according to this variation differs from the semiconductor storage device 3 according to the first embodiment in the structures of the lower member SLT_L and the dividing portion DP_L and the production method. In the following, differences from the first embodiment will be mainly described.

### 1.5.1 Cross-Sectional Structure of Contact Region

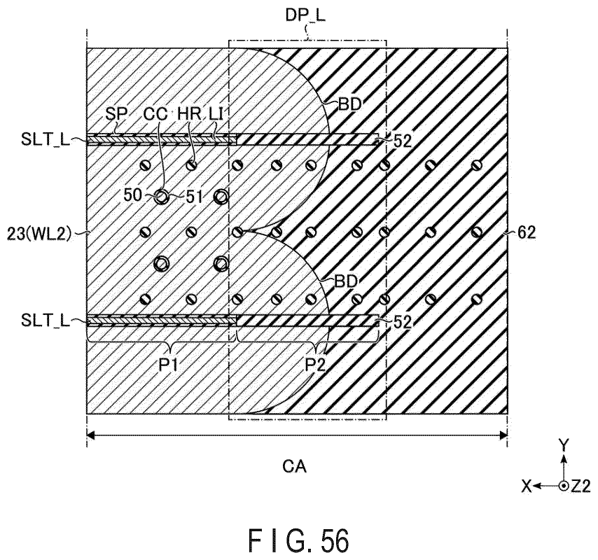

FIG. 56 is a plan view showing an example of a plan layout of the memory cell array 10 in the core region CR of the semiconductor storage device 3 according to the second variation of the first embodiment. FIG. 56 shows a plan structure including the wiring layer 23 (word line WL2) and the insulator layer 62 viewed from above the lower laminate L_SB.

As shown in FIG. 56, the lower member SLT_L extends in the Z direction and the X direction and divides the wiring layer 22 and the plurality of wiring layers 23 in the Y direction. The lower member SLT_L includes a first part P1 that includes a contact LI and a spacer SP and a second part P2 that includes an insulator 52. The first part P1 is provided closer to the memory region MA than the second part P2. The first part P1 is in contact with the second part P2. The insulator 52 contains silicon oxide, for example. The lower member SLT_L (the second part P2) penetrates boundaries BD between the wiring layer 22 and the plurality of wiring layers 23 and the insulator layer 61 and the plurality of insulator layers 62, respectively, in the X direction. That is, the second part P2 is in contact with each of the wiring layer 22 and the plurality of wiring layers 23 and each of the insulator layer 61 and the plurality of insulator layers 62. The boundary BD extends in the Z direction and the Y direction and includes a part having an arc shape in top view. The boundary BD and the second part P2 that penetrates the boundary BD in the X direction form a dividing portion DP_L. That is, the dividing portion DP_L includes the boundary BD and the second part P2 (the insulator 52). The dividing portion DP_L divides blocks BLK that are adjacent to each other in the Y direction. The dividing portion DP_L is arranged at a position closer to the memory region MA than the dividing portion DP_M. Note that the dividing portions DP_M and DP_U may have the same structure as the dividing portion DP_L shown in FIG. 56.

### 1.5.2 Production Method for Semiconductor Storage Device

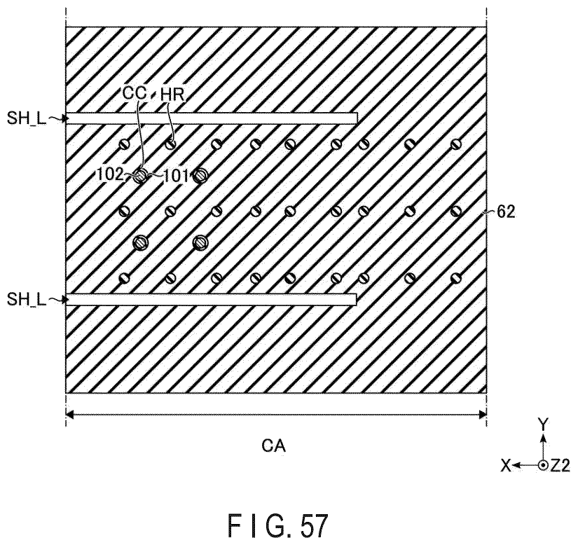

A production method for the semiconductor storage device 3 according to this variation will be described. FIGS. 57 to 63 are plan views showing examples of a plan structure during production of the semiconductor storage device 3 according to the second variation of the first embodiment. In the following, description of the step of forming the memory pillar MP and the supporting pillar HR will be omitted.

First, as in the first embodiment, on the semiconductor substrate W2, the wiring layer 21, the insulator layer 41 and the sacrificial member 61 are stacked, and then, on the sacrificial member 61, four insulator layers 42 and three sacrificial members 62 are alternately stacked one on another.

Then, as in the first embodiment, a hole CH_L corresponding to the lower contact part CC_L is provided. Then, as in the first embodiment, the forming step for the insulator 101 and the bottom removal step are performed for the hole CH_L, and then, the hole CH_L is filled with the sacrificial member 102.

Then, as shown in FIG. 57, as in the first embodiment, a hole SH_L corresponding to the lower member SLT_L is provided. The holes SH_L is formed to have such a length that the hole SH_L does not reach the position where the member SLTv_M is provided in the X direction, for example.

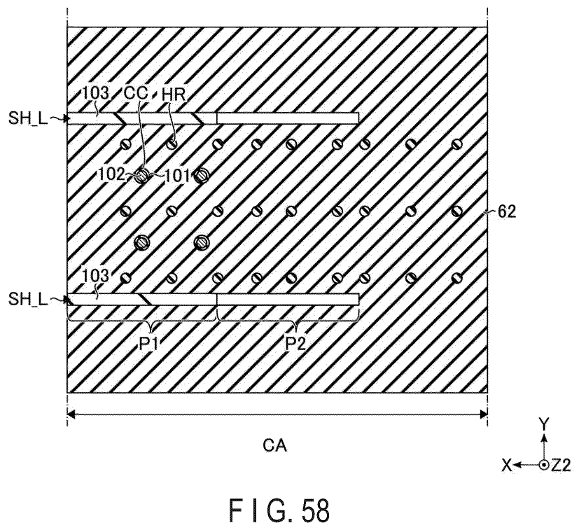

Then, as shown in FIG. 58, the of the hole SH_L that corresponds to the first part P1 is filled with the sacrificial member 103. For example, the region of the hole SH_L is filled with the sacrificial member 103 in such a manner that the length in the X direction of the region of the hole SH_L that corresponds to the second part P2 is greater than the length (distance) in the XY plane over which each of the sacrificial member 61 and the plurality of sacrificial members 62 is removed by etching in the replacement process.

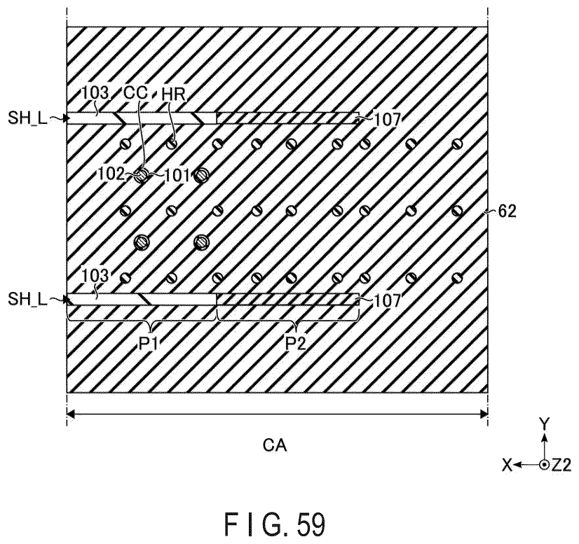

Then, as shown in FIG. 59, the region of the hole SH_L that corresponds to the second part P2 is filled with an insulator 107. The insulator 107 contains silicon oxide, for example. The insulator 107 corresponds to the insulator 52.

Then, as in the first embodiment, on the uppermost one of the insulator layers 42, the insulator layer 43 is provided, and then, as in the first embodiment, on the insulator layer 43, four sacrificial members 60 and four insulator layers 40 are alternately stacked one on another.

Then, as with the hole CH_L, a hole CH_M corresponding to the middle contact part CC_M is provided. Then, as with the hole CH_L, the forming step for the insulator 101 and the bottom removal step are performed for the hole CH_M, and then, the hole CH_M is filled with the sacrificial member 102.

Then, as in the first embodiment, a hole SHv_M corresponding to the member SLTv_M and a hole SH_M corresponding to the middle member SLT_M are provided, and then, as in the first embodiment, the hole SHv_M and the hole SH_M are filled with the sacrificial member 103.

Then, as in the first embodiment, on the uppermost one of the insulator layers 40, the insulator layer 43′ is provided, and then, on the insulator layer 43′, four sacrificial members 63 and four insulator layers 44 are alternately stacked one on another. Then, as in the first embodiment, on the uppermost one of the insulator layers 44, the sacrificial member 64, the insulator layer 45 and the insulator layer 46a are stacked in this order.

Then, as with the hole CH_L, a hole CH_U corresponding to the upper contact part CC_U is provided. Then, as with the hole CH_L, the forming step for the insulator 101 and the bottom removal step are performed for the hole CH_U, and then, the hole CH_U is filled with the sacrificial member 102.

Then, as with the holes SHv_M and SH_M, a hole SHv_U corresponding to the member SLTv_U and a hole SH_U corresponding to the upper member SLT_U are provided.

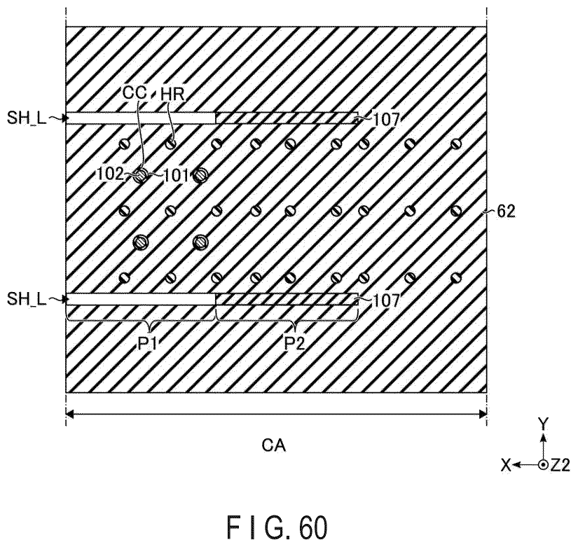

Then, as shown in FIG. 60, the sacrificial members 103 filling the holes SHv_M, SH_L and SH_M are removed by wet etching, for example.

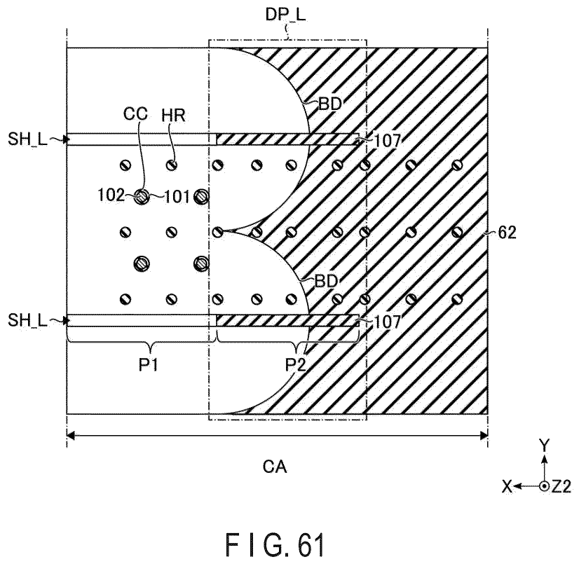

Then, as shown in FIG. 61, the sacrificial members 60 to 64 are removed by wet etching using phosphoric acid, for example. In this step, in the XY plane including each of the sacrificial member 61 and the plurality of sacrificial members 62, the etchant reaches a position at an equal distance from the end of the first part P1 in the X direction opposite to the memory region MA. Therefore, a semicircular part of each of the sacrificial member 61 and the plurality of sacrificial members 62 is removed with respect to the end of the first part P1 in the X direction opposite to the memory region MA. In this way, a boundary BD including a part having an arc shape in top view is formed. In addition, in the XY plane including each of the sacrificial member 61 and the plurality of sacrificial members 62, the etchant does not reach the end of the second part P2 in the X direction opposite to the memory region MA. In this way, the second part P2 that penetrates the boundary BD in the X direction is formed. In the region farther from the memory region MA than the boundary BD and the second part P2 that penetrates the boundary BD in the X direction, a region is formed in which each of the sacrificial member 61 and the plurality of sacrificial members 62 is not removed. In this way, the dividing portion DP_L is formed. The sacrificial members 60, 63 and 64 are removed in the same manner as in the first embodiment.

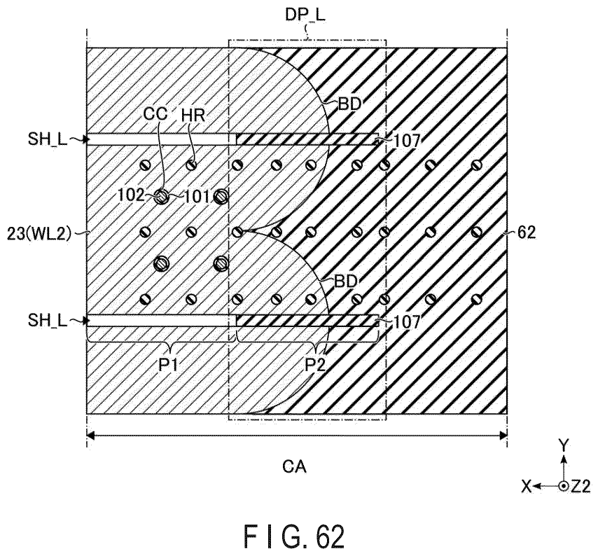

Then, as shown in FIG. 62, as in the first embodiment, in the regions (gaps) in which the sacrificial members 60 to 64 are removed, the wiring layers 20 and 22 to 25 are provided (replacement process).

Then, as in the first embodiment, the holes SHv_M and SHv_U are each filled with the insulator 104.

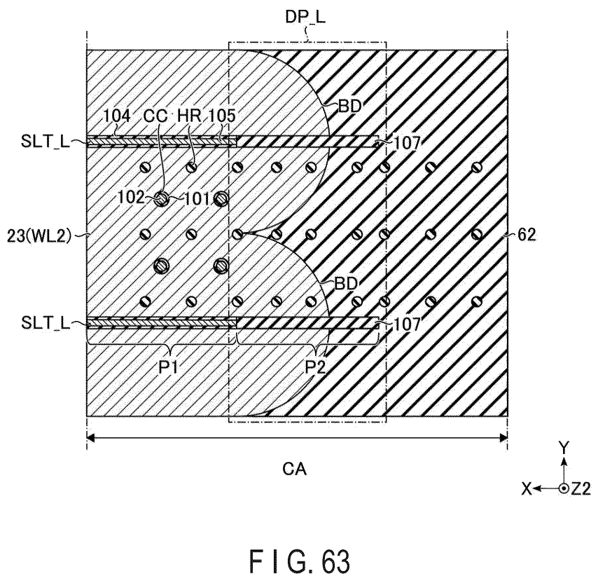

Then, as shown in FIG. 63, as in the first embodiment, the first part P1 of the hole SH_L and the holes SH_M and SH_U are each filled with the spacer SP and the conductor 105 (contact LI).

The subsequent steps are the same as those in the first embodiment shown in FIGS. 34 to 37.

1.5.3 Effects of this Variation

With the semiconductor storage device 3 according to this variation, holes corresponding to the members SLT and SLTv are formed in each of the lower laminate L_SB, the middle laminate M_SB and the upper laminate U_SB. Therefore, with the semiconductor storage device 3 according to this variation, as in the first embodiment, the amount of digging of the substrate can be reduced.

Furthermore, with the semiconductor storage device 3 according to this variation, after the hole SH_L corresponding to the member SLT_L is formed in the lower laminate L_SB, the hole SH_L is filled with the sacrificial member 103 and the insulator 107. Then, after the sacrificial member 103 is removed, the sacrificial members 60 to 64 are removed. In this way, the dividing portion DP_L is formed. In other words, in the lower laminate L_SB, the hole SHv_L corresponding to the member SLTv_L is not formed. Therefore, the amount of digging of the substrate can be reduced.

### 2. Second Embodiment

A semiconductor storage device according to a second embodiment will be described. A semiconductor storage device 3 according to this embodiment differs from the semiconductor storage device 3 according to the first embodiment in the structures of the lower laminate L_SB, the middle laminate M_SB and the upper laminate U_SB and the production method. In the following, differences from the first embodiment will be mainly described.

### 2.1 Plan Layout of Memory Cell Array

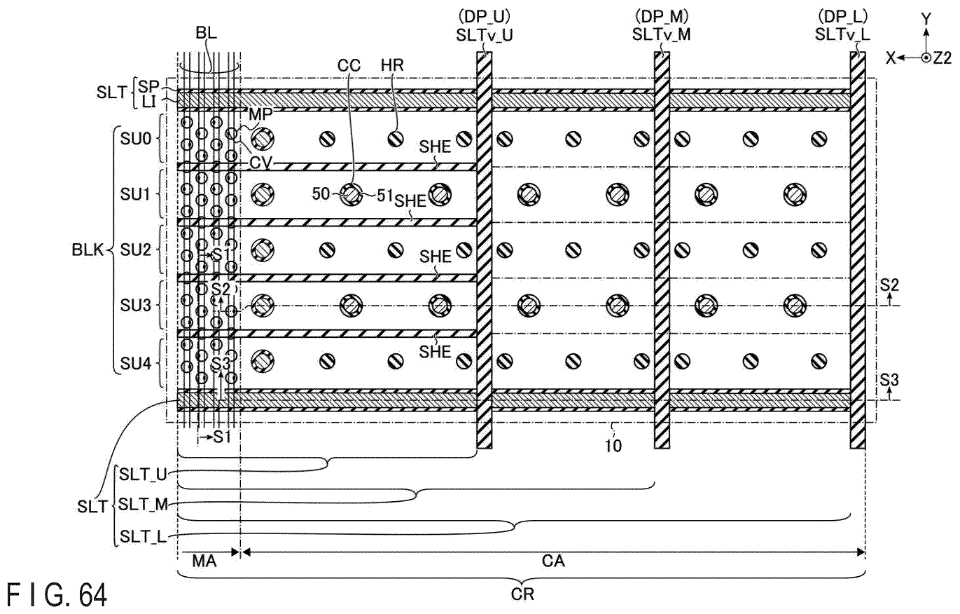

A plan layout of a memory cell array 10 will be described with reference to FIG. 64. FIG. 64 is a plan view showing an example of the plan layout of the memory cell array 10 in a core region CR of the semiconductor storage device 3 according to the second embodiment. FIG. 64 shows a region corresponding to one block BLK included in the memory cell array 10. Note that illustration of the interlayer insulating film is omitted.

As shown in FIG. 64, each member SLT has a portion provided to extend in the X direction and is arranged to span a memory region MA and a contact region CA. Two members SLT are arranged in the Y direction. An end portion of each member SLT opposite to the memory region MA in the X direction is in contact with a member SLTv_L. Each member SLT divides multilayer wiring on opposite sides of the member SLT.

An upper member SLT_U, a middle member SLT_M and a lower member SLT_L span the memory region MA and the contact region CA. An end portion of the upper member SLT_U opposite to the memory region MA in the X direction is in contact with a member SLTv_U. An end portion of the middle member SLT_M opposite to the memory region MA in the X direction is in contact with a member SLTv_M. An end portion of the lower member SLT_L opposite to the memory region MA in the X direction is in contact with a member SLTv_L.

Each member SHE has a portion provided to extend in the X direction and is arranged to span the memory region MA and the contact region CA. A plurality of members SHE are arranged in the Y direction. An end portion of each member SHE opposite to the memory region MA in the X direction is in contact with the member SLTv_U. Each member SHE divides wiring (at least a selection gate line SGD) on the opposite sides of the member SHE.

The members SLTv_L, SLTv_M and SLTv_U are arranged in the contact region CA. The members SLTv_L, SLTv_M and SLTv_U are arranged in the order of SLTv_U, SLTv_M and SLTv_L from the side of the memory region MA.

The member SLTv_L has a portion provided to extend in the Y direction. The member SLTv_L is in contact with the lower member SLT_L of each member SLT on the side closer to the memory region MA. The member SLTv_L divides blocks BLK adjacent to each other in the Y direction.

The member SLTv_M has a portion provided to extend in the Y direction. The member SLTv_M is in contact with the middle member SLT_M of each member SLT on the side closer to the memory region MA. The member SLTv_M divides blocks BLK adjacent to each other in the Y direction.

The member SLTv_U has a portion provided to extend in the Y direction. The member SLTv_U is in contact with the upper member SLT_U of each member SLT and each member SHE on the side closer to the memory region MA. The member SLTv_U divides blocks BLK adjacent to each other in the Y direction.

Note that the other blocks BLK have the same structure as that shown in FIG. 64. When the memory cell array 10 includes a plurality of blocks BLK, for example, the structure shown in FIG. 64 is repeatedly arranged in the Y direction.

The plan layout of the memory cell array 10 included in the semiconductor storage device 3 may be other layouts. For example, the number of the members SHE arranged between two adjacent members SLT can be any number. The number of the string units SU included in each block BLK can be modified based on the number of the members SHE arranged between two adjacent members SLT. The number of the members SLTv can be any number equal to or greater than 2 and can be modified according to the structure of the memory cell array 10.

### 2.2 Plan Layout of Memory Region

The plan layout of the memory region MA is the same as the plan layout according to the first embodiment shown in FIG. 5.

### 2.3 Plan Layout of Contact Region

Still referring to FIG. 64, a plan layout of the contact region CA will be described.

Contacts CC are arranged in regions excluding the members SLT, SHE and SLTv in the contact region CA. In this example, five contacts CC are arranged in the Y direction in the vicinity of the memory region MA. These five contacts CC are disposed in regions corresponding to string units SU0 to SU4, respectively. These five contacts CC are connected to the selection gate line SGD, for example.

In the region corresponding to the string unit SU1, six contacts CC are arranged in addition to the contact CC in the vicinity of the memory region MA. Between the contact CC in the vicinity of the memory region MA and the member SLTv_U, two contacts CC are arranged side by side in the X direction. For example, of these two contacts CC, the one closer to the memory region MA is connected to a word line WL10, and the other is connected to a word line WL8. Between the member SLTv_U and the member SLTv_M, two contacts CC are arranged side by side in the X direction. For example, of these two contacts CC, the one closer to the memory region MA is connected to a word line WL6, and the other is connected to a word line WL4. Between the member SLTv_M and the member SLTv_L, two contacts CC are arranged side by side in the X direction. For example, of these two contacts CC, the one closer to the memory region MA is connected to a word line WL2, and the other is connected to a word line WL0.

In the region corresponding to the string unit SU3, six contacts CC are arranged in addition to the contact CC in the vicinity of the memory region MA. Between the contact CC in the vicinity of the memory region MA and the member SLTv_U, two contacts CC are arranged side by side in the X direction. For example, of these two contacts CC, the one closer to the memory region MA is connected to a word line WL9, and the other is connected to a word line WL7. Between the member SLTv_U and the member SLTv_M, two contacts CC are arranged side by side in the X direction. For example, of these two contacts CC, the one closer to the memory region MA is connected to a word line WL5, and the other is connected to a word line WL3. Between the member SLTv_M and the member SLTv_L, two contacts CC are arranged side by side in the X direction. For example, of these two contacts CC, the one closer to the memory region MA is connected to a word line WL1, and the other is connected to a selection gate line SGS.

Supporting pillars HR are appropriately arranged in regions excluding the members SLT, SHE and SLTv and the contacts CC in the contact region CA. In this example, the supporting pillars HR are arranged in the same manner as in the first embodiment shown in FIG. 5.

The plan layout of the contact region CA of the memory cell array 10 included in the semiconductor storage device 3 may be other layouts. For example, the number and arrangement of the contacts CC and the supporting pillars HR can be modified as required.

### 2.4 Cross-Sectional Structure of Memory Region

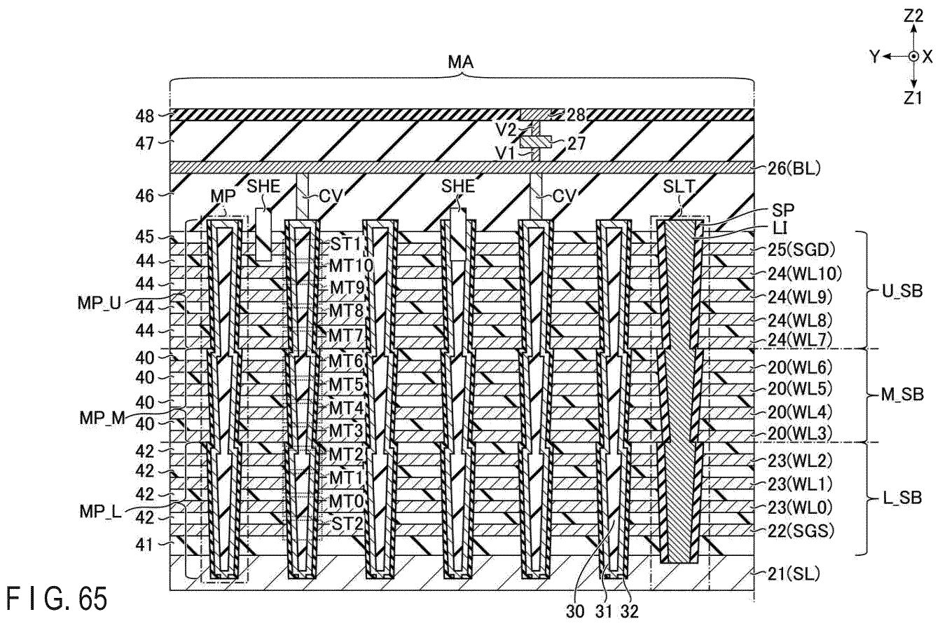

A cross-sectional structure of the memory region MA will be described with reference to FIG. 65. FIG. 65 is a cross-sectional view taken along the line S1-S1 in FIG. 64, showing an example of the cross-sectional structure in the memory region MA of the memory cell array 10 included in the semiconductor storage device 3 according to the second embodiment. As shown in FIG. 65, in the memory region MA in the memory cell array 10, the insulator layers 43 and 43′ in the cross-sectional structure according to the first embodiment shown in FIG. 6 are omitted. In the following description, it is assumed that the Z2 direction is the upward direction, and the Z1 direction is the downward direction.

The cross-sectional structure below the uppermost one of the insulator layers 42 is the same as the cross-sectional structure according to the first embodiment shown in FIG. 6. On the uppermost one of the insulator layers 42, wiring layers 20 and insulator layers 40 are alternately stacked. On the uppermost one of the insulator layers 40, wiring layers 24 and insulator layers 44 are alternately stacked. On the uppermost one of the insulator layers 44, a wiring layer 25, an insulator layer 45 and an insulator layer 46 are stacked in this order. The cross-sectional structure above the insulator layer 46 is the same as the cross-sectional structure according to the first embodiment shown in FIG. 6.

The structures of the memory pillar MP, the members SLT and the members SHE are the same as the structures according to the first embodiment shown in FIG. 6.

### 2.5 Cross-Sectional Structure of Contact Region

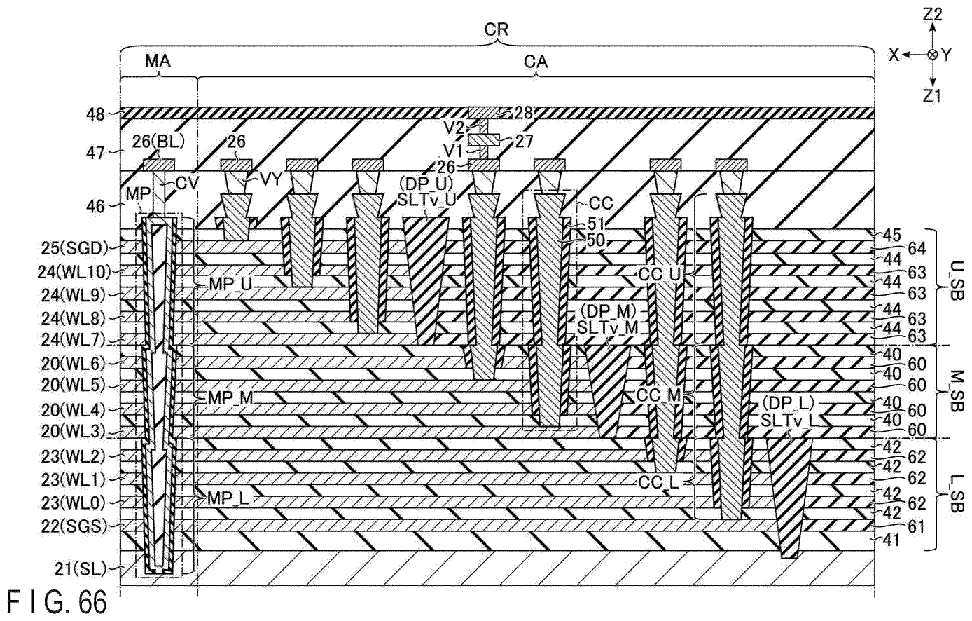

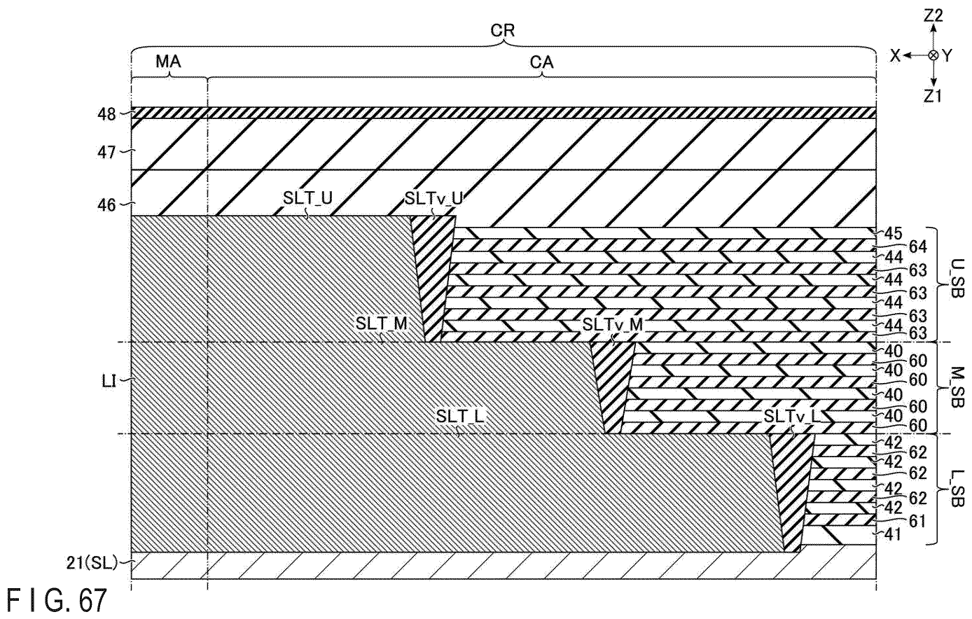

A cross-sectional structure of the contact region CA will be described with reference to FIGS. 66 and 67. FIG. 66 is a cross-sectional view taken along the line S2-S2 in FIG. 64, showing an example of the cross-sectional structure in the contact region CA of the memory cell array 10 included in the semiconductor storage device 3 according to the second embodiment. FIG. 66 also shows a cross-sectional structure in the memory region MA in the vicinity of the contact region CA. The cross-sectional structure in the memory region MA is the same as the structure shown in FIG. 65. As shown in FIG. 66, in the contact region CA in the memory cell array 10, the insulator layers 43 and 43′ in the cross-sectional structure according to the first embodiment shown in FIG. 8 are omitted. In the following description, it is assumed that the Z2 direction is the upward direction, and the Z1 direction is the downward direction.

Each contact CC is provided to extend in the Z direction and has a cylindrical shape, for example. The plurality of contacts CC are provided on the selection gate line SGS, the word lines WL0 to WL10 and the selection gate line SGD.

First, lower wiring contacts CC will be described. Each lower wiring contact CC includes a lower contact part CC_L, a middle contact part CC_M and an upper contact part CC_U.

The lower contact part CC_L extends in the Z direction and is connected to any of the wiring layer 22 and the plurality of wiring layers 23. In other words, the lower contact part CC_L penetrates the wiring layers 23 and the insulator layers 42 above the wiring layer to which the contact CC is connected (any of the selection gate line SGS and the word lines WL0 to WL2). The lower contact part CC_L includes a conductor 50 and an insulator 51 that covers at least a part of the side face of the conductor 50. The middle contact part CC_M is provided on the lower contact part CC_L and penetrates a plurality of insulator layers 60 and a plurality of insulator layers 40 in the Z direction. The upper end of the lower contact part CC_L and the lower end of the middle contact part CC_M are in contact with each other at the interface between the insulator layer 42 and the insulator layer 60. In other words, the upper end of the lower contact part CC_L is in contact with the lowermost one of the insulator layers 60 that is provided in the same layer as the lowermost one of the wiring layers 20. The middle contact part CC_M includes the conductor 50 and the insulator 51 that covers a side face of the conductor 50. The upper contact part CC_U is provided on the middle contact part CC_M and penetrates a plurality of insulator layers 63, an insulator layer 64, a plurality of insulator layers 44 and an insulator layer 45 in the Z direction. The upper end of the middle contact part CC_M and the lower end of the upper contact part CC_U are in contact with each other at the interface between the insulator layer 40 and the insulator layer 63. In other words, the upper end of the middle contact part CC_M is in contact with the lowermost one of the insulator layers 63 that is provided in the same layer as the lowermost one of the wiring layers 24. The upper contact part CC_U includes the conductor 50 and the insulator 51 that covers at least a part of the side face of the conductor 50.

The upper end of the conductor 50 is located in the insulator layer 46, and the lower end of the conductor 50 is in contact with the wiring layer to which the conductor 50 is connected. The upper end of the insulator 51 is located at a lower level than the upper end of the conductor 50 in the insulator layer 46, and the lower end of the insulator 51 is in contact with the insulator layer 42 on the wiring layer to which the conductor 50 is connected. That is, the insulator 51 covers the side face of the conductor 50 excluding the top part and the bottom part of the conductor 50.

As described above, the lower wiring contact CC extends in the Z direction, penetrates the middle laminate M_SB (the plurality of insulator layers 60) and the upper laminate U_SB (the plurality of insulator layers 63 and the insulator layer 64) and is connected to any of the wiring layer 22 and the plurality of wiring layers 23, and at least a part of the side face of the lower wiring contact CC is covered by the insulator 51.

Next, middle wiring contacts CC will be described. Each middle wiring contact CC includes a middle contact part CC_M and an upper contact part CC_U.

The middle contact part CC_M extends in the Z direction and is connected to any of the plurality of wiring layers 20. In other words, the middle contact part CC_M penetrates the wiring layers 20 and the insulator layers 40 above the wiring layer to which the contact CC is connected (any of the word lines WL3 to WL6). The middle contact part CC_M includes the conductor 50 and the insulator 51 that covers at least a part of the side face of the conductor 50. The upper contact part CC_U is provided on the middle contact part CC_M and penetrates the plurality of insulator layers 63, the insulator layer 64, the plurality of insulator layers 44 and the insulator layer 45 in the Z direction. The upper end of the middle contact part CC_M and the lower end of the upper contact part CC_U are in contact with each other at the interface between the insulator layer 40 and the insulator layer 63. In other words, the upper end of the middle contact part CC_M is in contact with the lowermost one of the insulator layers 63 that is provided in the same layer as the lowermost one of the wiring layers 24. The upper contact part CC_U includes the conductor 50 and the insulator 51 that covers at least a part of the side face of the conductor 50.

The upper end of the conductor 50 is located in the insulator layer 46, and the lower end of the conductor 50 is in contact with the wiring layer to which the conductor 50 is connected. The upper end of the insulator 51 is located at a lower level than the upper end of the conductor 50 in the insulator layer 46, and the lower end of the insulator 51 is in contact with the insulator layer 40 on the wiring layer to which the conductor 50 is connected. That is, the insulator 51 covers the side face of the conductor 50 excluding the top part and the bottom part of the conductor 50.

As described above, the middle wiring contact CC extends in the Z direction, penetrates the upper laminate U_SB (the plurality of insulator layers 63 and the insulator layer 64) and is connected to any of the plurality of wiring layers 20, and at least a part of the side face of the middle wiring contact CC is covered by the insulator 51.

Next, upper wiring contacts CC will be described. Each upper wiring contact CC includes an upper contact part CC_U.

The upper contact part CC_U extends in the Z direction and is connected to any of the plurality of wiring layers 24 and the wiring layer 25. In other words, the upper contact part CC_U associated with any of the word lines WL7 to WL10 penetrates the wiring layers 24 and 25 and the insulator layers 44 and 45 above the wiring layer to which the contact CC is connected. The upper contact part CC_U associated with the selection gate line SGD penetrates the insulator layer 45 on the selection gate line SGD. The upper contact part CC_U includes the conductor 50 and the insulator 51 that covers at least a part of the side face of the conductor 50.

The upper end of the conductor 50 is located in the insulator layer 46, and the lower end of the conductor 50 is in contact with the wiring layer to which the conductor 50 is connected. The upper end of the insulator 51 is located at a lower level than the upper end of the conductor 50 in the insulator layer 46, and the lower end of the insulator 51 is in contact with the insulator layer 44 or 45 on the wiring layer to which the conductor 50 is connected. That is, the insulator 51 covers the side face of the conductor 50 excluding the top part and the bottom part of the conductor 50.

As described above, the upper wiring contact CC extends in the Z direction and is connected to any of the plurality of wiring layers 24 and the wiring layer 25, and at least a part of the side face of the upper wiring contact CC is covered by the insulator 51.

For example, each of the lower contact part CC_L and the middle contact part CC_M increases in cross-sectional area in the XY plane (XY cross-sectional area) from the bottom to the top. In addition, the part of the upper contact part CC_U below the top part in which the conductor 50 is not covered by the insulator 51 increases in cross-sectional area in the XY plane from the bottom to the top. The top part of the upper contact part CC_U in which the conductor 50 is not covered by the insulator 51 also increases in cross-sectional area in the XY plane from the bottom to the top. At the juncture between the lower contact part CC_L and the middle contact part CC_M, the side face of the lower contact part CC_L and the side face of the middle contact part CC_M are offset from each other. At the juncture between the middle contact part CC_M and the upper contact part CC_U, the side face of the middle contact part CC_M and the side face of the upper contact part CC_U are offset from each other.

Each of the member SLTv_L (dividing portion DP_L), the member SLTv_M (dividing portion DP_M) and the member SLTv_U (dividing portion DP_U) is formed to spread in the YZ plane, for example. The member SLTv_L extends in the Z direction and the Y direction and divides the wiring layer 22 and the plurality of wiring layers 23 in the X direction. The position of the upper end of the member SLTv_L is at the same level as the interface between the insulator layer 42 and the insulator layer 60, for example. The lower end of the member SLTv_L is located in the wiring layer 21, for example. The member SLTv_M extends in the Z direction and the Y direction and divides the plurality of wiring layers 20 in the X direction. The position of the upper end of the member SLTv_M is at the same level as the interface between the insulator layer 40 and the insulator layer 63, for example. The lower end of the member SLTv_M is at the same level as the interface between the insulator layer 42 and the insulator layer 60, for example. The member SLTv_U extends in the Z direction and the Y direction and divides the plurality of wiring layers 24 and the wiring layer 25 in the X direction. The upper end of the member SLTv_U is located in the insulator layer 46, for example. The position of the lower end of the member SLTv_U is at the same level as the interface between the insulator layer 40 and the insulator layer 63, for example. For example, each of the member SLTv_L, the member SLTv_M and the member SLTv_U increases in cross-sectional area in the XY plane (XY cross-sectional area) from the bottom to the top.

The member SLTv_U is disposed at a position closer to the memory pillar MP than the member SLTv_M. The member SLTv_M is disposed at a position closer to the memory pillar MP than the member SLTv_L. In other words, the member SLTv_U does not overlap with the member SLTv_L and the member SLTv_M in the Z direction, and the member SLTv_M does not overlap with the member SLTv_L in the Z direction.

The upper wiring contacts CC are arranged in the region between the memory pillar MP and the member SLTv_U. In addition, the upper wiring contacts CC are arranged above the plurality of wiring layers 20. The middle wiring contacts CC are arranged in the region between the member SLTv_U and the member SLTv_M. In addition, the middle wiring contacts CC are arranged above the wiring layer 22 and the plurality of wiring layers 23. The lower wiring contacts CC are arranged in the region between the member SLTv_M and the member SLTv_L.

The insulator layer 61 and the plurality of insulator layers 62 are disposed at positions farther from the memory pillar MP than the member SLTv_L. In other words, the member SLTv_L is disposed closer to the memory pillar MP than the insulator layer 61 and the plurality of insulator layers 62. The member SLTv_L is in contact with the wiring layer 22, the plurality of wiring layers 23, the insulator layer 61 and the plurality of insulator layers 62. In other words, in a region farther from the memory pillar MP than the member SLTv_L, the lower laminate L_SB does not include the wiring layer 22 and the plurality of wiring layers 23, although the lower laminate L_SB includes the insulator layer 61 and the plurality of insulator layers 62. In the region farther from the memory pillar MP than the member SLTv_L, the insulator layer 41 and the insulator layer 61 are stacked on the wiring layer 21 in this order. The insulator layer 61 is provided in the same layer as the wiring layer 22. On the insulator layer 61, the insulator layers 42 and the insulator layers 62 are alternately stacked. Each of the plurality of insulator layers 62 is provided in the same layer as one of the plurality of wiring layers 23.

The plurality of insulator layers 60 are disposed at positions farther from the memory pillar MP than the member SLTv_M. In other words, the member SLTv_M is disposed closer to the memory pillar MP than the plurality of insulator layers 60. In addition, the member SLTv_M is disposed above the wiring layer 22 and the plurality of wiring layers 23. The member SLTv_M is in contact with the plurality of wiring layers 20 and the plurality of insulator layers 60. In other words, in a region farther from the memory pillar MP than the member SLTv_M, the middle laminate M_SB does not include the plurality of wiring layers 20, although the middle laminate M_SB includes the plurality of insulator layers 60. In the region farther from the memory pillar MP than the member SLTv_M, the insulator layers 60 and the insulator layers 40 are alternately stacked on the uppermost one of the insulator layers 42. Each of the plurality of insulator layers 60 is provided in the same layer as one of the plurality of wiring layers 20.

The plurality of insulator layers 63 and the insulator layer 64 are disposed at positions farther from the memory pillar MP than the member SLTv_U. In other words, the member SLTv_U is disposed closer to the memory pillar MP than the plurality of insulator layers 63 and the insulator layer 64. In addition, the member SLTv_U is disposed above the plurality of wiring layers 20. The member SLTv_U is in contact with the plurality of wiring layers 24, the wiring layer 25, the plurality of insulator layers 63 and the insulator layer 64. In other words, in a region farther from the memory pillar MP than the member SLTv_U, the upper laminate U_SB does not include the plurality of wiring layers 24 and the wiring layer 25, although the upper laminate U_SB includes the plurality of insulator layers 63 and the insulator layer 64. In the region farther from the memory pillar MP than the member SLTv_U, the insulator layers 63 and the insulator layers 64 are alternately stacked on the uppermost one of the insulator layers 40. Each of the plurality of insulator layers 63 is provided in the same layer as one of the plurality of wiring layers 24. On the uppermost one of the insulator layers 44, the insulator layer 64, the insulator layer 45 and the insulator layer 46 are stacked in this order. The insulator layer 64 is provided in the same layer as the wiring layer 25.

The cross-sectional structure above the insulator layer 46 is the same as the structure according to the first embodiment shown in FIG. 8.

FIG. 67 is a cross-sectional view taken along the line S3-S3 in FIG. 64, showing an example of the cross-sectional structure in the contact region CA of the memory cell array 10 included in the semiconductor storage device 3 according to the second embodiment. FIG. 67 also shows a cross-sectional structure in the memory region MA in the vicinity of the contact region CA. In the contact region CA, the cross-sectional structure in the region farther from the memory region MA than the member SLTv_L, the cross-sectional structure in the region farther from the memory region MA than the member SLTv_M and the cross-sectional structure in the region farther from the memory region MA than the member SLTv_U are the same as those shown in FIG. 66, except that no contact CC is formed.

In the region closer to the memory region MA than the member SLTv in the contact region CA, the lower member SLT_L is in contact with the member SLTv_L and penetrates the wiring layer 22 and the plurality of wiring layers 23. The position of the upper end of the lower member SLT_L is at the same level as the position of the upper end of the member SLTv_L, for example. The position of the lower end of the lower member SLT_L is at the same level as the position of the lower end of the member SLTv_L, for example. The middle member SLT_M is in contact with the member SLTv_M and penetrates the plurality of wiring layers 20. The position of the upper end of the middle member SLT_M is at the same level as the position of the upper end of the member SLTv_M, for example. The position of the lower end of the middle member SLT_M is at the same level as the position of the lower end of the member SLTv_M, for example. The upper member SLT_U is in contact with the member SLTv_U and penetrates the plurality of wiring layers 24 and the wiring layer 25. The position of the upper end of the upper member SLT_U is at the same level as the position of the upper end of the member SLTv_U, for example. The position of the lower end of the upper member SLT_U is at the same level as the position of the lower end of the member SLTv_U, for example. The cross-sectional structure in the memory region MA has the same structure. The cross-sectional structure above the insulator layer 46 is the same as the structure according to the first embodiment shown in FIG. 9.

### 2.6 Production Method for Semiconductor Storage Device

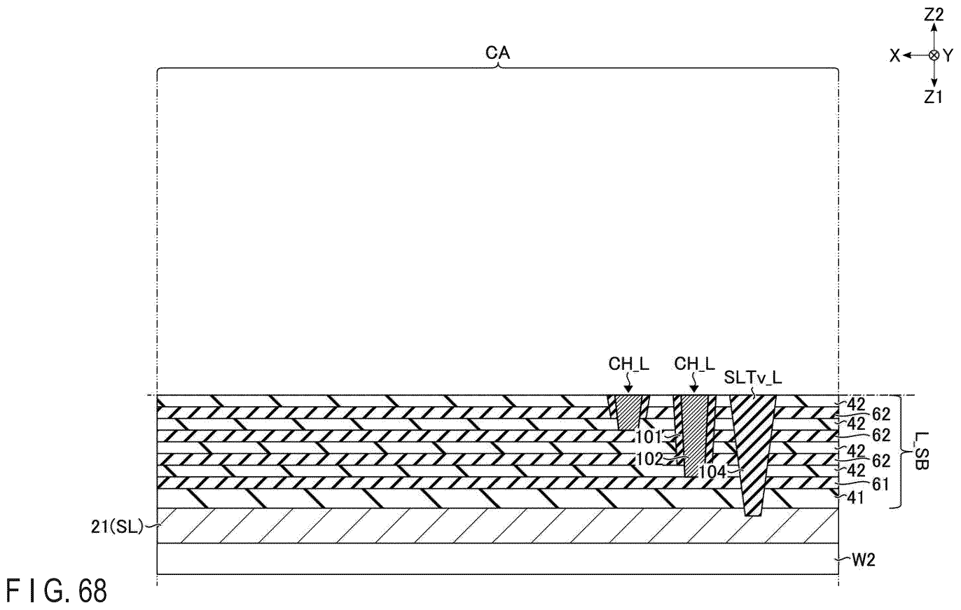

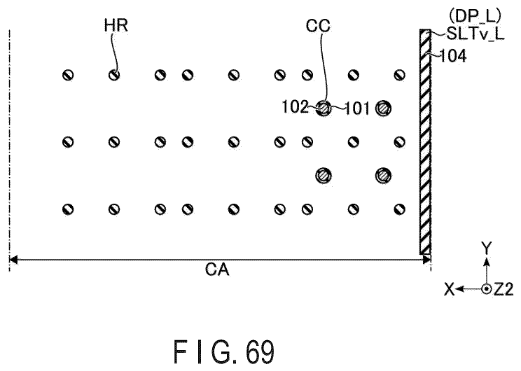

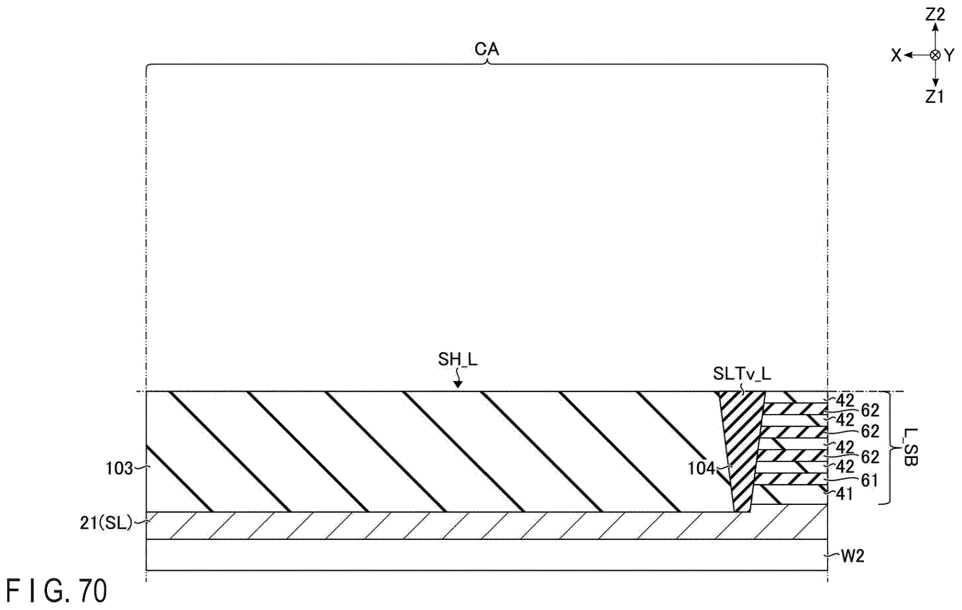

A production method for the semiconductor storage device 3 according to the second embodiment will be described with reference to FIGS. 68 to 86. FIGS. 68, 70, 72, 74, 76, 78, 80, 82, 83 and 85 are cross-sectional views showing examples of a cross-sectional structure during production of the semiconductor storage device 3 according to the second embodiment. FIGS. 68, 72, 76, 82 and 85 show cross-sectional structures corresponding to the structure in FIG. 66. FIGS. 70, 74, 78, 80 and 83 show cross-sectional structures corresponding to the structure in FIG. 67. FIGS. 69, 71, 73, 75, 77, 79, 81, 84 and 86 are plan views showing examples of a plan structure during production of the semiconductor storage device 3 according to the second embodiment. In FIGS. 69, 71, 73, 75, 77, 79, 81, 84 and 86, illustration of the interlayer insulating film is omitted. In the following, description of the step of forming the memory pillar MP and the supporting pillar HR will be omitted.

First, as shown in FIG. 68, as in the first embodiment, on the semiconductor substrate W2, the wiring layer 21, the insulator layer 41 and the sacrificial member 61 are stacked, and then, on the sacrificial member 61, four insulator layers 42 and three sacrificial members 62 are alternately stacked one on another. The wiring layer 21 contains polysilicon, for example. The insulator layers 41 and 42 contain silicon oxide, for example. The sacrificial members 61 and 62 contain silicon nitride, for example. Then, although not shown, as in the first embodiment, a hole corresponding to the lower pillar part MP_L is formed, and the hole is filled with a sacrificial member.

Then, as shown in FIG. 68, as in the first embodiment, a hole CH_L corresponding to the lower contact part CC_L is provided. The lower end of the hole CH_L corresponding to the selection gate line SGS reaches the upper face of the lowermost one of the insulator layers 42. The lower end of the hole CH_L corresponding to the word line WL1 reaches the upper face of the second uppermost one of the insulator layers 42. Then, as in the first embodiment, the forming step for an insulator 101 and the bottom removal step are performed for the holes CH_L, and then, the holes CH_L are filled with a sacrificial member 102. The insulator 101 contains silicon oxide, for example. The sacrificial member 102 contains polysilicon, for example.

Then, as shown in FIG. 68, as in the first embodiment, a hole SHv_L corresponding to the member SLTv_L is provided. The lower end of the hole SHv_L reaches into the wiring layer 21. After that, the hole SHv_L is filled with an insulator 104. In this way, the member SLTv_L is formed. The insulator 104 contains silicon oxide, for example. FIG. 69 shows a plan structure of the lower laminate L_SB after the hole SHv_L is filled with the insulator 104 viewed from above.

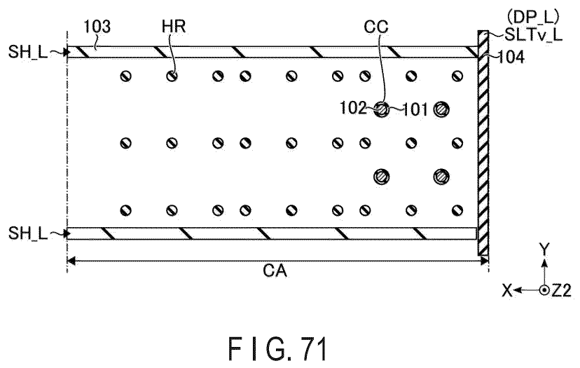

Then, as shown in FIG. 70, as in the first embodiment, a hole SH_L corresponding to the lower member SLT_L is provided. The lower end of the hole SH_L reaches into the wiring layer 21. After that, the hole SH_L is filled with an insulator 103. FIG. 71 shows a plan structure of the lower laminate L_SB after the hole SH_L is filled with the sacrificial member 103 viewed from above.

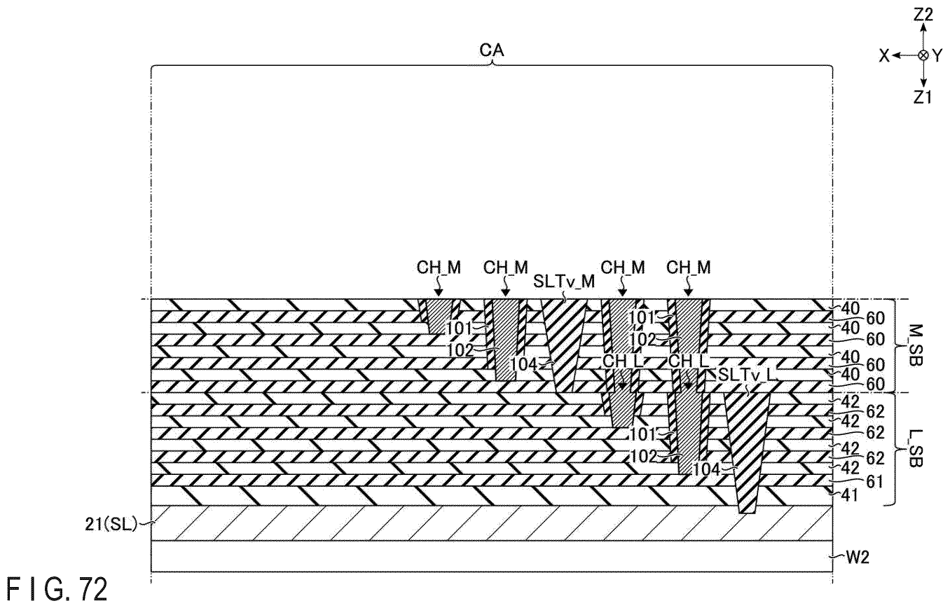

Then, as shown in FIG. 72, as in the first embodiment, on the uppermost one of the insulator layers 42, four sacrificial members 60 and four insulator layers 40 are alternately stacked one on another. The insulator layers 40 contains silicon oxide, for example. The sacrificial members 60 contain silicon nitride, for example. Then, although not shown, as in the first embodiment, a hole corresponding to the middle pillar part MP_M is provided, and the hole is filled with a sacrificial member.

Then, as shown in FIG. 72, as with the hole CH_L, a hole CH_M corresponding to the middle contact part CC_M is provided. The lower end of the hole CH_M corresponding to the selection gate line SGS and the lower end of the hole CH_M corresponding to the word line WL1 reach the upper face of the hole CH_L. The lower end of the hole CH_M corresponding to the word line WL3 reaches the upper face of the lowermost one of the insulator layers 40. The lower end of the hole CH_M corresponding to the word line WL5 reaches the upper face of the second uppermost one of the insulator layers 40. Then, as in the first embodiment, the forming step for the insulator 101 and the bottom removal step are performed for the holes CH_M, and then, the holes CH_M are filled with the sacrificial member 102.

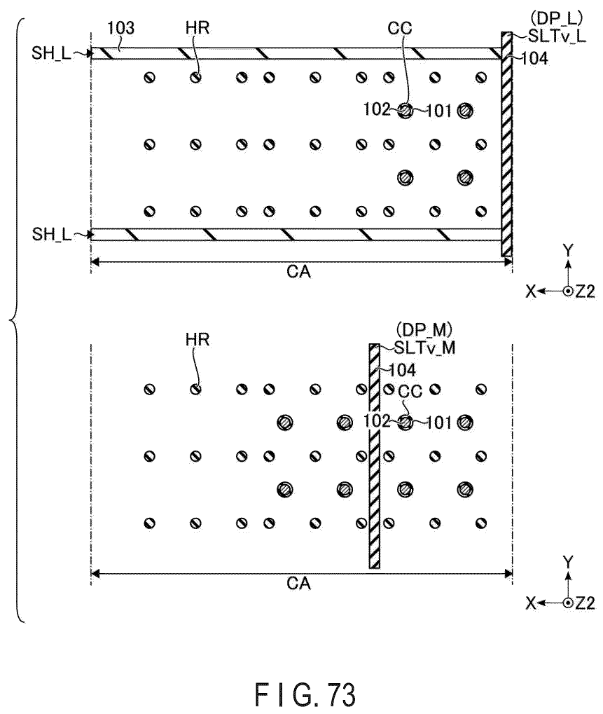

Then, as shown in FIG. 72, as with the hole SHv_L, a hole SHv_M corresponding to the member SLTv_M is provided. The lower end of the hole SHv_M reaches the interface between the insulator layer 42 and the insulator layer 60. After that, as with the hole SHv_L, the hole SHv_M is filled with the insulator 104. In this way, the member SLTv_M is formed. FIG. 73 shows a plan structure of the lower laminate L_SB after the hole SHv_M is filled with the insulator 104 viewed from above (the first structure from the top of the sheet) and a plan structure of the middle laminate M_SB after the hole SHv_M is filled with the insulator 104 viewed from above (the second structure from the top of the sheet).

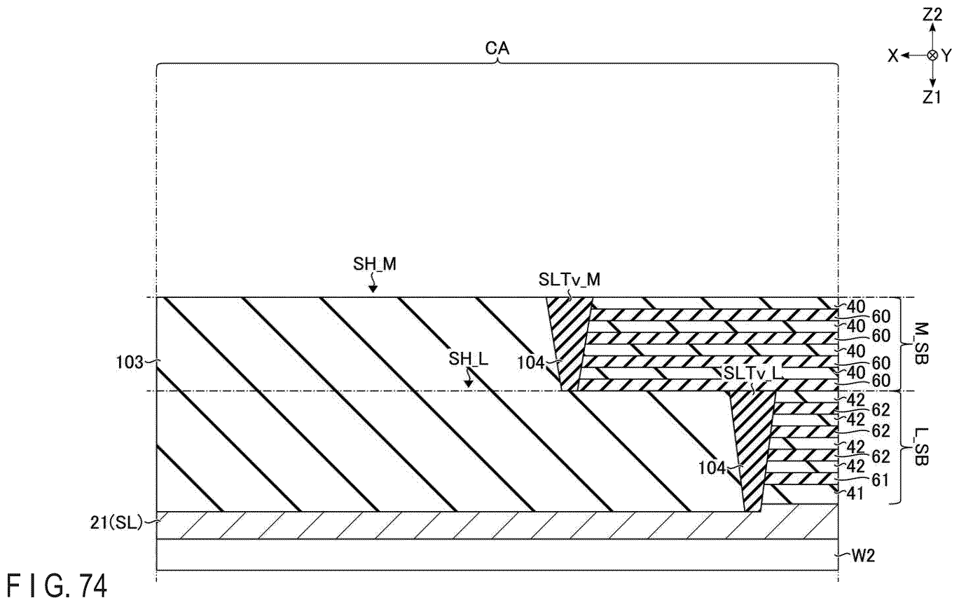

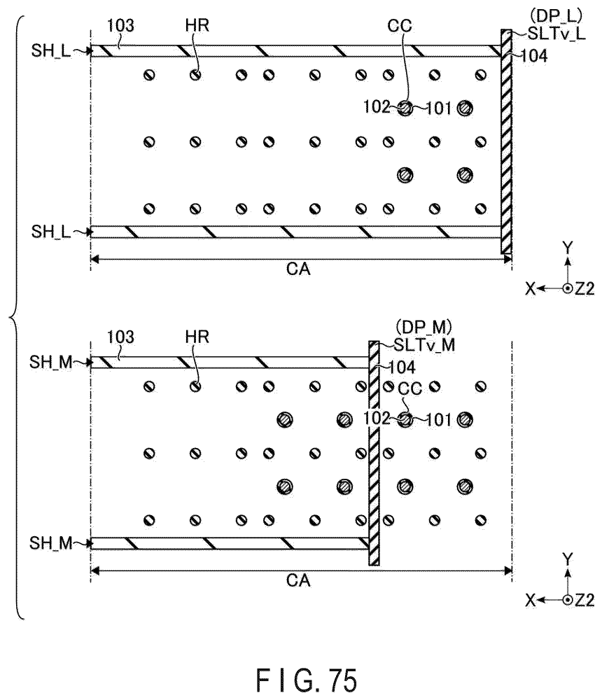

Then, as shown in FIG. 74, as with the hole SH_L, a hole SH_M corresponding to the middle member SLT_M is provided. The lower end of the hole SH_M reaches the interface between the insulator layer 42 and the insulator layer 60. After that, as with the hole SH_L, the hole SH_M is filled with the sacrificial member 103. FIG. 75 shows a plan structure of the lower laminate L_SB after the hole SH_M is filled with the sacrificial member 103 viewed from above (the first structure from the top of the sheet) and a plan structure of the middle laminate M_SB after the hole SH_M is filled with the sacrificial member 103 viewed from above (the second structure from the top of the sheet).

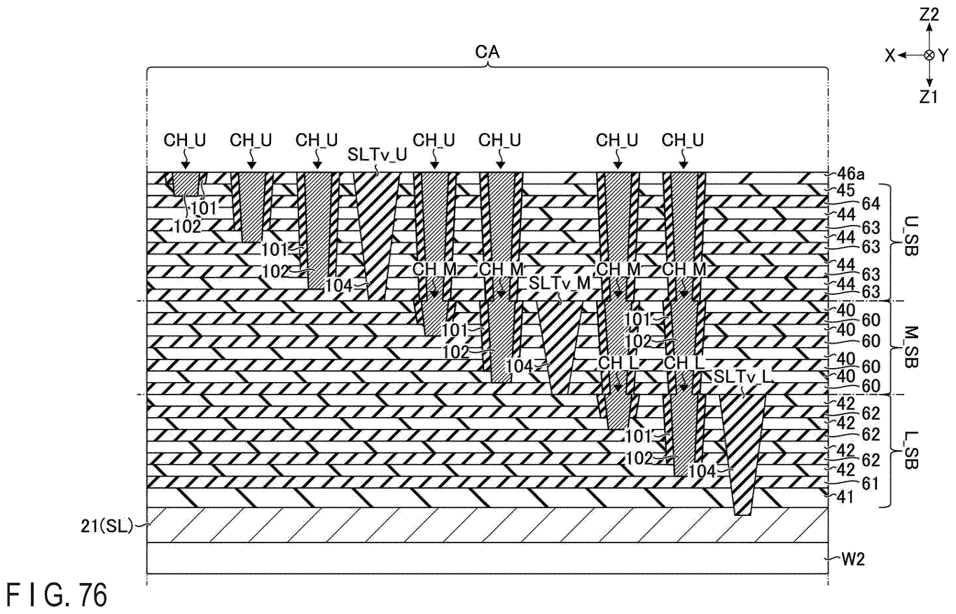

Then, as shown in FIG. 76, as in the first embodiment, on the uppermost one of the insulator layers 40, four sacrificial members 63 and four insulator layers 44 are alternately stacked one on another. Then, as in the first embodiment, on the uppermost one of the insulator layers 44, the sacrificial member 64, the insulator layer 45 and an insulator layer 46a are stacked in this order. The insulator layers 44, 45 and 46a contain silicon oxide, for example. The sacrificial members 63 and 64 contain silicon nitride, for example. Then, although not shown, as in the first embodiment, as with the hole CH_L, a hole corresponding to the upper pillar part MP_U is provided. Then, as in the first embodiment, after the sacrificial members in the holes corresponding to the lower pillar part MP_L and the middle pillar part MP_M are removed, the memory pillar MP is formed in the holes corresponding to the lower pillar part MP_L, the middle pillar part MP_M and the upper pillar part MP_U.

Then, as shown in FIG. 76, as with the hole CH_L, a hole CH_U corresponding to the upper contact part CC_U is provided. The lower end of the hole CH_U corresponding to the selection gate line SGS, the lower end of the hole CH_U corresponding to the word line WL1, the lower end of the hole CH_U corresponding to the word line WL3 and the lower end of the hole CH_U corresponding to the word line WL5 each reach the upper face of corresponding one of the holes CH_M. The lower end of the hole CH_U corresponding to the word line WL7 reaches the upper face of the lowermost one of the insulator layers 44. The lower end of the hole CH_U corresponding to the word line WL9 reaches the upper face of the second uppermost one of the insulator layers 44. The lower end of the hole CH_U corresponding to the selection gate line SGD reaches the upper face of the insulator layer 45. Then, as with the hole CH_L, after the forming step for the insulator 101 and the bottom removal step are performed for the holes CH_U, the holes CH_U are filled with the sacrificial member 102.

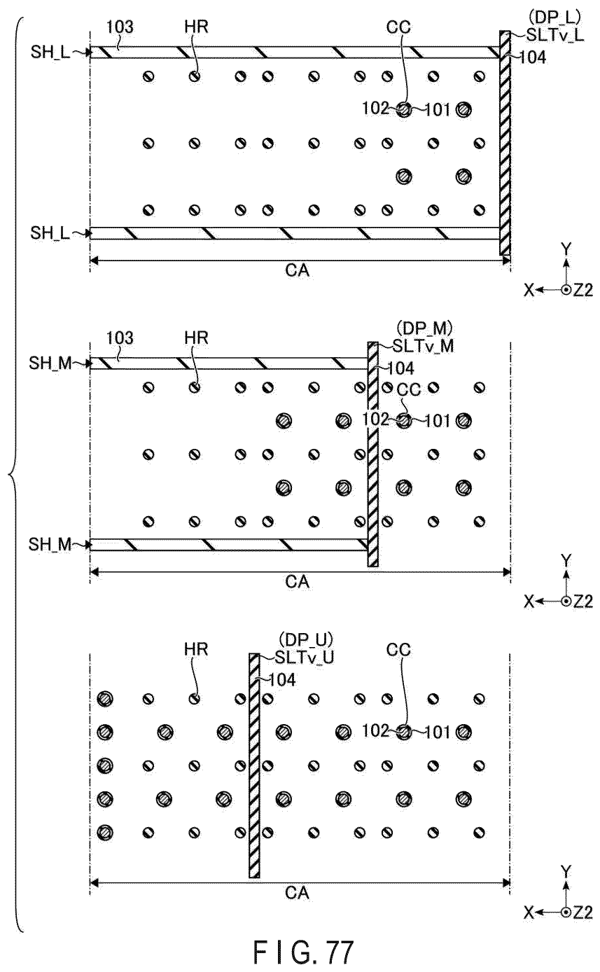

Then, as shown in FIG. 76, as with the hole SHv_L, a hole SHv_U corresponding to the member SLTv_U is provided. The lower end of the hole SHv_U reaches the interface between the insulator layer 40 and the insulator layer 63. After that, as with the hole SHv_L, the hole SHv_U is filled with the insulator 104. In this way, the member SLTv_U is formed. FIG. 77 shows a plan structure of the lower laminate L_SB after the hole SHv_U is filled with the insulator 104 viewed from above (the first structure from the top of the sheet), a plan structure of the middle laminate M_SB after the hole SHv_U is filled with the insulator 104 viewed from above (the second structure from the top of the sheet) and a plan structure of the upper laminate U_SB after the hole SHv_U is filled with the insulator 104 viewed from above (the third structure from the top of the sheet).

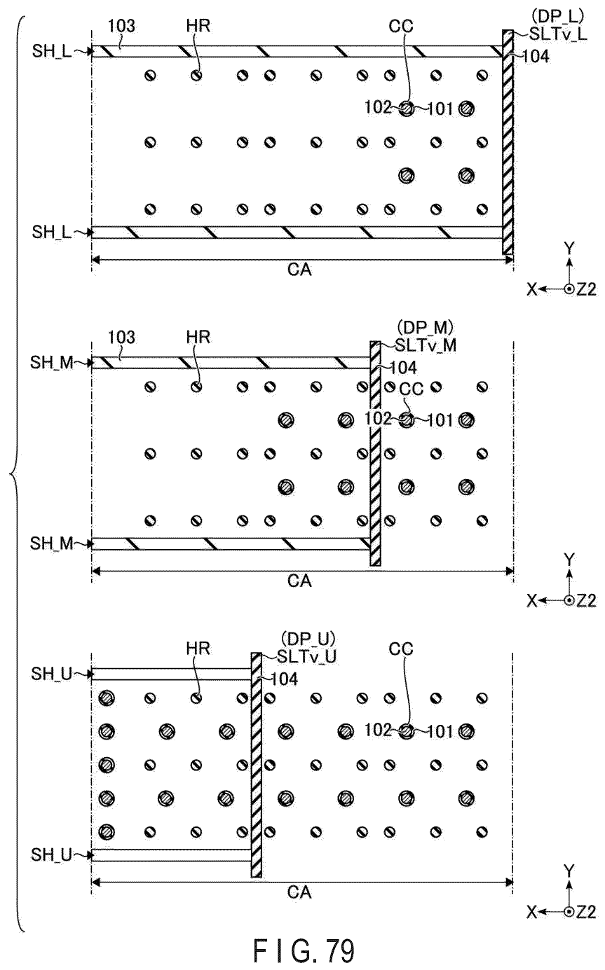

Then, as shown in FIG. 76, as with the hole SH_L, a hole SH_U corresponding to the upper member SLT_U is provided. The lower end of the hole SH_U reaches the interface between the insulator layer 40 and the insulator layer 63. FIG. 79 shows a plan structure of the lower laminate L_SB after the hole SH_U is formed viewed from above (the first structure from the top of the sheet), a plan structure of the middle laminate M_SB after the hole SH_U is formed viewed from above (the second structure from the top of the sheet) and a plan structure of the upper laminate U_SB after the hole SH_U is formed viewed from above (the third structure from the top of the sheet).

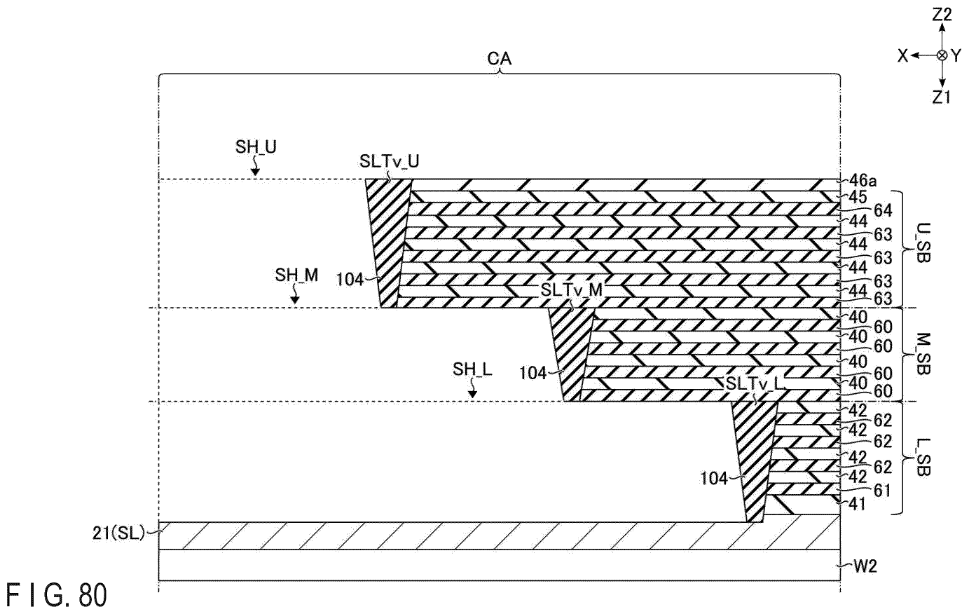

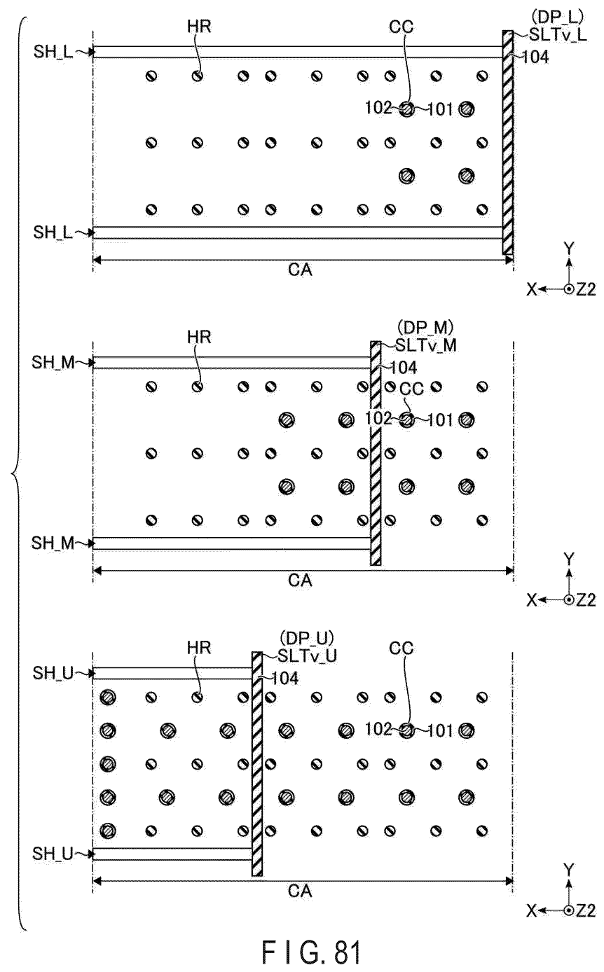

Then, as shown in FIG. 80, as in the first embodiment, the sacrificial members 103 filling the holes SH_L and SH_M are removed. FIG. 81 shows a plan structure of the lower laminate L_SB after the sacrificial members 103 are removed viewed from above (the first structure from the top of the sheet), a plan structure of the middle laminate M_SB after the sacrificial members 103 are removed viewed from above (the second structure from the top of the sheet) and a plan structure of the upper laminate U_SB after the sacrificial members 103 are removed viewed from above (the third structure from the top of the sheet).

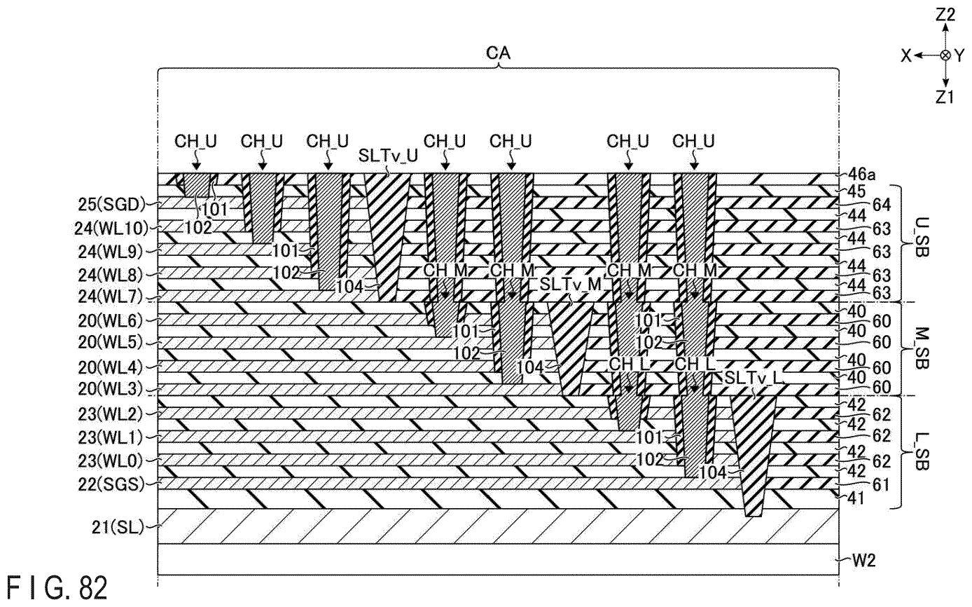

Then, as shown in FIG. 82, as in the first embodiment, the sacrificial members 60 to 64 are removed. In this step, the etchant does not reach regions farther from the memory pillar MP than the members SLTv_L, SLTv_M and SLTv_U in the X direction. As a result, in the region farther from the memory pillar MP than the member SLTv_L, each of the sacrificial member 61 and the plurality of sacrificial members 62 is not removed and remains. In the region farther from the memory pillar MP than the member SLTv_M, each of the plurality of sacrificial members 60 is not removed and remains. In the region farther from the memory pillar MP than the member SLTv_U, each of the plurality of sacrificial members 63 and the sacrificial member 64 is not removed and remains. After that, as in the first embodiment, in the regions (gaps) in which the sacrificial members 60 to 64 are removed, the wiring layers 20 and 22 to 25 are provided (replacement process). The wiring layers 20 and 22 to 25 contain tungsten, for example.

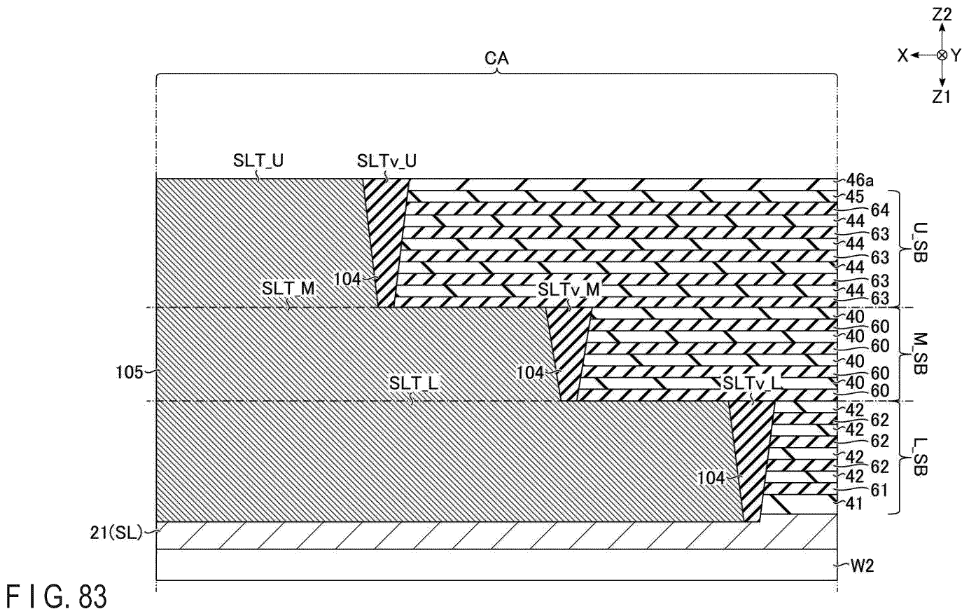

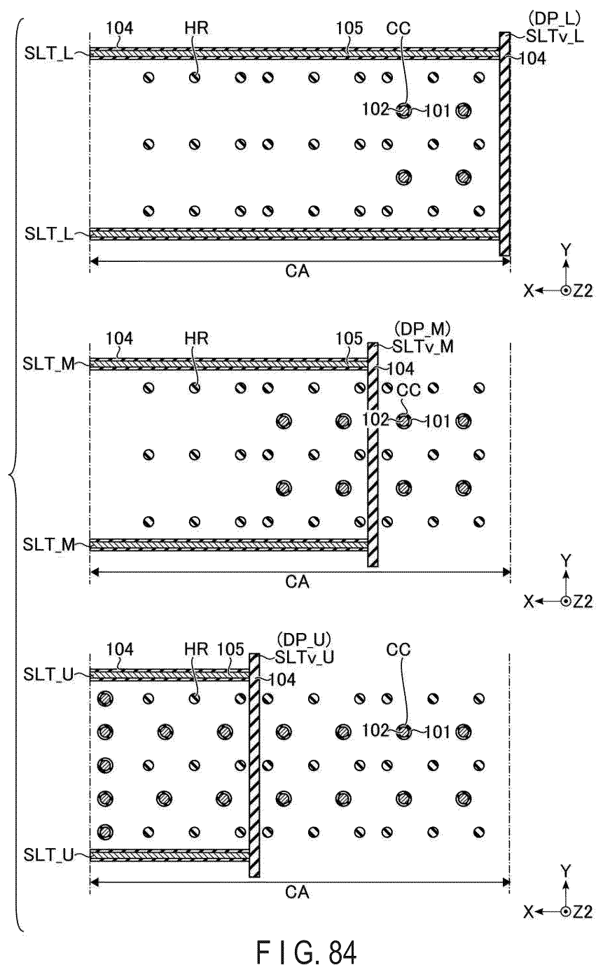

Then, as shown in FIG. 83, as in the first embodiment, the holes SH_L, SH_M and SH_U are each filled with a spacer SP and a conductor 105 (contact LI). In this way, the members SLT are formed. FIG. 84 shows a plan structure of the lower laminate L_SB after the members SLT are formed viewed from above (the first structure from the top of the sheet), a plan structure of the middle laminate M_SB after the members SLT are formed viewed from above (the second structure from the top of the sheet) and a plan structure of the upper laminate U_SB after the members SLT are formed viewed from above (the third structure from the top of the sheet).

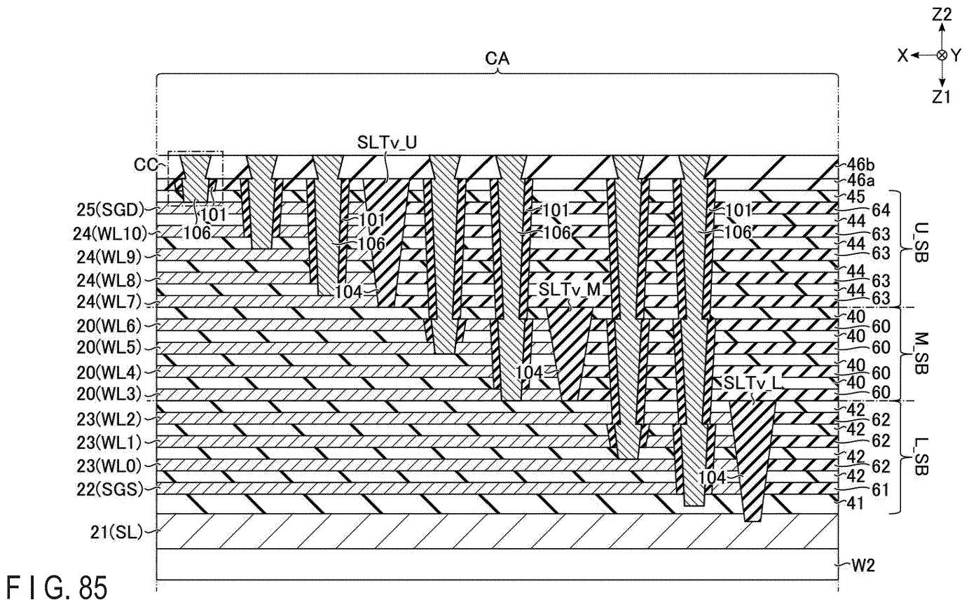

Then, as shown in FIG. 85, as in the first embodiment, an insulator layer 46b is provided on the insulator layer 46a, and then holes EH corresponding to the contacts CC are provided. The lower end of the hole EH reaches the upper face of the hole CH_U. The insulator layer 46b contains silicon oxide, for example. The insulator layers 46a and 46b correspond to the insulator layer 46.

Then, as shown in FIG. 85, as in the first embodiment, the sacrificial member 102 in each of the holes CH_L, CH_M and CH_U is removed.

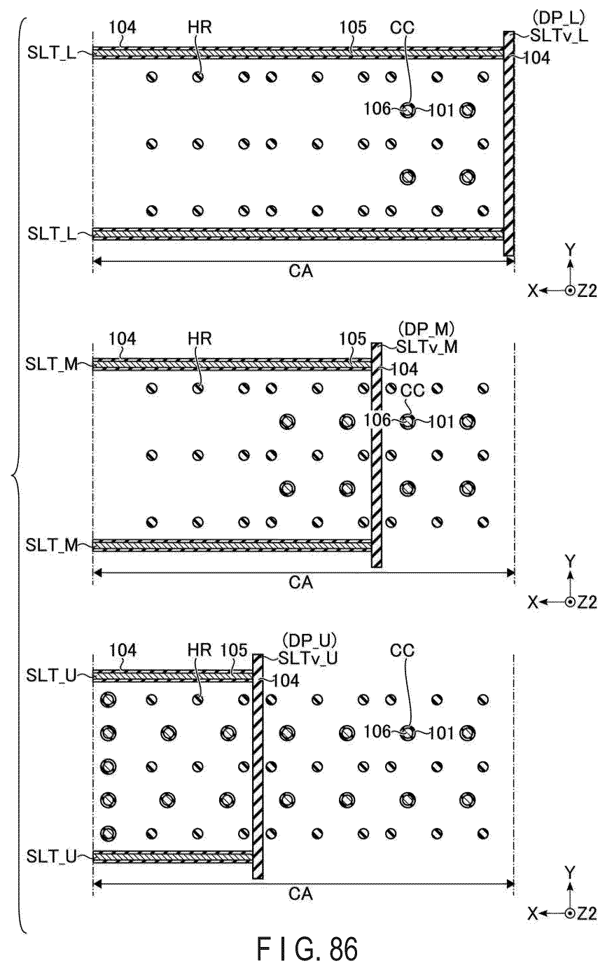

Then, as shown in FIG. 85, as in the first embodiment, each of the holes CH_L, CH_M and CH_U is filled with a conductor 106. In this way, the contacts CC are formed. The conductor 106 contains tungsten, for example. The insulator 101 and the conductor 106 included in each contact CC correspond to the insulator 51 and the conductor 50, respectively. FIG. 86 shows a plan structure of the lower laminate L_SB after the contacts CC are formed viewed from above (the first structure from the top of the sheet), a plan structure of the middle laminate M_SB after the contacts CC are formed viewed from above (the second structure from the top of the sheet) and a plan structure of the upper laminate U_SB after the contacts CC are formed viewed from above (the third structure from the top of the sheet).

Note that the step of forming the hole SH_L may be performed before the step of forming the hole SHv_L. The step of forming the hole SH_M may be performed before the step of forming the hole SHv_M. The step of forming the hole SH_U may be performed before the step of forming the hole SHv_U.

2.7 Effects of this Embodiment

With the semiconductor storage device 3 according to this embodiment, holes corresponding to the members SLT and SLTv are formed in each of the lower laminate L_SB, the middle laminate M_SB and the upper laminate U_SB. Therefore, with the semiconductor storage device 3 according to this embodiment, as in the first embodiment, the amount of digging of the substrate can be reduced.

For example, in order to ensure the withstand voltage, some distance is needed between the contacts connected to the wiring layers of a laminate and the wiring layer of the lowermost one of the wiring layers of the laminate immediately above the laminate, such as between the lower wiring contacts CC and the lowermost one of the wiring layers 20 and between the middle wiring contacts CC and the lowermost one of the wiring layers 24.

With the semiconductor storage device 3 according to this embodiment, the upper end of the lower contact part CC_L is in contact with the lowermost one of the insulator layers 60 provided in the same layer as the lowermost one of the wiring layers 20. The upper end of the middle contact part CC_M is in contact with the lowermost one of the insulator layers 63 provided in the same layer as the lowermost one of the wiring layers 24. In addition, the plurality of insulator layers 60 are provided in the middle laminate M_SB that is above the lower wiring contact CC. The plurality of insulator layers 63 and the insulator layer 64 are provided in the upper laminate U_SB that is above the lower wiring contact CC. The plurality of insulator layers 63 and the insulator layer 64 are provided in the upper laminate U_SB that is above the middle wiring contact CC. Therefore, the withstand voltage can be ensured between the upper end of the lower contact part CC_L and the lowermost one of the wiring layers 20 and between the upper end of the middle contact part CC_M and the lowermost one of the wiring layers 24. In addition, since the distance between the upper end of the lower contact part CC_L and the lowermost one of the insulator layers 60 provided in the same layer as the lowermost one of the wiring layers 20 and the distance between the upper end of the middle contact part CC_M and the insulator layer 63 provided in the same layer as the lowermost one of the wiring layers 24 can be reduced, degradation of a current Icell flowing through the memory cell transistors MT can be reduced.

### 2.8 Variation

A semiconductor storage device according to a variation of the second embodiment will be described. A semiconductor storage device 3 according to this variation differs from the semiconductor storage device 3 according to the second embodiment in the structures of the lower laminate L_SB, the middle laminate M_SB and the upper laminate U_SB and the production method. In the following, differences from the second embodiment will be mainly described.

### 2.8.1 Cross-Sectional Structure of Contact Region

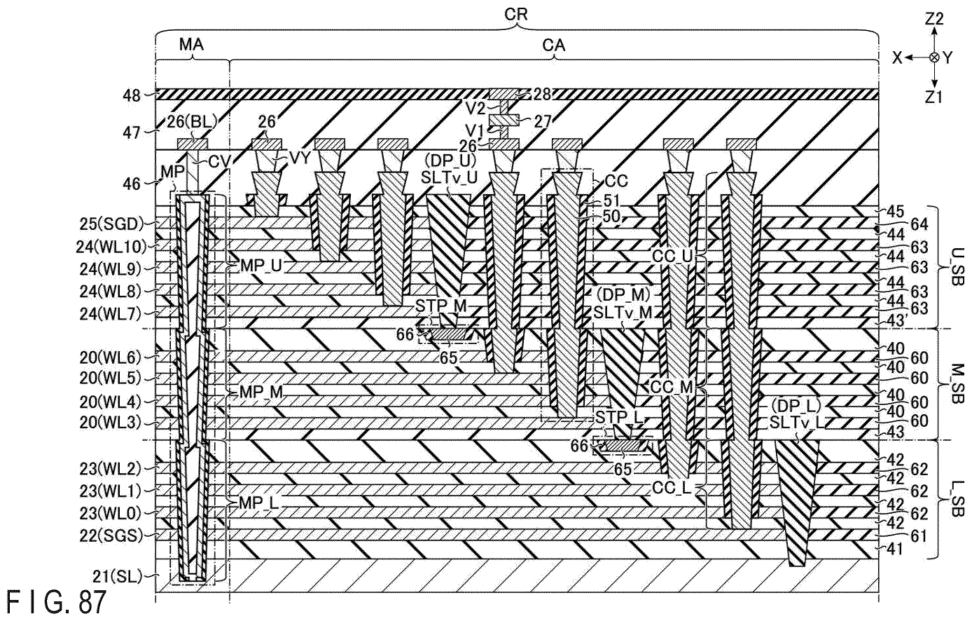

A cross-sectional structure of the contact region CA will be described with reference to FIG. 87. FIG. 87 is a cross-sectional view taken along the line S2-S2 in FIG. 64, showing an example of the cross-sectional structure in the contact region CA of the memory cell array 10 included in the semiconductor storage device 3 according to the variation of the second embodiment. FIG. 87 also shows a cross-sectional structure in the memory region MA in the vicinity of the contact region CA. As shown in FIG. 87, in the memory region MA and the contact region CA of the memory cell array 10, insulator layers 43 and 43′ are added to the cross-sectional structure according to the second embodiment shown in FIG. 66. In addition, in the contact region CA of the memory cell array 10, a lower stopper part STP_L and a middle stopper part STP_M are added. In the following description, it is assumed that the Z2 direction is the upward direction, and the Z1 direction is the downward direction.

In the contact region, the structures of the contact CC and the members SLTv_L, SLTv_M and SLTv_U are the same as those shown in FIG. 66.

The cross-sectional structure below the uppermost one of the insulator layers 42 is the same as the structure shown in FIG. 66.

In the contact region CA, in the region closer to the memory pillar MP than the member SLTv_L, the uppermost one of the insulator layers 42 includes the lower stopper part STP_L. The lower stopper part STP_L functions as a stopper against etching in the step of forming the hole SHv_M corresponding to the member SLTv_M. The lower stopper part STP_L is provided under the member SLTv_M. The upper end of the lower stopper part STP_L is in contact with the lower end of the member SLTv_M. The lower end of the lower stopper part STP_L is located above the lower end of the uppermost one of the insulator layers 42. The lower stopper part STP_L includes a conductor 65 and an insulator 66. The conductor 65 contains polysilicon, for example. Note that the conductor 65 may contain HfO, ZrO, TaO, tungsten or titanium. The insulator 66 covers the side face of the conductor 65. In other words, the lower laminate L_SB is arranged above the uppermost one of the wiring layers 23 and includes the conductor 65 whose side face and bottom face are covered by the insulator. In addition, the upper end of the conductor 65 is in contact with the lower end of the member SLTv_M. The insulator 66 contains silicon oxide, for example.

In the contact region CA, in the region closer to the memory pillar MP than the member SLTv_M, the insulator layer 43 is provided on the upper most one of the insulator layers 42. The insulator layer 43 contains TEOS, for example. On the insulator layer 43, the wiring layers 20 and the insulator layers 40 are alternately stacked. The uppermost one of the insulator layers 40 includes the middle stopper part STP_M. The middle stopper part STP_M functions as a stopper against etching in the step of forming the hole SHv_U corresponding to the member SLTv_U. The middle stopper part STP_M is provided under the member SLTv_U. The upper end of the middle stopper part STP_M is in contact with the lower end of the member SLTv_U. The lower end of the middle stopper part STP_M is located above the lower end of the uppermost one of the insulator layers 40. The middle stopper part STP_M includes the conductor 65 and the insulator 66. The insulator 66 covers the side face of the conductor 65. In other words, the middle laminate M_SB is arranged above the uppermost one of the wiring layers 20 and includes the conductor 65 whose side face and bottom face are covered by the insulator. In addition, the upper end of the conductor 65 is in contact with the lower end of the member SLTv_U.

In the contact region CA, in the region closer to the memory pillar MP than the member SLTv_U, the insulator layer 43′ is provided on the upper most one of the insulator layers 40. The insulator layer 43′ contains TEOS, for example. On the insulator layer 43′, the wiring layers 24 and the insulator layers 44 are alternately stacked. On the uppermost one of the insulator layers 44, the wiring layer 25, the insulator layer 45 and the insulator layer 46 are stacked in this order.

In the contact region CA, in the region farther from the memory pillar MP than the member SLTv_M, the insulator layer 43 is provided on the uppermost one of the insulator layers 42. On the insulator layer 43, the insulator layers 60 and the insulator layers 40 are alternately stacked.

In the contact region CA, in the region farther from the memory pillar MP than the member SLTv_U, the insulator layer 43′ is provided on the uppermost one of the insulator layers 40. On the insulator layer 43′, the insulator layers 63 and the insulator layers 44 are alternately stacked. On the uppermost one of the insulator layers 44, the insulator layer 64, the insulator layer 45 and the insulator layer 46 are stacked in this order.

The cross-sectional structure above the insulator layer 46 is the same as the structure shown in FIG. 66.

### 2.8.2 Production Method for Semiconductor Storage Device

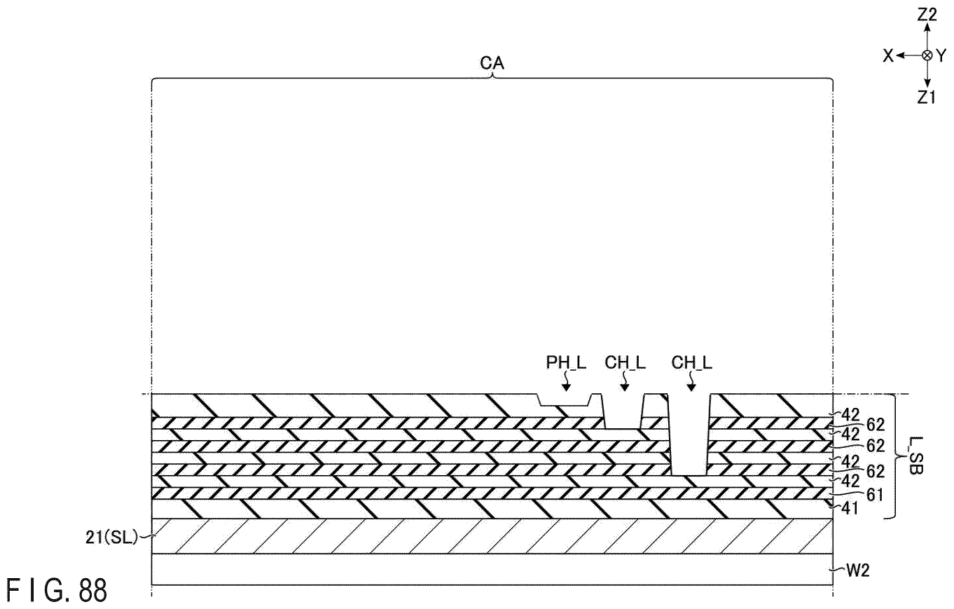

A production method for the semiconductor storage device 3 according to this variation will be described with reference to FIGS. 88 to 91. FIGS. 88 to 91 are cross-sectional views showing examples of a cross-sectional structure during production of the semiconductor storage device 3 according to the variation of the second embodiment. In the following, description of the step of forming the memory pillar MP and the supporting pillar HR will be omitted.

First, as shown in FIG. 88, as in the second embodiment, on the semiconductor substrate W2, the wiring layer 21, the insulator layer 41 and the sacrificial member 61 are stacked, and then, on the sacrificial member 61, four insulator layers 42 and three sacrificial members 62 are alternately stacked one on another.

Then, as shown in FIG. 88, as in the second embodiment, a hole CH_L corresponding to the lower contact part CC_L and a hole PH_L corresponding to the lower stopper part STP_L are provided. The lower end of the hole PH_L reaches a position above the lower end of the uppermost one of the insulator layers 42.

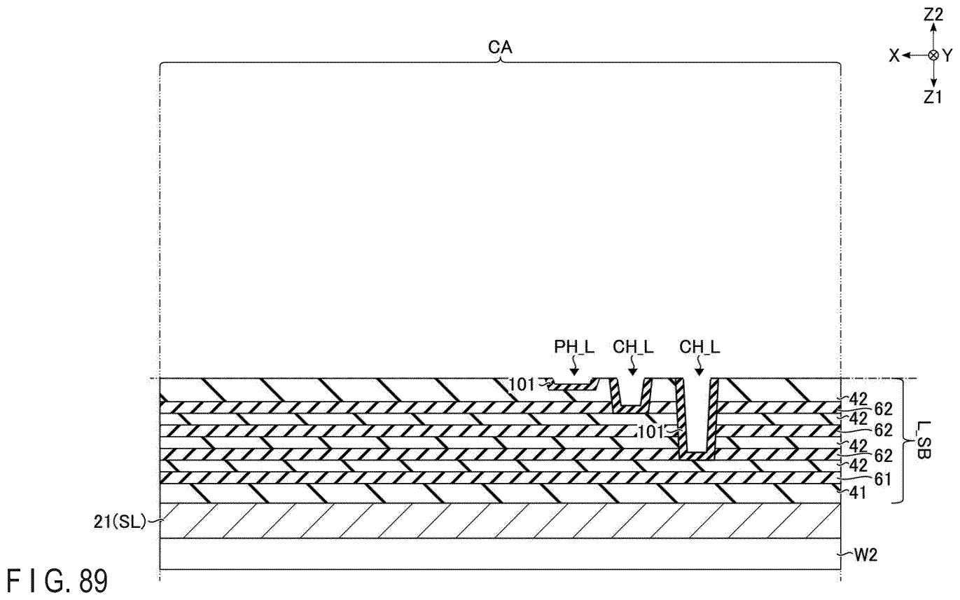

Then, as shown in FIG. 89, as in the second embodiment, an insulator 101 is provided in the holes CH_L and PH_L. In this way, the side face and the bottom face of each of the holes CH_L and PH_L are covered by the insulator 101. The insulator 101 corresponds to the insulator 66.

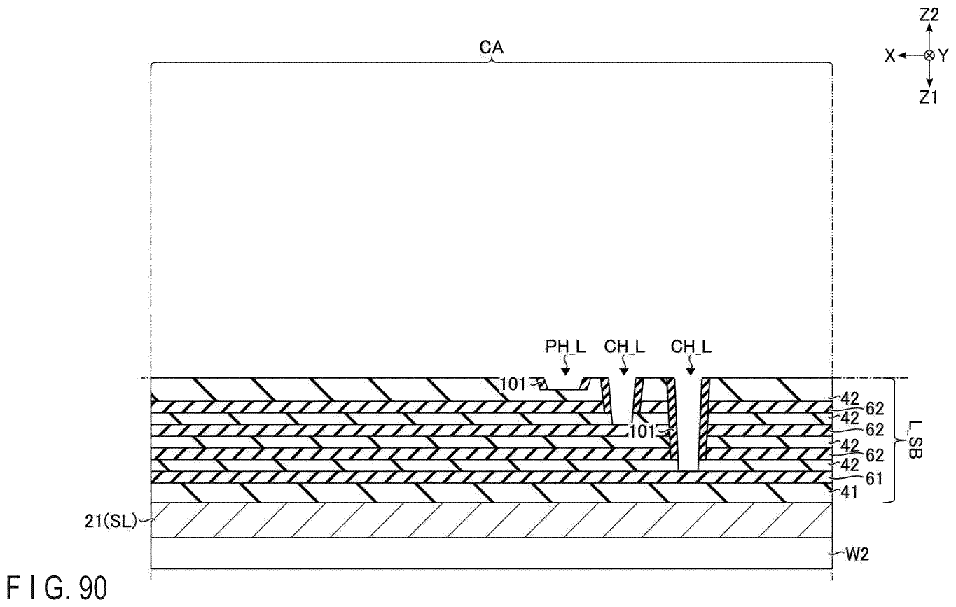

Then, as shown in FIG. 90, as in the second embodiment, the bottom removal step is performed for the holes CH_L and PH_L. In this way, the insulator 101 on the bottom face of the hole PH_L is removed.

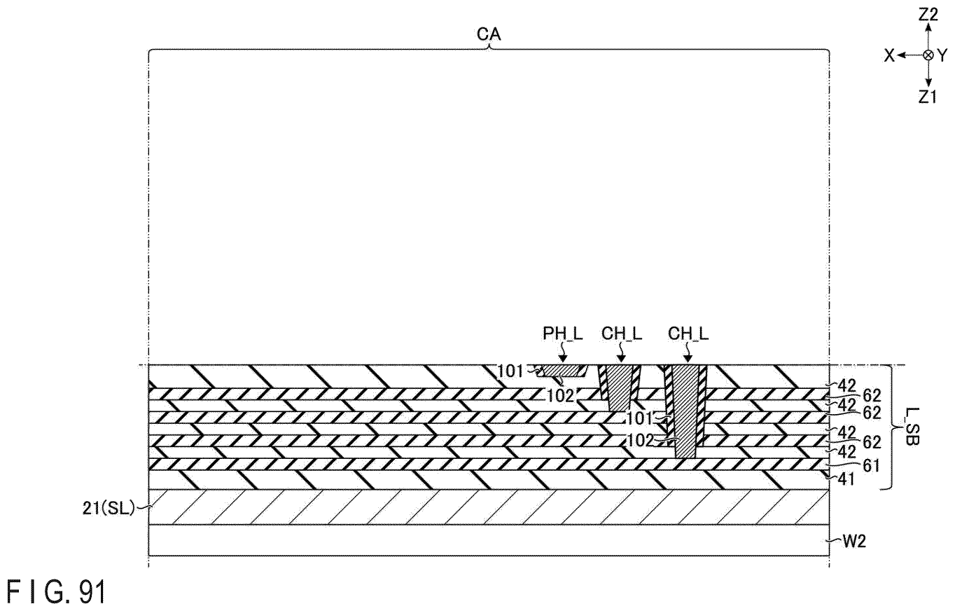

Then, as shown in FIG. 91, as in the second embodiment, the holes CH_L and PH_L are filled with a sacrificial member 102. The sacrificial member 102 contains polysilicon, for example. The sacrificial member 102 corresponds to the conductor 65.

Then, as in the second embodiment, the step of forming a hole SHv_L corresponding to the member SLTv_L and the step of filling the hole SHv_L with the insulator 104 are performed. Then, the step of forming a hole SH_L corresponding to the lower member SLT_L and the step of filling the hole SH_L with the sacrificial member 103 are performed.

Then, on the uppermost one of the insulator layers 42, an insulator layer 43 is provided. The insulator layer 43 contains TEOS, for example. Then, as in the second embodiment, on the insulator layer 43, four sacrificial members 60 and four insulator layers 40 are alternately stacked one on another.

Then, as with the holes CH_L and PH_L, a hole CH_M corresponding to the middle contact part CC_M and a hole PH_M corresponding to the middle stopper part STP_M are provided. The lower end of the hole PH_L reaches a position above the lower end of the uppermost one of the insulator layers 40.

Then, as with the holes CH_L and PH_L, the forming step for the insulator 101 and the bottom removal step are performed for the holes CH_M and PH_M, and then, the holes CH_M and PH_M are filled with the sacrificial member 102.

Then, a hole SHv_M corresponding to the member SLTv_M is provided. In this step, since the lower stopper part STP_L is provided under the position where the hole SHv_M is formed, the etching is stopped at the upper face of the lower stopper part STP_L. That is, the lower end of the hole SHv_M reaches the upper face of the lower stopper part STP_L. Then, the step of filling the hole SHv_M with the insulator 104 is performed. Then, the step of forming a hole SH_M corresponding to the middle member SLT_M and the step of filling the hole SH_M with the sacrificial member 103 are performed.

Then, on the uppermost one of the insulator layers 40, an insulator layer 43′ is provided. The insulator layer 43′ contains TEOS, for example. Then, as in the second embodiment, on the insulator layer 43′, four sacrificial members 63 and four insulator layers 44 are alternately stacked one on another. Then, as in the second embodiment, on the uppermost one of the insulator layers 44, the sacrificial member 64, the insulator layer 45 and the insulator layer 46a are stacked in this order.

Then, as with the hole CH_L, a hole CH_U corresponding to the upper contact part CC_U is provided. Then, as with the hole CH_L, the forming step for the insulator 101 and the bottom removal step are performed for the hole CH_U, and then, the hole CH_U is filled with the sacrificial member 102.

Then, a hole SHv_U corresponding to the member SLTv_U is provided. In this step, since the middle stopper part STP_M is provided under the position where the hole SHv_U is formed, the etching is stopped at the upper face of the middle stopper part STP_M. That is, the lower end of the hole SHv_U reaches the upper face of the middle stopper part STP_M. Then, the step of filling the hole SHv_U with the insulator 104 is performed.

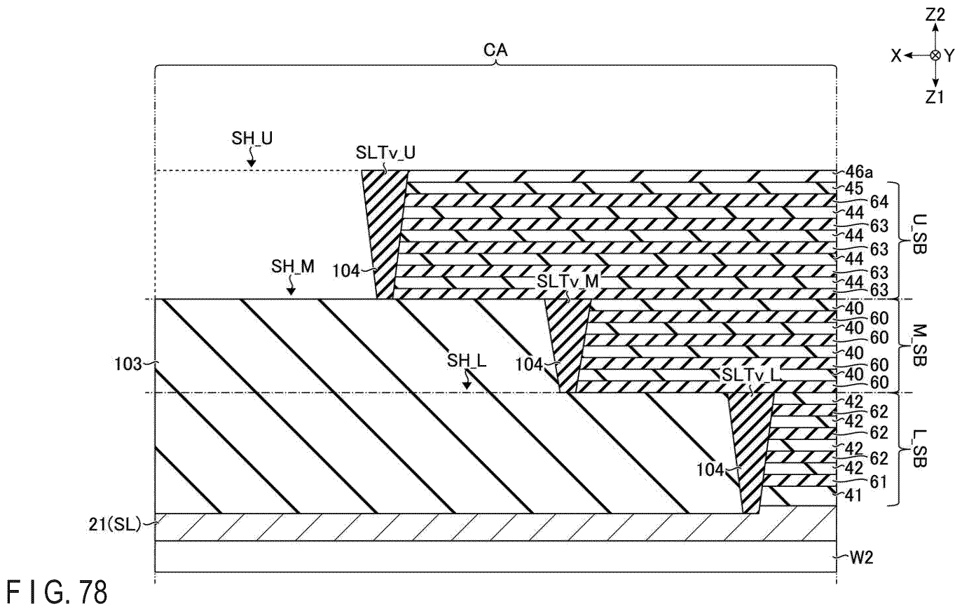

The subsequent steps are the same as those in the second embodiment shown in FIGS. 78 to 86.

2.8.3 Effects of this Variation

With the semiconductor storage device 3 according to this variation, holes corresponding to the members SLT and SLTv are formed in each of the lower laminate L_SB, the middle laminate M_SB and the upper laminate U_SB. Therefore, with the semiconductor storage device 3 according to this variation, as in the second embodiment, the amount of digging of the substrate can be reduced.

Furthermore, with the semiconductor storage device 3 according to this variation, the lower laminate L_SB is arranged above the uppermost one of the wiring layers 23 and includes the conductor 65 whose side face and bottom face are covered by the insulator. In addition, the upper end of the conductor 65 is in contact with the lower end of the member SLTv_M. The middle laminate M_SB is arranged above the uppermost one of the wiring layers 20 and includes the conductor 65 whose side face and bottom face are covered by the insulator. In addition, the upper end of the conductor 65 is in contact with the lower end of the member SLTv_U. Therefore, in the processing of the holes SHv_M and SHv_U, non-selective etching of the insulator layers 40, 43 and 44 and the sacrificial members 60, 63 and 64 can also be applied.

### 3. Others

As described above, a semiconductor storage device (3) according to an embodiment includes a first laminate (L_SB), a second laminate (M_SB), a memory pillar (MP), a first contact (CC), a first dividing portion (DP_L), a second contact (CC) and a second dividing portion (DP_M). The first laminate (L_SB) includes a plurality of first wiring layers (22, 23) and a plurality of first insulator layers (61, 62), the plurality of first wiring layers being arranged at intervals in a first direction (Z), and the plurality of first insulator layers (61, 62) being provided in the same layers as the plurality of first wiring layers. The second laminate (M_SB) includes a plurality of second wiring layers (20) and a plurality of second insulator layers (60) and is arranged above the first laminate (L_SB), the plurality of second wiring layers being arranged at intervals in the first direction (Z), and the plurality of second insulator layers (60) being provided in the same layers as the plurality of second wiring layers. The memory pillar (MP) penetrates the plurality of first wiring layers (22, 23) and the plurality of second wiring layers (20) in the first direction (Z). The first contact extends in the first direction (Z), penetrates the second laminate (M_SB) and is connected (e.g., electrically connected) to one of the first wiring layers 22, 23 (e.g., a third wiring layer (SGS/WL0/WL1/WL2) among the plurality of first wiring layers (22, 23)), and at least a part of the side face of the first contact is covered by a first insulator (51). The first dividing portion (DP_L) extends in the first direction (Z) and a second direction (Y) that intersects with the first direction, and divides the first wiring layers (22, 23) in a third direction (X) that intersects with the first direction and the second direction. The second contact (CC) extends in the first direction (Z) and is connected (e.g., electrically connected) to one second wiring layer 20 (e.g., a fourth wiring layer (WL3/WL4/WL5/WL6) among the plurality of second wiring layers (20)), and at least a part of the side face of the second contact is covered by a second insulator (51). The second dividing portion (DP_M) extends in the first direction (Z) and the second direction (Y) and divides the plurality of second wiring layers (20) in the third direction (X). The second dividing portion (DP_M) does not overlap with the first dividing portion (DP_L) in the first direction (Z).

Note that the embodiments described above are not intended to be limiting, and various modifications can be made.

The production processes in the embodiments described above are just examples and are not intended to be limiting. For example, other processing may be inserted between production steps described above, or some steps may be omitted or integrated. Furthermore, the sequence of the production steps may be changed within the bounds of possibility.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. The accompanying claims and their equivalents are intended to cover such forms or modification as would fall within the scope and spirit of the inventions.

What is claimed is:

1. A semiconductor storage device, comprising:
a first laminate that includes a plurality of first wiring layers and a plurality of first insulator layers, the plurality of first wiring layers being arranged at intervals in a first direction, and the plurality of first insulator layers being on the same layers as the plurality of first wiring layers;
a second laminate that includes a plurality of second wiring layers and a plurality of second insulator layers and is arranged above the first laminate, the plurality of second wiring layers being arranged at intervals in the first direction, and the plurality of second insulator layers being on the same layers as the plurality of second wiring layers;
a memory pillar that penetrates the plurality of first wiring layers and the plurality of second wiring layers in the first direction;
a first contact that extends in the first direction, penetrates the second laminate and is connected to one first wiring layer of the plurality of first wiring layers, at least a part of a side face of the first contact being covered by a first insulator;
a first dividing portion that extends in the first direction and a second direction that intersects with the first direction, and divides the plurality of first wiring layers in a third direction that intersects with the first direction and the second direction;
a second contact that extends in the first direction and is connected to one second wiring layer of the plurality of second wiring layers, at least a part of a side face of the second contact being covered by a second insulator; and
a second dividing portion that extends in the first direction and the second direction and divides the plurality of second wiring layers in the third direction,
wherein the second dividing portion does not overlap with the first dividing portion in the first direction.

2. The semiconductor storage device of claim 1, wherein the first contact penetrates the plurality of second wiring layers.

3. The semiconductor storage device of claim 2, wherein the first dividing portion is closer to the memory pillar than the second dividing portion is to the memory pillar.

4. The semiconductor storage device of claim 3, wherein:
the first contact is in a region between the memory pillar and the first dividing portion, and
the second contact is in a region between the first dividing portion and the second dividing portion.

5. The semiconductor storage device of claim 4 further comprising:
a third contact connected to an upper end of the first contact; and
a fourth contact connected to an upper end of the second contact,
wherein a sum of a distance from the upper end of the first contact to a lower end of the first contact and a distance from the lower end of the first contact to the memory pillar and a sum of a distance from the upper end of the second contact to a lower end of the second contact and a distance from the lower end of the second contact to the memory pillar are balanced.

6. The semiconductor storage device of claim 2, wherein:
the first dividing portion is closer to the memory pillar than the plurality of first insulator layers is to the memory pillar,
the second dividing portion is closer to the memory pillar than the plurality of second insulator layers is to the memory pillar, and
the second dividing portion is above the plurality of first insulator layers in the first direction.

7. The semiconductor storage device of claim 6, wherein:
each first insulator layer of the plurality of first insulator layers is in contact with a corresponding one first wiring layer of the plurality of first wiring layers, and
each second insulator layer of the plurality of second insulator layers is in contact with a corresponding one second wiring layer of the plurality of second wiring layers.

8. The semiconductor storage device of claim 6, wherein:
the first dividing portion is in contact with the plurality of first wiring layers and the plurality of first insulator layers, and
the second dividing portion is in contact with the plurality of second wiring layers and the plurality of second insulator layers.

9. The semiconductor storage device of claim 8, wherein the second contact is above the plurality of first insulator layers in the first direction.

10. The semiconductor storage device of claim 2, wherein the first dividing portion includes:
a boundary between each first wiring layer of the plurality of first wiring layers and a corresponding one first insulator layer of the plurality of first insulator layers, the boundary extending in the first direction and the second direction; and
a third insulator that penetrates the boundaries in the third direction.

11. The semiconductor storage device of claim 10, wherein the boundary includes a part having an arc shape in top view.

12. The semiconductor storage device of claim 11 further comprising a first member that extends in the first direction and the third direction and divides the plurality of first wiring layers in the second direction,
wherein:
the first member includes a first part and a second part, the first part including a first conductor and a fourth insulator, and the second part including the third insulator, and
the second part is in contact with each first wiring layer of the plurality of first wiring layers and each first insulator layer of the plurality of first insulator layers.

13. The semiconductor storage device of claim 1, wherein the first contact penetrates the plurality of second insulator layers.

14. The semiconductor storage device of claim 13, wherein the second dividing portion is at a position closer to the memory pillar than the first dividing portion is to the memory pillar.

15. The semiconductor storage device of claim 14, wherein:
the second contact is in a region between the memory pillar and the second dividing portion, and
the first contact is in a region between the second dividing portion and the first dividing portion.

16. The semiconductor storage device of claim 13, wherein:
the first dividing portion is closer to the memory pillar than the plurality of first insulator layers is to the memory pillar,
the second dividing portion is closer to the memory pillar than the plurality of second insulator layers is to the memory pillar, and
the second dividing portion is above the plurality of first wiring layers in the first direction.

17. The semiconductor storage device of claim 16, wherein:
the first dividing portion is in contact with the plurality of first wiring layers and the plurality of first insulator layers, and
the second dividing portion is in contact with the plurality of second wiring layers and the plurality of second insulator layers.

18. The semiconductor storage device of claim 17, wherein the second contact is above the plurality of first wiring layers in the first direction.

19. The semiconductor storage device of claim 13, wherein the first contact includes:
a fifth contact that is connected to the third wiring layer; and
a sixth contact that penetrates the plurality of second insulator layers in the first direction and is in contact with an upper end of the fifth contact, and
wherein the upper end of the fifth contact is in contact with a lowermost second insulator layer of the plurality of second insulator layers.

20. The semiconductor storage device of claim 13, wherein the first laminate further includes:
a conductor above an uppermost first wiring layer of the plurality of first wiring layers, a side face and a bottom face of the conductor being covered by an insulator, and
an upper end of the conductor is in contact with a lower end of the second dividing portion.
